(19) United States
(12) Patent Application Publication
(10) Pub. No.: US 2024/0334831 A1
(43) Pub. Date: Oct. 3, 2024

(54) POLYCYCLIC COMPOUND AND ORGANIC LIGHT EMITTING DEVICE INCLUDING THE SAME

(71) Applicant: SFC CO., LTD, Chungcheongbuk-do (KR)

(72) Inventors: Jin-hwi CHO, Chungcheongbuk-do (KR); So-young SHIM, Chungcheongbuk-do (KR)

(21) Appl. No.: 18/586,830

(22) Filed: Feb. 26, 2024

(30) Foreign Application Priority Data
Feb. 28, 2023 (KR) 10-2023-0026611
Jan. 29, 2024 (KR) 10-2024-0012960

(51) Int. Cl. H10K 85/60; C07F 5/02; C09K 11/06; H10K 50/12; H10K 85/40

(52) U.S. Cl. CPC H10K 85/658; C07F 5/027; C09K 11/06; H10K 85/40; C09K 2211/1018; H10K 50/12

(57) ABSTRACT

Disclosed are a polycyclic compound with a specific fused ring structure and an organic light emitting device including a light emitting layer that employs the polycyclic compound. The use of the polycyclic compound ensures significantly long lifetime and improved luminous efficiency of the device.

### CROSS-REFERENCE TO RELATED APPLICATIONS

This application claims priority to Korean Patent Application No. 10-2023-0026611, filed on Feb. 28, 2023 and Korean Patent Application No. 10-2024-0012960, filed on Jan. 29, 2024. The entire disclosure of the applications identified in this paragraph is incorporated herein by references.

### FIELD

The present invention relates to a polycyclic compound employed in an organic layer (for example, a light emitting layer) of an organic light emitting device and an organic light emitting device including the polycyclic compound.

### BACKGROUND

Organic light emitting devices are self-luminous devices in which electrons injected from an electron injecting electrode (cathode) recombine with holes injected from a hole injecting electrode (anode) in a light emitting layer to form excitons, which emit light while releasing energy. Such organic light emitting devices have the advantages of low driving voltage, high luminance, large viewing angle, and short response time and can be applied to full-color light emitting flat panel displays. Due to these advantages, organic light emitting devices have received attention as next-generation light sources.

The above characteristics of organic light emitting devices are achieved by structural optimization of organic layers of the devices and are supported by stable and efficient materials for the organic layers, such as hole injecting materials, hole transport materials, light emitting materials, electron transport materials, electron injecting materials, and electron blocking materials. However, more research still needs to be done to develop structurally optimized structures of organic layers for organic light emitting devices and stable and efficient materials for organic layers of organic light emitting devices.

Particularly, for maximum efficiency in a light emitting layer, an appropriate combination of energy band gaps of a host and a dopant is required such that holes and electrons migrate to the dopant through stable electrochemical paths to form excitons.

### SUMMARY

Therefore, the present invention is intended to provide a polycyclic compound with a specific fused ring structure and an organic light emitting device including a light emitting layer that employs the polycyclic compound as a dopant material, achieving significantly long lifetime and improved luminous efficiency.

One aspect of the present invention provides a polycyclic compound with a specific fused ring structure, represented by Formula 1:

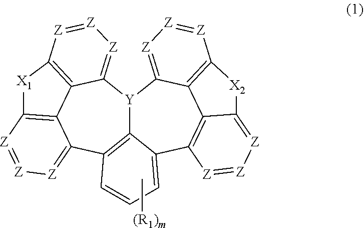

The specific structure of Formula 1, definitions of the substituents in Formula 1, and specific compounds that can be represented by Formula 1 are described below.

A further aspect of the present invention provides an organic light emitting device including the polycyclic compound as a dopant for a light emitting layer.

The organic light emitting device of the present invention includes a light emitting layer in which the polycyclic compound having a specific fused ring structure is employed as a dopant. The use of the dopant ensures high efficiency and long lifetime of the organic light emitting device. Due to these advantages, the organic light emitting device of the present invention can find useful applications in not only lighting systems but also a variety of displays, including flat panel displays, flexible displays, and wearable displays.

### DETAILED DESCRIPTION

The present invention will now be described in more detail.

One aspect of the present invention is directed to a polycyclic compound represented by Formula 1:

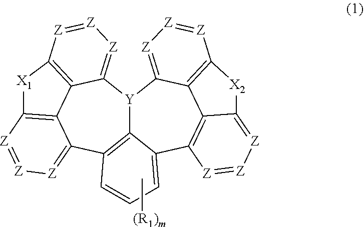

wherein Y is selected from B, N, P═O, and P═S, each Z is independently CR or N, X₁ and X₂ are the same as or different from each other and are each independently selected from O, S, Se, NR₂, CR₃R₄, SiR₅R₆, and GeR₇R₈, R and R₁ to R₈ are the same as or different from each other and are each independently selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, cyclic groups in which a substituted or unsubstituted C₃-C₃₀ aliphatic ring and a C₅-C₃₀ aromatic ring are fused together, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, nitro, cyano, and halogen, with the proviso that adjacent ones of the groups R are optionally linked to each other to form an alicyclic or aromatic mono- or polycyclic ring, that R₃ and R₄ are optionally linked to each other to form an alicyclic or aromatic mono- or polycyclic ring, that R₅ and R₆ are optionally linked to each other to form an alicyclic or aromatic mono- or polycyclic ring, and that R₇ and R₅ are optionally linked to each other to form an alicyclic or aromatic mono- or polycyclic ring, and m is an integer of 3, with the proviso that adjacent ones of the groups R₁ are optionally linked to each other to form an alicyclic or aromatic mono- or polycyclic ring.

According to one embodiment of the present invention, Y in Formula 1 may be B.

According to one embodiment of the present invention, at least one of the groups R₁ in Formula 1 may be other than hydrogen or deuterium.

According to one embodiment of the present invention, X₁ and X₂ in Formula 1 may be each independently O or S.

As used herein, the term “substituted” in the definitions of Z, X₁, X₂, and R₁ in Formula 1 indicates substitution with one or more substituents selected from deuterium, C₁-C₂₄ alkyl, C₁-C₂₄ haloalkyl, C₂-C₂₄ alkenyl, C₂-C₂₄ alkynyl, C₃-C₃₀ cycloalkyl, C₁-C₂₄ heteroalkyl, C₆-C₃₀ aryl, C₇-C₃₀ arylalkyl, C₇-C₃₀ alkylaryl, C₂-C₃₀ heteroaryl, C₂-C₃₀ heteroarylalkyl, cyclic groups in which a C₅-C₂₄ aliphatic ring and a C₅-C₂₄ aromatic ring are fused together, C₁-C₂₄ alkoxy, C₁-C₃₀ amine, C₁-C₃₀ silyl, C₁-C₃₀ germanium, C₆-C₂₄ aryloxy, C₆-C₂₄ arylthionyl, cyano, halogen, hydroxyl, and nitro, or a combination thereof. The term “unsubstituted” in the same definition indicates having no substituent. One or more hydrogen atoms in each of the substituents are optionally replaced by deuterium atoms and two or more adjacent ones of the substituents are optionally linked to each other to form an alicyclic or aromatic mono- or polycyclic ring.

In the “substituted or unsubstituted C₁-C₃₀ alkyl”, “substituted or unsubstituted C₆-C₅₀ aryl”, etc., the number of carbon atoms in the alkyl or aryl group indicates the number of carbon atoms constituting the unsubstituted alkyl or aryl moiety without considering the number of carbon atoms in the substituent(s). For example, a phenyl group substituted with a butyl group at the para-position corresponds to a C₆ aryl group substituted with a C₄ butyl group.

As used herein, the expression “optionally linked to each other or an adjacent group to form a ring” means that the corresponding adjacent substituents are bonded to each other or each of the corresponding substituents is bonded to an adjacent group to form a substituted or unsubstituted alicyclic or aromatic ring. The term “adjacent group” may mean a substituent on an atom directly attached to an atom substituted with the corresponding substituent, a substituent disposed sterically closest to the corresponding substituent or another substituent on an atom substituted with the corresponding substituent. For example, two substituents substituted at the ortho position of a benzene ring or two substituents on the same carbon in an aliphatic ring may be considered “adjacent” to each other. Optionally, the paired substituents each lose one hydrogen radical and are linked to each other to form a ring. The carbon atoms in the resulting alicyclic, aromatic mono- or polycyclic ring may be replaced by one or more heteroatoms such as O, S, N, P, Si, and Ge.

In the present invention, the alkyl groups may be straight or branched. Specific examples of the alkyl groups include, but are not limited to, methyl, ethyl, propyl, n-propyl, isopropyl, butyl, n-butyl, isobutyl, tert-butyl, sec-butyl, 1-methylbutyl, 1-ethylbutyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohexylmethyl, octyl, n-octyl, tert-octyl, 1-methylheptyl, 2-ethylhexyl, 2-propylpentyl, n-nonyl, 2,2-dimethylheptyl, 1-ethylpropyl, 1,1-dimethylpropyl, isohexyl, 2-methylpentyl, 4-methylhexyl, and 5-methylhexyl groups.

In the present invention, specific examples of the arylalkyl groups include, but are not limited to, phenylmethyl(benzyl), phenylethyl, phenylpropyl, naphthylmethyl, and naphthylethyl.

In the present invention, specific examples of the alkylaryl groups include, but are not limited to, tolyl, xylenyl, dimethylnaphthyl, t-butylphenyl, t-butylnaphthyl, and t-butylphenanthryl.

The alkenyl group is intended to include straight and branched ones and may be optionally substituted with one or more other substituents. The alkenyl group may be specifically a vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl) vinyl-1-yl, 2,2-bis(diphenyl-1-yl)vinyl-1-yl, stilbenyl or styrenyl group but is not limited thereto.

The alkynyl group is intended to include straight and branched ones and may be optionally substituted with one or more other substituents. The alkynyl group may be, for example, ethynyl or 2-propynyl but is not limited thereto.

The cycloalkenyl group is a non-aromatic cyclic unsaturated hydrocarbon group having one or more carbon-carbon double bonds. The cycloalkenyl group may be, for example, cyclopropenyl, cyclobutenyl, cyclopentenyl, cyclohexenyl, cycloheptenyl, 1,3-cyclohexadienyl, 1,4-cyclohexadienyl, 2,4-cycloheptadienyl or 1,5-cyclooctadienyl but is not limited thereto.

The aromatic hydrocarbon rings or aryl groups may be monocyclic or polycyclic ones. As used herein, the term “polycyclic” means that the aromatic hydrocarbon ring may be directly attached or fused to one or more other cyclic groups. The other cyclic groups may be aromatic hydrocarbon rings and other examples thereof include aliphatic heterocyclic rings, aliphatic hydrocarbon rings, and aromatic heterocyclic rings. Examples of the monocyclic aryl groups include, but are not limited to, phenyl, biphenyl, and terphenyl. Examples of the polycyclic aryl groups include naphthyl, anthracenyl, phenanthrenyl, pyrenyl, perylenyl, tetracenyl, chrysenyl, fluorenyl, acenaphathcenyl, triphenylene, and fluoranthrene groups but the scope of the present invention is not limited thereto.

The aromatic heterocyclic rings or heteroaryl groups refer to aromatic groups containing one or more heteroatoms such as O, S, N, P, Si, and Ge. Examples of the aromatic heterocyclic rings or heteroaryl groups include, but are not limited to, thiophene, furan, pyrrole, imidazole, thiazole, oxazole, oxadiazole, triazole, pyridyl, bipyridyl, pyrimidyl, triazine, triazole, acridyl, pyridazine, pyrazinyl, quinolinyl, quinazoline, quinoxalinyl, phthalazinyl, pyridopyrimidinyl, pyridopyrazinyl, pyrazinopyrazinyl, isoquinoline, indole, carbazole, benzoxazole, benzimidazole, benzothiazole, benzocarbazole, benzothiophene, dibenzothiophene, benzofuranyl, dibenzofuranyl, phenanthroline, thiazolyl, isoxazolyl, oxadiazolyl, thiadiazolyl, benzothiazolyl, and phenothiazinyl groups.

The aliphatic hydrocarbon rings or cycloalkyl groups refer to non-aromatic rings consisting only of carbon and hydrogen atoms. The aliphatic hydrocarbon ring is intended to include monocyclic and polycyclic ones and may be optionally substituted with one or more other substituents. As used herein, the term “polycyclic” means that the aliphatic hydrocarbon ring may be directly attached or fused to one or more other cyclic groups. The other cyclic groups may be aliphatic hydrocarbon rings and other examples thereof include aliphatic heterocyclic rings, aromatic hydrocarbon rings, and aromatic heterocyclic rings. Specific examples of the aliphatic hydrocarbon rings include, but are not limited to, cycloalkyl groups such as cyclopropyl, cyclobutyl, cyclopentyl, adamantyl, bicycloheptanyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, and cyclooctyl, cycloalkanes such as cyclohexane and cyclopentane, and cycloalkenes such as cyclohexene and cyclobutene.

The aliphatic heterocyclic rings or heterocycloalkyl groups refer to aliphatic rings containing one or more heteroatoms such as O, S, N, P, Si, and Ge. The aliphatic heterocyclic ring is intended to include monocyclic or polycyclic ones and may be optionally substituted with one or more other substituents. As used herein, the term “polycyclic” means that the aliphatic heterocyclic ring such as heterocycloalkyl or heterocycloalkane may be directly attached or fused to one or more other cyclic groups. The other cyclic groups may be aliphatic heterocyclic rings and other examples thereof include aliphatic hydrocarbon rings, aromatic hydrocarbon rings, and aromatic heterocyclic rings.

The cyclic groups in which an aliphatic ring and an aromatic ring are fused together refers to mixed aliphatic-aromatic cyclic groups in which at least one aliphatic ring and at least one aromatic ring are linked and fused together and which are overall non-aromatic. More specifically, the cyclic groups in which an aliphatic ring and an aromatic ring are fused together may be an aromatic hydrocarbon cyclic group fused with an aliphatic hydrocarbon ring, an aromatic hydrocarbon cyclic group fused with an aliphatic heterocyclic ring, an aromatic heterocyclic group fused with an aliphatic hydrocarbon ring, an aromatic heterocyclic group fused with an aliphatic heterocyclic ring, an aliphatic hydrocarbon cyclic group fused with an aromatic hydrocarbon ring, an aliphatic hydrocarbon cyclic group fused with an aromatic hydrocarbon ring, an aliphatic heterocyclic group fused with an aromatic hydrocarbon ring, and an aliphatic heterocyclic group fused with an aromatic heterocyclic ring. Specific examples of the cyclic groups in which an aliphatic ring and an aromatic ring are fused together include tetrahydronaphthyl, tetrahydrobenzocycloheptene, tetrahydrophenanthrene, tetrahydroanthracenyl, octahydrotriphenylene, tetrahydrobenzothiophene, tetrahydrobenzofuranyl, tetrahydrocarbazole, and tetrahydroquinoline. The cyclic groups in which an aliphatic ring and an aromatic ring are fused together may be interrupted by contain at least one heteroatom other than carbon. The heteroatom may be, for example, O, S, N, P, Si or Ge.

The alkoxy group may be specifically a methoxy, ethoxy, propoxy, isobutyloxy, sec-butyloxy, pentyloxy, iso-amyloxy or hexyloxy group but is not limited thereto.

The silyl group is intended to include —SiH₃, alkylsilyl, arylsilyl, alkylarylsilyl, arylheteroarylsilyl, and heteroarylsilyl. The arylsilyl refers to a silyl group obtained by substituting one, two or three of the hydrogen atoms in —SiH₃ with aryl groups. The alkylsilyl refers to a silyl group obtained by substituting one, two or three of the hydrogen atoms in-SiHs with alkyl groups. The alkylarylsilyl refers to a silyl group obtained by substituting one of the hydrogen atoms in-SiHs with an alkyl group and the other two hydrogen atoms with aryl groups or substituting two of the hydrogen atoms in —SiH₃ with alkyl groups and the remaining hydrogen atom with an aryl group. The arylheteroarylsilyl refers to a silyl group obtained by substituting one of the hydrogen atoms in-SiHs with an aryl group and the other two hydrogen atoms with heteroaryl groups or substituting two of the hydrogen atoms in —SiH₃ with aryl groups and the remaining hydrogen atom with a heteroaryl group. The heteroarylsilyl refers to a silyl group obtained by substituting one, two or three of the hydrogen atoms in-SiHs with heteroaryl groups. The arylsilyl group may be, for example, substituted or unsubstituted monoarylsilyl, substituted or unsubstituted diarylsilyl, or substituted or unsubstituted triarylsilyl. The same applies to the alkylsilyl and heteroarylsilyl groups.

Each of the aryl groups in the arylsilyl, heteroarylsilyl, and arylheteroarylsilyl groups may be a monocyclic or polycyclic one. Each of the heteroaryl groups in the arylsilyl, heteroarylsilyl, and arylheteroarylsilyl groups may be a monocyclic or polycyclic one.

Specific examples of the silyl groups include trimethylsilyl, triethylsilyl, triphenylsilyl, trimethoxysilyl, dimethoxyphenylsilyl, diphenylmethylsilyl, diphenylvinylsilyl, methylcyclobutylsilyl, and dimethylfurylsilyl. One or more of the hydrogen atoms in each of the silyl groups may be substituted with the substituents mentioned in the aryl groups.

The amine group is intended to include —NH₂, alkylamine, arylamine, arylheteroarylamine, and heteroarylamine. The arylamine refers to an amine group obtained by substituting one or two of the hydrogen atoms in —NH₂ with aryl groups. The alkylamine refers to an amine group obtained by substituting one or two of the hydrogen atoms in —NH₂ with alkyl groups. The alkylarylamine refers to an amine group obtained by substituting one of the hydrogen atoms in —NH₂ with an alkyl group and the other hydrogen atom with an aryl group. The arylheteroarylamine refers to an amine group obtained by substituting one of the hydrogen atoms in —NH₂ with an aryl group and the other hydrogen atom with a heteroaryl group. The heteroarylamine refers to an amine group obtained by substituting one or two of the hydrogen atoms in —NH₂ with heteroaryl groups. The arylamine may be, for example, substituted or unsubstituted monoarylamine, substituted or unsubstituted diarylamine, or substituted or unsubstituted triarylamine. The same applies to the alkylamine and heteroarylamine groups.

Each of the aryl groups in the arylamine, heteroarylamine, and arylheteroarylamine groups may be a monocyclic or polycyclic one. Each of the heteroaryl groups in the arylamine, heteroarylamine, and arylheteroarylamine groups may be a monocyclic or polycyclic one.

The germanium group is intended to include —GeH₃, alkylgermanium, arylgermanium, heteroarylgermanium, alkylarylgermanium, alkylheteroarylgermanium, and arylheteroarylgermanium. The definitions of the substituents in the germanium groups follow those described for the silyl groups, except that the silicon (Si) atom in each silyl group is changed to a germanium (Ge) atom.

Specific examples of the germanium groups include trimethylgermane, triethylgermane, triphenylgermane, trimethoxygermane, dimethoxyphenylgermane, diphenylmethylgermane, diphenylvinylgermane, methylcyclobutylgermane, and dimethylfurylgermane. One or more of the hydrogen atoms in each of the germanium groups may be substituted with the substituents mentioned in the aryl groups.

The cycloalkyl, aryl, and heteroaryl groups in the cycloalkyloxy, aryloxy, heteroaryloxy, cycloalkylthioxy, arylthioxy, and heteroarylthioxy groups are the same as those exemplified above. Specific examples of the aryloxy groups include, but are not limited to, phenoxy, p-tolyloxy, m-tolyloxy, 3,5-dimethylphenoxy, 2,4,6-trimethylphenoxy, p-tert-butylphenoxy, 3-biphenyloxy, 4-biphenyloxy, 1-naphthyloxy, 2-naphthyloxy, 4-methyl-1-naphthyloxy, 5-methyl-2-naphthyloxy, 1-anthryloxy, 2-anthryloxy, 9-anthryloxy, 1-phenanthryloxy, 3-phenanthryloxy, and 9-phenanthryloxy groups. Specific examples of the arylthioxy groups include, but are not limited to, phenylthioxy, 2-methylphenylthioxy, and 4-tert-butylphenylthioxy groups.

The halogen group may be, for example, fluorine, chlorine, bromine or iodine.

According to one embodiment of the present invention, the polycyclic compound represented by Formula 1 may be selected from the following compounds 1 to 60:

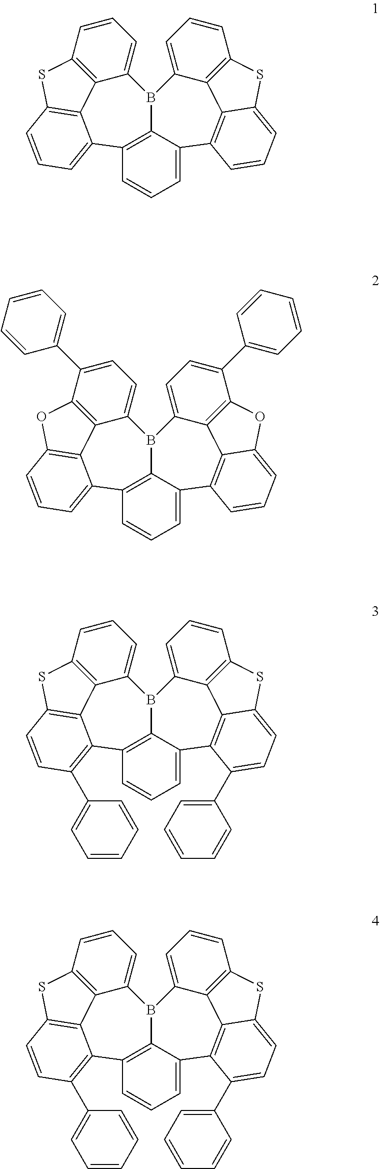 [SMILES: c1cc2c3c(c1)-c1cccc4sc5cccc(c5c14)B3c1cccc3sc4cccc-2c4c13 ; c1ccc(-c2ccc3c4c2oc2cccc(c24)-c2cccc4c2B3c2ccc(-c3ccccc3)c3oc5cccc-4c5c23)cc1 ; c1ccc(-c2ccc3sc4cccc5c4c3c2-c2cccc3c2B5c2cccc4sc5ccc(-c6ccccc6)c-3c5c24)cc1 ; c1ccc(-c2ccc3sc4cccc5c4c3c2-c2cccc3c2B5c2cccc4sc5ccc(-c6ccccc6)c-3c5c24)cc1]

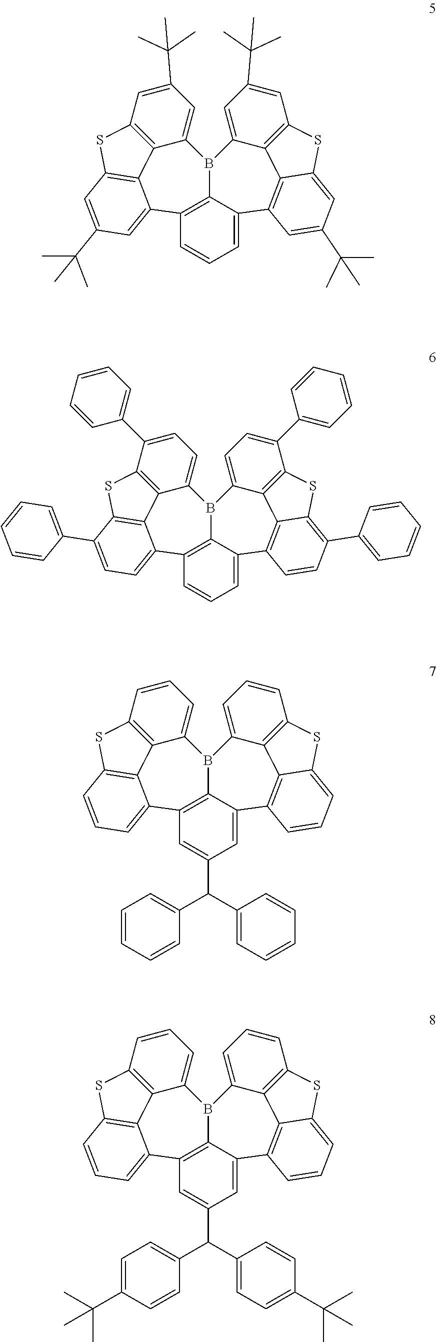

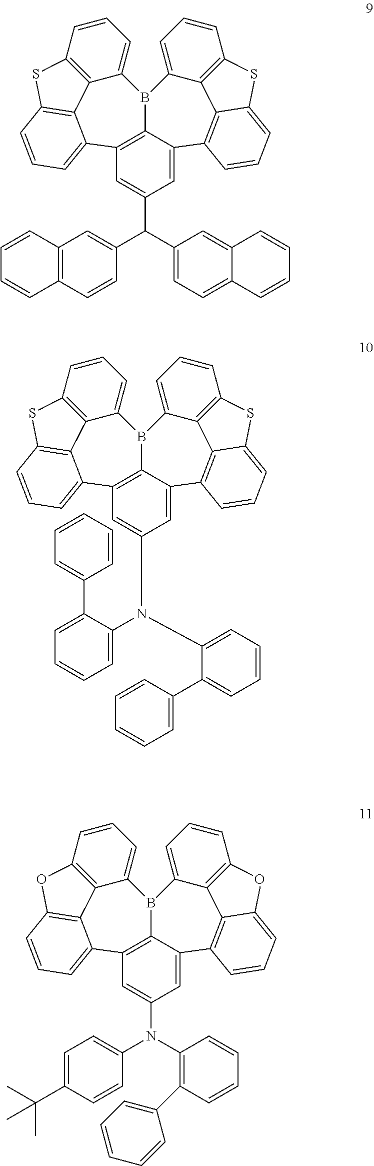 [SMILES: c1ccc2cc(C(c3cc4c5c(c3)-c3cccc6sc7cccc(c7c36)B5c3cccc5sc6cccc-4c6c35)c3ccc4ccccc4c3)ccc2c1 ; c1ccc(-c2ccccc2N(c2cc3c4c(c2)-c2cccc5sc6cccc(c6c25)B4c2cccc4sc5cccc-3c5c24)c2ccccc2-c2ccccc2)cc1 ; CC(C)(C)c1ccc(N(c2cc3c4c(c2)-c2cccc5oc6cccc(c6c25)B4c2cccc4oc5cccc-3c5c24)c2ccccc2-c2ccccc2)cc1]

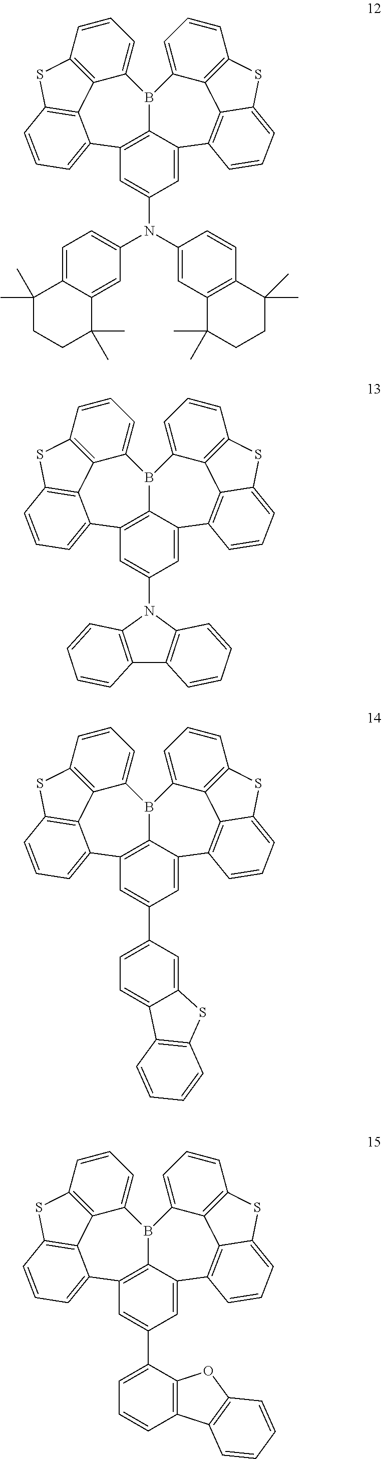

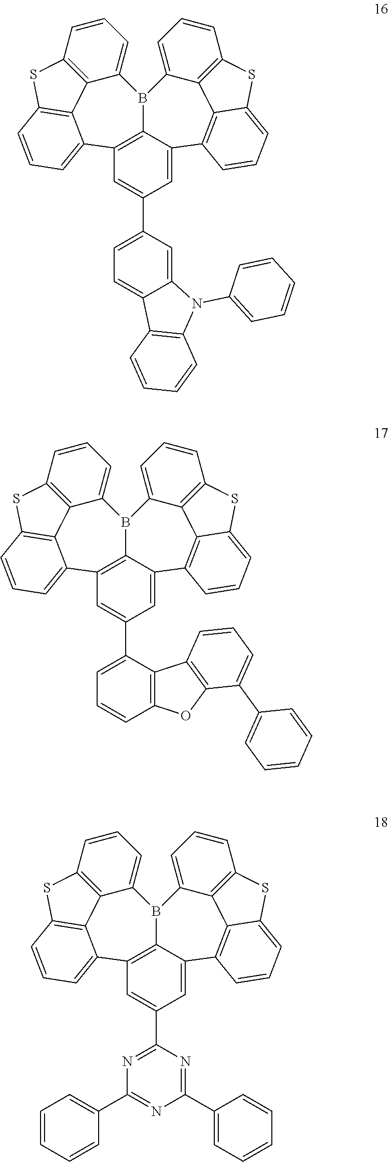 [SMILES: c1ccc(-n2c3ccccc3c3ccc(-c4cc5c6c(c4)-c4cccc7sc8cccc(c8c47)B6c4cccc6sc7cccc-5c7c46)cc32)cc1 ; c1ccc(-c2cccc3c2oc2cccc(-c4cc5c6c(c4)-c4cccc7sc8cccc(c8c47)B6c4cccc6sc7cccc-5c7c46)c23)cc1 ; c1ccc(-c2nc(-c3ccccc3)nc(-c3cc4c5c(c3)-c3cccc6sc7cccc(c7c36)B5c3cccc5sc6cccc-4c6c35)n2)cc1]

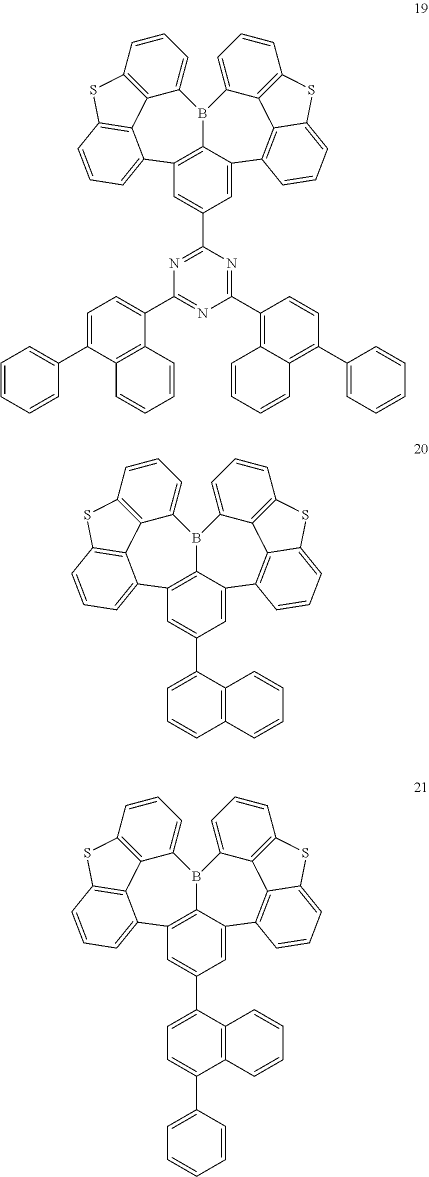 [SMILES: c1ccc(-c2ccc(-c3nc(-c4cc5c6c(c4)-c4cccc7sc8cccc(c8c47)B6c4cccc6sc7cccc-5c7c46)nc(-c4ccc(-c5ccccc5)c5ccccc45)n3)c3ccccc23)cc1 ; c1ccc2c(-c3cc4c5c(c3)-c3cccc6sc7cccc(c7c36)B5c3cccc5sc6cccc-4c6c35)cccc2c1 ; c1ccc(-c2ccc(-c3cc4c5c(c3)-c3cccc6sc7cccc(c7c36)B5c3cccc5sc6cccc-4c6c35)c3ccccc23)cc1]

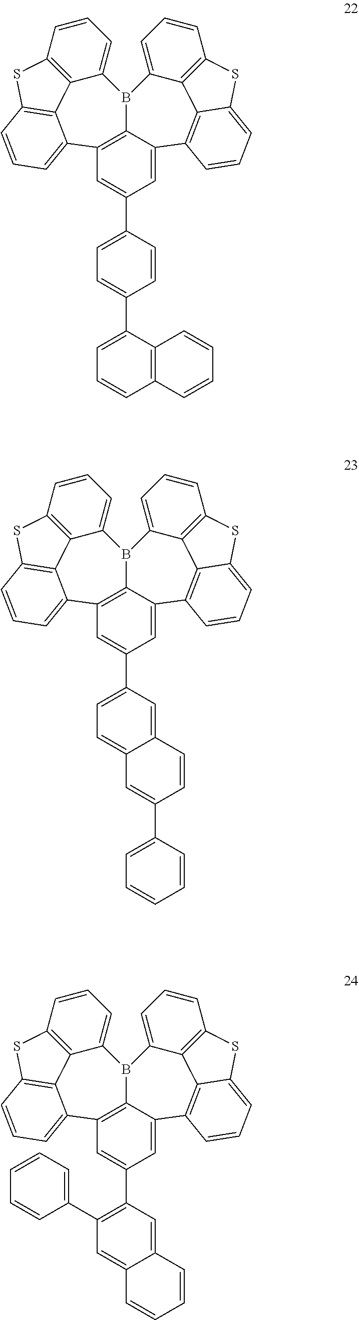 [SMILES: c1ccc2c(-c3ccc(-c4cc5c6c(c4)-c4cccc7sc8cccc(c8c47)B6c4cccc6sc7cccc-5c7c46)cc3)cccc2c1 ; c1ccc(-c2ccc3cc(-c4cc5c6c(c4)-c4cccc7sc8cccc(c8c47)B6c4cccc6sc7cccc-5c7c46)ccc3c2)cc1 ; c1ccc(-c2cc3ccccc3cc2-c2cc3c4c(c2)-c2cccc5sc6cccc(c6c25)B4c2cccc4sc5cccc-3c5c24)cc1]

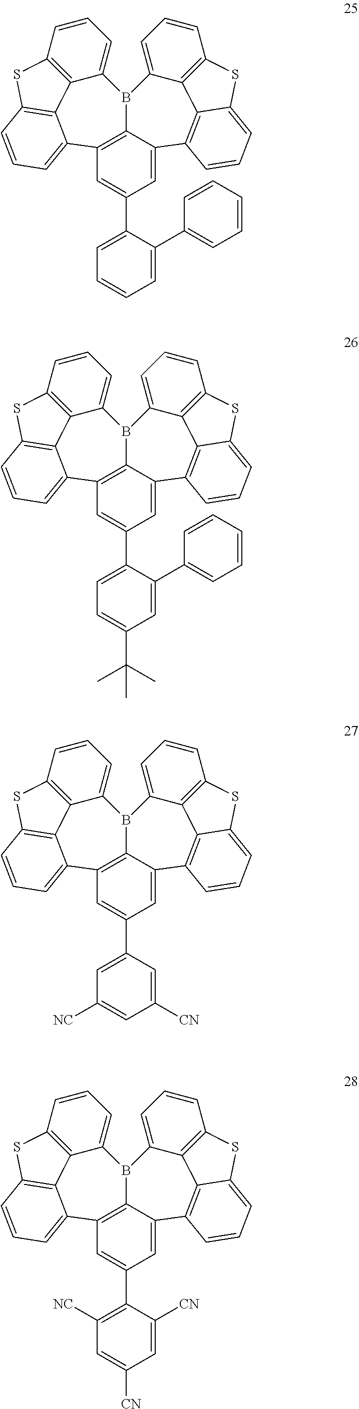 [SMILES: c1ccc(-c2ccccc2-c2cc3c4c(c2)-c2cccc5sc6cccc(c6c25)B4c2cccc4sc5cccc-3c5c24)cc1 ; CC(C)(C)c1ccc(-c2cc3c4c(c2)-c2cccc5sc6cccc(c6c25)B4c2cccc4sc5cccc-3c5c24)c(-c2ccccc2)c1 ; N#Cc1cc(C#N)cc(-c2cc3c4c(c2)-c2cccc5sc6cccc(c6c25)B4c2cccc4sc5cccc-3c5c24)c1 ; N#Cc1cc(C#N)c(-c2cc3c4c(c2)-c2cccc5sc6cccc(c6c25)B4c2cccc4sc5cccc-3c5c24)c(C#N)c1]

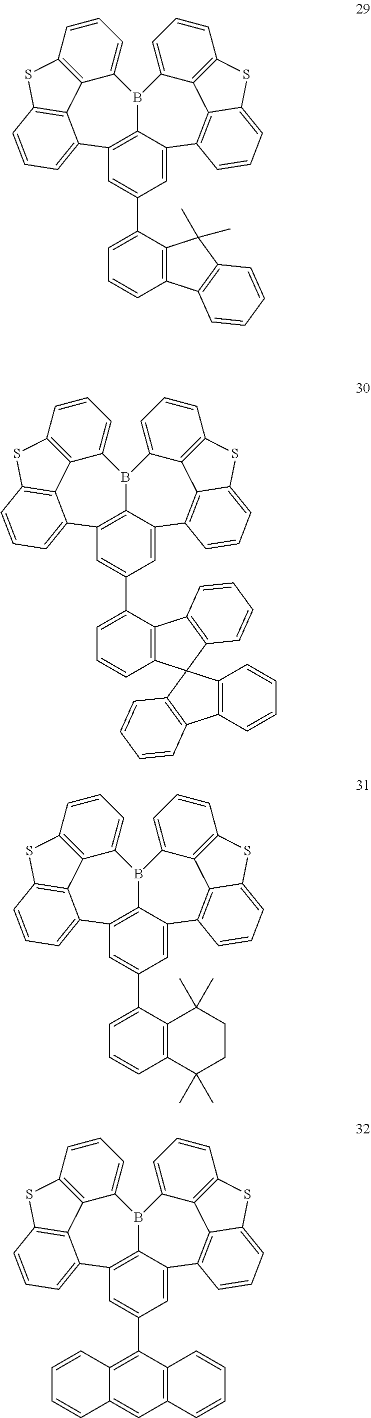

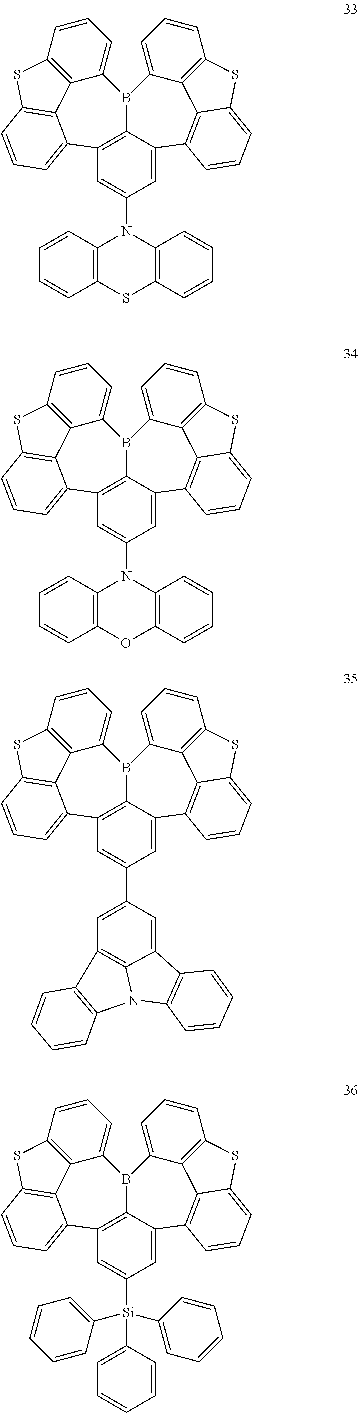 [SMILES: c1ccc2c(c1)Sc1ccccc1N2c1cc2c3c(c1)-c1cccc4sc5cccc(c5c14)B3c1cccc3sc4cccc-2c4c13 ; c1ccc2c(c1)Oc1ccccc1N2c1cc2c3c(c1)-c1cccc4sc5cccc(c5c14)B3c1cccc3sc4cccc-2c4c13 ; c1cc2c3c(c1)sc1cccc(c13)-c1cc(-c3cc4c5ccccc5n5c6ccccc6c(c3)c45)cc3c1B2c1cccc2sc4cccc-3c4c12 ; c1ccc([Si](c2ccccc2)(c2ccccc2)c2cc3c4c(c2)-c2cccc5sc6cccc(c6c25)B4c2cccc4sc5cccc-3c5c24)cc1]

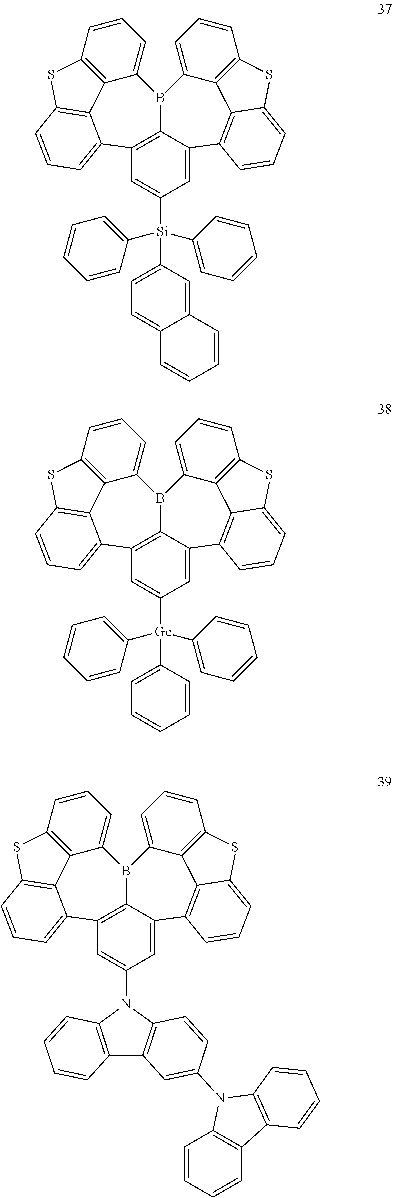

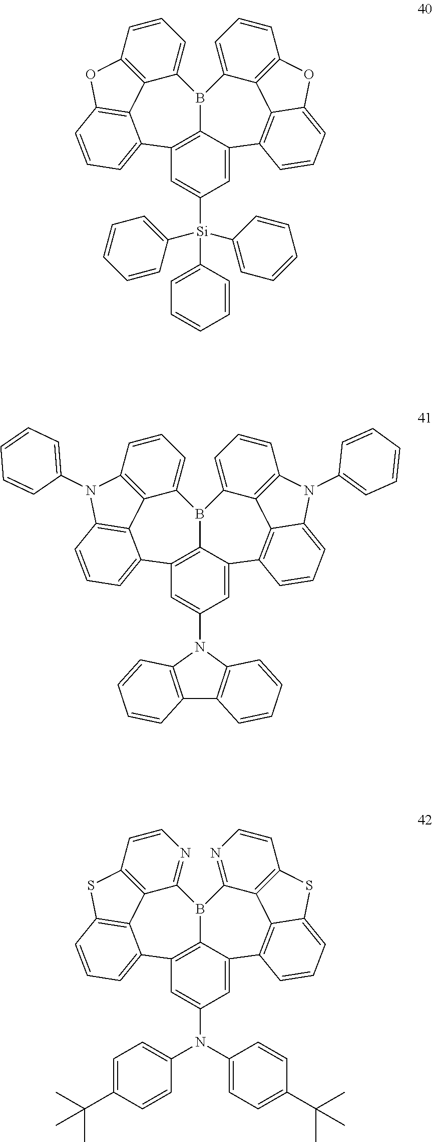 [SMILES: c1ccc([Si](c2ccccc2)(c2ccccc2)c2cc3c4c(c2)-c2cccc5oc6cccc(c6c25)B4c2cccc4oc5cccc-3c5c24)cc1 ; c1ccc(-n2c3cccc4c3c3c(cccc32)-c2cc(-n3c5ccccc5c5ccccc53)cc3c2B4c2cccc4c2c2c-3cccc2n4-c2ccccc2)cc1 ; CC(C)(C)c1ccc(N(c2ccc(C(C)(C)C)cc2)c2cc3c4c(c2)-c2cccc5sc6ccnc(c6c25)B4c2nccc4sc5cccc-3c5c24)cc1]

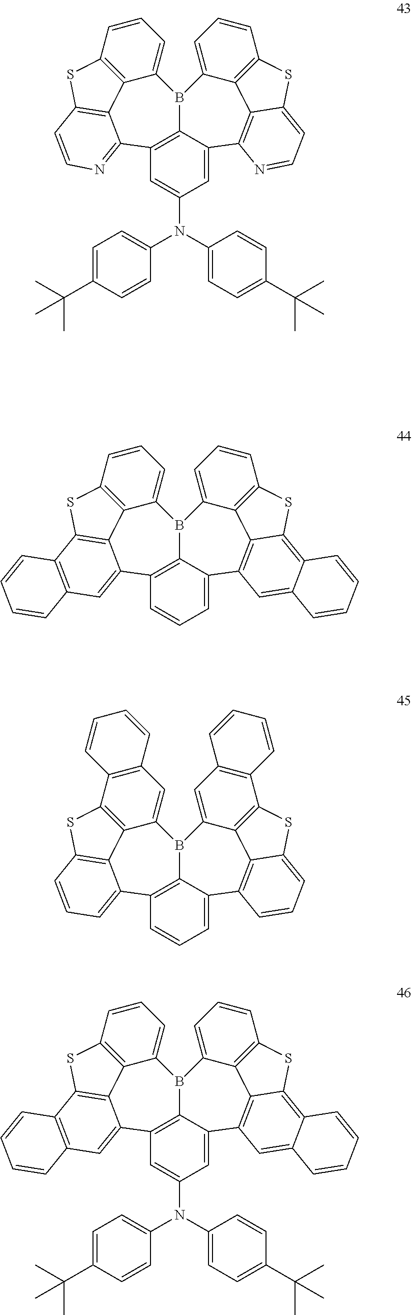 [SMILES: CC(C)(C)c1ccc(N(c2ccc(C(C)(C)C)cc2)c2cc3c4c(c2)-c2nccc5sc6cccc(c6c25)B4c2cccc4sc5ccnc-3c5c24)cc1 ; c1cc2c3c(c1)-c1cc4ccccc4c4sc5cccc(c5c14)B3c1cccc3sc4c5ccccc5cc-2c4c13 ; c1cc2c3c(c1)-c1cccc4sc5c6ccccc6cc(c5c14)B3c1cc3ccccc3c3sc4cccc-2c4c13 ; CC(C)(C)c1ccc(N(c2ccc(C(C)(C)C)cc2)c2cc3c4c(c2)-c2cc5ccccc5c5sc6cccc(c6c25)B4c2cccc4sc5c6ccccc6cc-3c5c24)cc1]

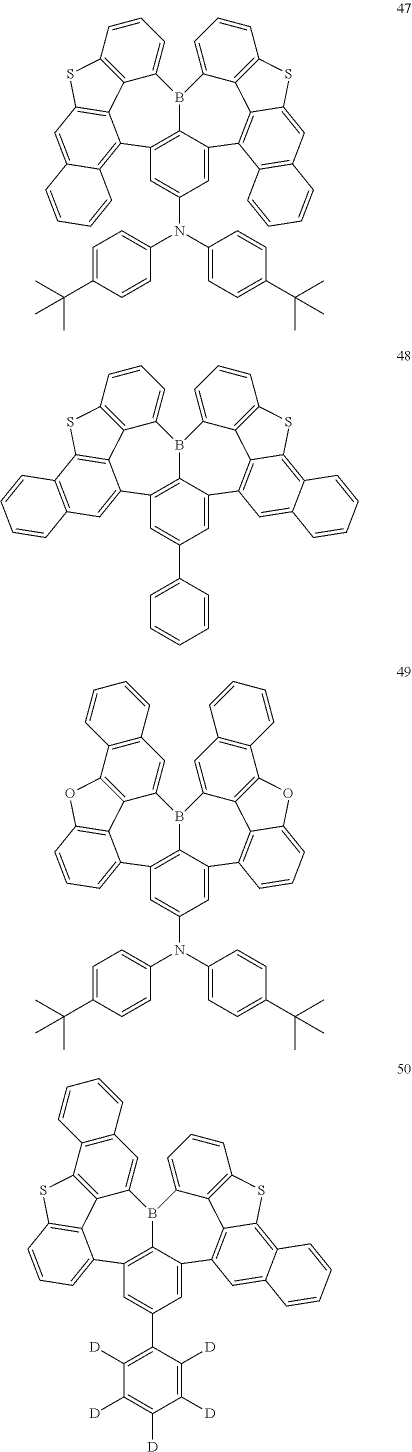

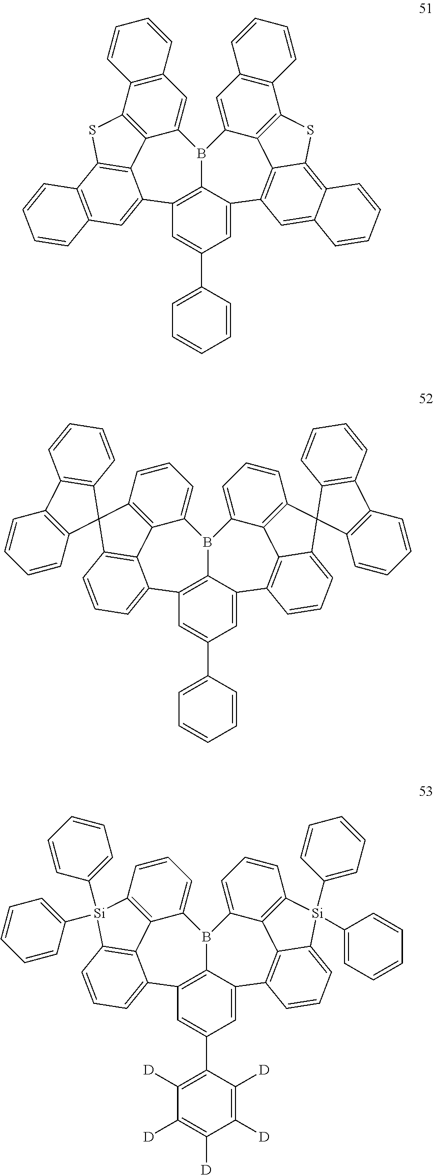 [SMILES: c1ccc(-c2cc3c4c(c2)-c2cc5ccccc5c5sc6c7ccccc7cc(c6c25)B4c2cc4ccccc4c4sc5c6ccccc6cc-3c5c24)cc1 ; c1ccc(-c2cc3c4c(c2)-c2cccc5c2-c2c(cccc2C52c5ccccc5-c5ccccc52)B4c2cccc4c2-c2c-3cccc2C42c3ccccc3-c3ccccc32)cc1 ; [2H]c1c([2H])c([2H])c(-c2cc3c4c(c2)-c2cccc5c2-c2c(cccc2[Si]5(c2ccccc2)c2ccccc2)B4c2cccc4c2-c2c-3cccc2[Si]4(c2ccccc2)c2ccccc2)c([2H])c1[2H]]

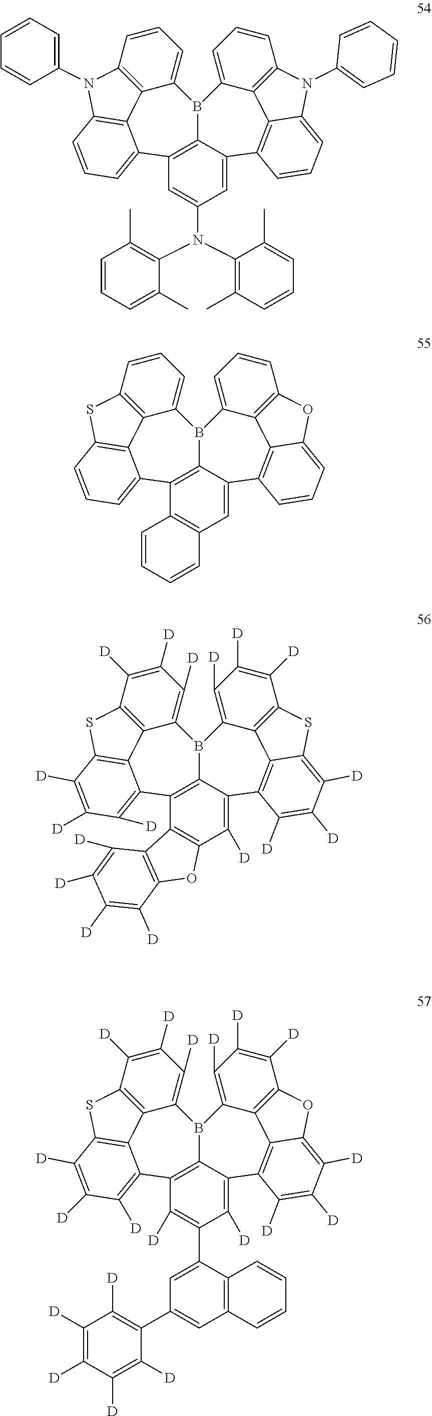

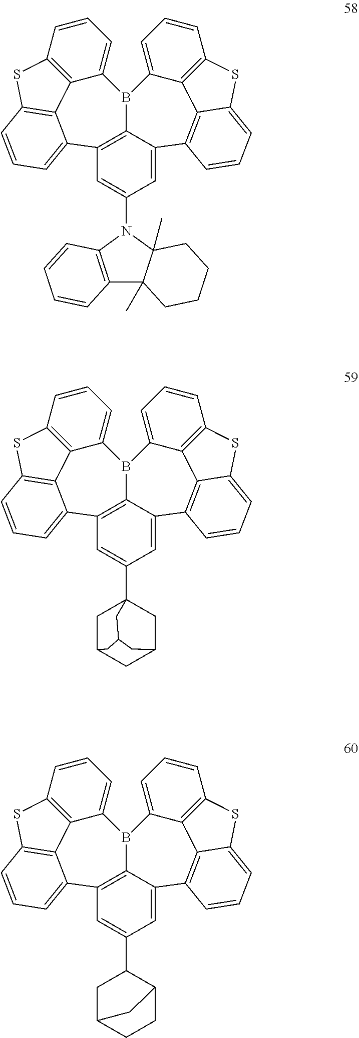 [SMILES: CC12CCCCC1(C)N(c1cc3c4c(c1)-c1cccc5sc6cccc(c6c15)B4c1cccc4sc5cccc-3c5c14)c1ccccc12 ; c1cc2c3c(c1)sc1cccc(c13)-c1cc(C34CC5CC(CC(C5)C3)C4)cc3c1B2c1cccc2sc4cccc-3c4c12 ; c1cc2c3c(c1)sc1cccc(c13)-c1cc(C3CC4CCC3C4)cc3c1B2c1cccc2sc4cccc-3c4c12]

However, these compounds are not intended to limit the scope of Formula 1.

A further aspect of the present invention is directed to an organic light emitting device including a first electrode, a second electrode, and one or more organic layers interposed between the first and second electrodes wherein one of the organic layers, preferably a light emitting layer includes the compound represented by Formula 1 as a dopant.

The light emitting layer may further include a host material. In this case, the content of the dopant in the light emitting layer is typically in the range of about 0.01 to about 20 parts by weight, based on about 100 parts by weight of the host but is not limited to this range.

The light emitting layer may further include one or more other dopants and one or more other host materials. In this case, the hosts and the dopant materials may be mixed or stacked in the light emitting layer.

According to one embodiment of the present invention, the host compound employed in the light emitting layer may be an anthracene compound represented by Formula 2:

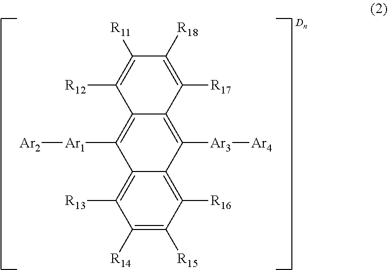

wherein R₁₁ to R₁₈ are the same as or different from each other and are each independently selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, cyclic groups in which a substituted or unsubstituted C₃-C₃₀ aliphatic ring and a C₅-C₃₀ aromatic ring are fused together, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, nitro, cyano, and halogen, Ar₁ and Ar₃ are the same as or different from each other and are each independently a single bond or selected from substituted or unsubstituted C₆-C₃₀ arylene, substituted or unsubstituted C₅-C₃₀ heteroarylene, and divalent cyclic groups in which a substituted or unsubstituted C₃-C₃₀ aliphatic ring and a C₅-C₃₀ aromatic ring are fused together, Ar₂ and Ar₄ are the same as or different from each other and are each independently selected from substituted or unsubstituted C₆-C₅₀ aryl, substituted or unsubstituted C₃-C₃₀ cycloalkyl, substituted or unsubstituted C₃-C₃₀ heterocycloalkyl, substituted or unsubstituted C₂-C₅₀ heteroaryl, and cyclic groups in which a substituted or unsubstituted C₃-C₃₀ aliphatic ring and a C₅-C₃₀ aromatic ring are fused together, Dₙ represents the number of deuterium atoms replacing hydrogen atoms, and n is an integer from 0 to 50.

According to one embodiment of the present invention, the anthracene compound represented by Formula 2 may be selected from the following compounds:

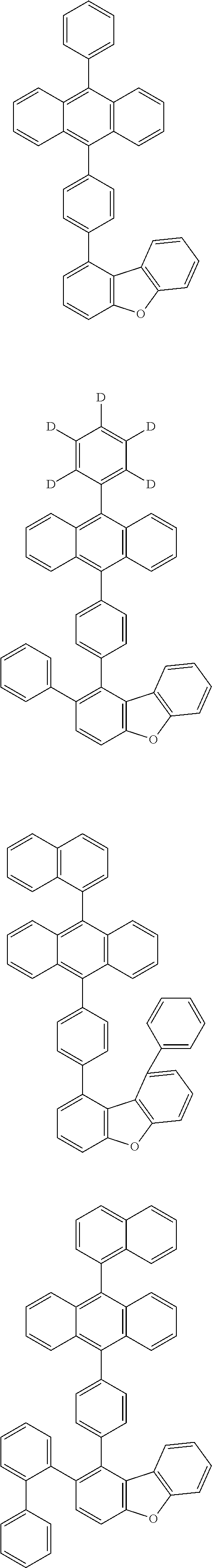 [SMILES: c1ccc(-c2c3ccccc3c(-c3ccc(-c4cccc5oc6ccccc6c45)cc3)c3ccccc23)cc1 ; [2H]c1c([2H])c([2H])c(-c2c3ccccc3c(-c3ccc(-c4c(-c5ccccc5)ccc5oc6ccccc6c45)cc3)c3ccccc23)c([2H])c1[2H] ; c1ccc(-c2cccc3oc4cccc(-c5ccc(-c6c7ccccc7c(-c7cccc8ccccc78)c7ccccc67)cc5)c4c23)cc1 ; c1ccc(-c2ccccc2-c2ccc3oc4ccccc4c3c2-c2ccc(-c3c4ccccc4c(-c4cccc5ccccc45)c4ccccc34)cc2)cc1]

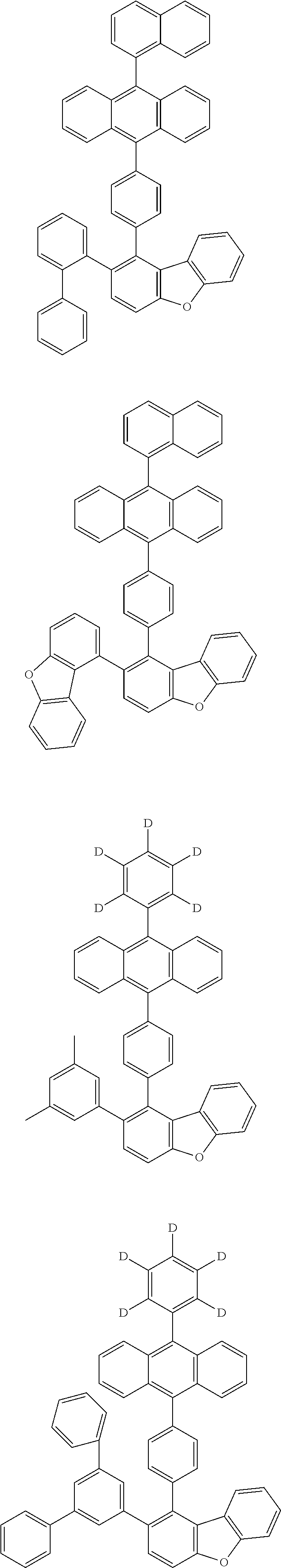 [SMILES: c1ccc(-c2ccccc2-c2ccc3oc4ccccc4c3c2-c2ccc(-c3c4ccccc4c(-c4cccc5ccccc45)c4ccccc34)cc2)cc1 ; c1ccc2c(-c3c4ccccc4c(-c4ccc(-c5c(-c6cccc7oc8ccccc8c67)ccc6oc7ccccc7c56)cc4)c4ccccc34)cccc2c1 ; [2H]c1c([2H])c([2H])c(-c2c3ccccc3c(-c3ccc(-c4c(-c5cc(C)cc(C)c5)ccc5oc6ccccc6c45)cc3)c3ccccc23)c([2H])c1[2H] ; [2H]c1c([2H])c([2H])c(-c2c3ccccc3c(-c3ccc(-c4c(-c5cc(-c6ccccc6)cc(-c6ccccc6)c5)ccc5oc6ccccc6c45)cc3)c3ccccc23)c([2H])c1[2H]]

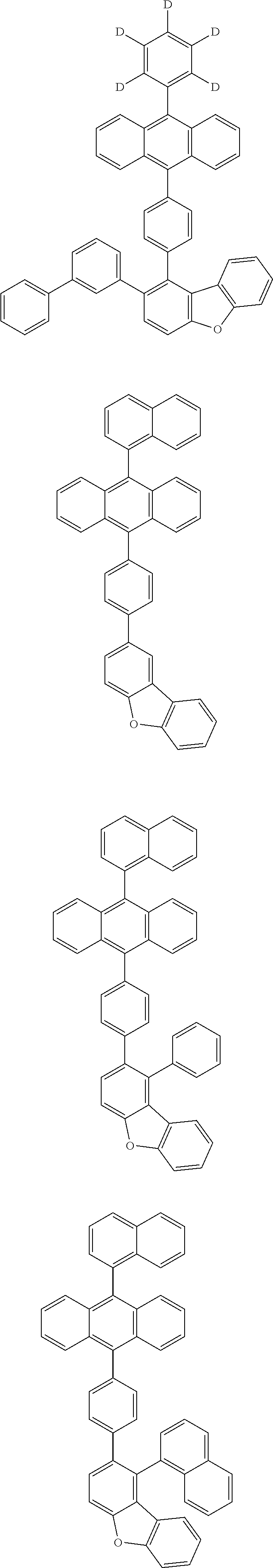 [SMILES: [2H]c1c([2H])c([2H])c(-c2c3ccccc3c(-c3ccc(-c4c(-c5cccc(-c6ccccc6)c5)ccc5oc6ccccc6c45)cc3)c3ccccc23)c([2H])c1[2H] ; c1ccc2c(-c3c4ccccc4c(-c4ccc(-c5ccc6oc7ccccc7c6c5)cc4)c4ccccc34)cccc2c1 ; c1ccc(-c2c(-c3ccc(-c4c5ccccc5c(-c5cccc6ccccc56)c5ccccc45)cc3)ccc3oc4ccccc4c23)cc1 ; c1ccc2c(-c3c4ccccc4c(-c4ccc(-c5ccc6oc7ccccc7c6c5-c5cccc6ccccc56)cc4)c4ccccc34)cccc2c1]

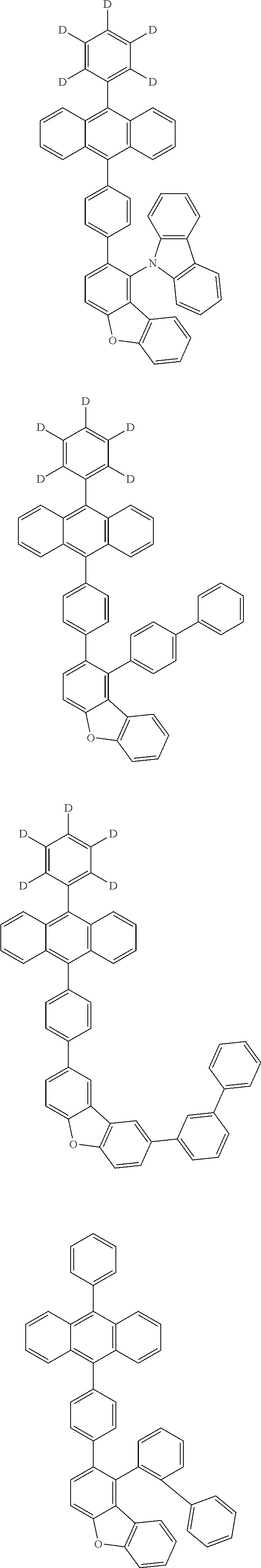 [SMILES: [2H]c1c([2H])c([2H])c(-c2c3ccccc3c(-c3ccc(-c4ccc5oc6ccccc6c5c4-n4c5ccccc5c5ccccc54)cc3)c3ccccc23)c([2H])c1[2H] ; [2H]c1c([2H])c([2H])c(-c2c3ccccc3c(-c3ccc(-c4ccc5oc6ccccc6c5c4-c4ccc(-c5ccccc5)cc4)cc3)c3ccccc23)c([2H])c1[2H] ; [2H]c1c([2H])c([2H])c(-c2c3ccccc3c(-c3ccc(-c4ccc5oc6ccc(-c7cccc(-c8ccccc8)c7)cc6c5c4)cc3)c3ccccc23)c([2H])c1[2H] ; c1ccc(-c2ccccc2-c2c(-c3ccc(-c4c5ccccc5c(-c5ccccc5)c5ccccc45)cc3)ccc3oc4ccccc4c23)cc1]

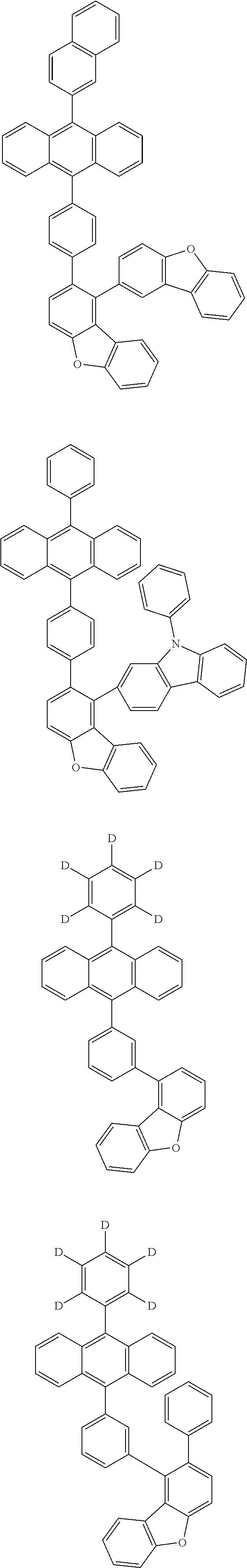 [SMILES: c1ccc2cc(-c3c4ccccc4c(-c4ccc(-c5ccc6oc7ccccc7c6c5-c5ccc6oc7ccccc7c6c5)cc4)c4ccccc34)ccc2c1 ; c1ccc(-c2c3ccccc3c(-c3ccc(-c4ccc5oc6ccccc6c5c4-c4ccc5c6ccccc6n(-c6ccccc6)c5c4)cc3)c3ccccc23)cc1 ; [2H]c1c([2H])c([2H])c(-c2c3ccccc3c(-c3cccc(-c4cccc5oc6ccccc6c45)c3)c3ccccc23)c([2H])c1[2H] ; [2H]c1c([2H])c([2H])c(-c2c3ccccc3c(-c3cccc(-c4c(-c5ccccc5)ccc5oc6ccccc6c45)c3)c3ccccc23)c([2H])c1[2H]]

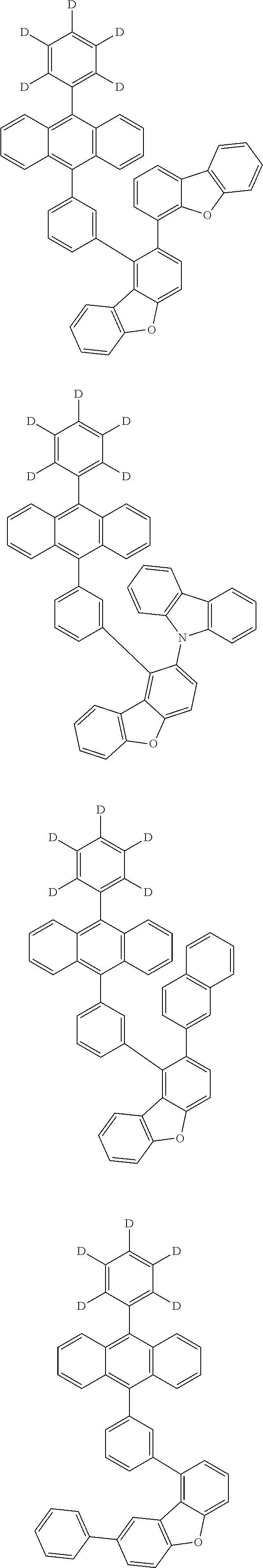 [SMILES: [2H]c1c([2H])c([2H])c(-c2c3ccccc3c(-c3cccc(-c4c(-c5cccc6c5oc5ccccc56)ccc5oc6ccccc6c45)c3)c3ccccc23)c([2H])c1[2H] ; [2H]c1c([2H])c([2H])c(-c2c3ccccc3c(-c3cccc(-c4c(-n5c6ccccc6c6ccccc65)ccc5oc6ccccc6c45)c3)c3ccccc23)c([2H])c1[2H] ; [2H]c1c([2H])c([2H])c(-c2c3ccccc3c(-c3cccc(-c4c(-c5ccc6ccccc6c5)ccc5oc6ccccc6c45)c3)c3ccccc23)c([2H])c1[2H] ; [2H]c1c([2H])c([2H])c(-c2c3ccccc3c(-c3cccc(-c4cccc5oc6ccc(-c7ccccc7)cc6c45)c3)c3ccccc23)c([2H])c1[2H]]

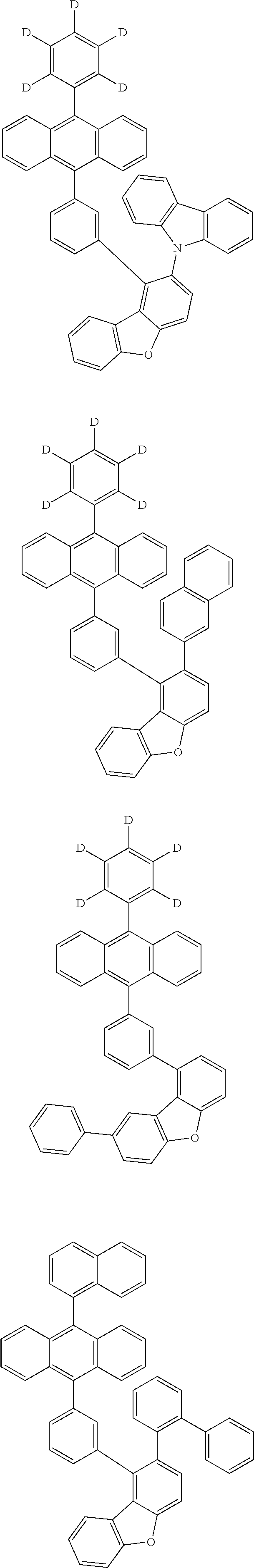 [SMILES: [2H]c1c([2H])c([2H])c(-c2c3ccccc3c(-c3cccc(-c4c(-n5c6ccccc6c6ccccc65)ccc5oc6ccccc6c45)c3)c3ccccc23)c([2H])c1[2H] ; [2H]c1c([2H])c([2H])c(-c2c3ccccc3c(-c3cccc(-c4c(-c5ccc6ccccc6c5)ccc5oc6ccccc6c45)c3)c3ccccc23)c([2H])c1[2H] ; [2H]c1c([2H])c([2H])c(-c2c3ccccc3c(-c3cccc(-c4cccc5oc6ccc(-c7ccccc7)cc6c45)c3)c3ccccc23)c([2H])c1[2H] ; c1ccc(-c2ccccc2-c2ccc3oc4ccccc4c3c2-c2cccc(-c3c4ccccc4c(-c4cccc5ccccc45)c4ccccc34)c2)cc1]

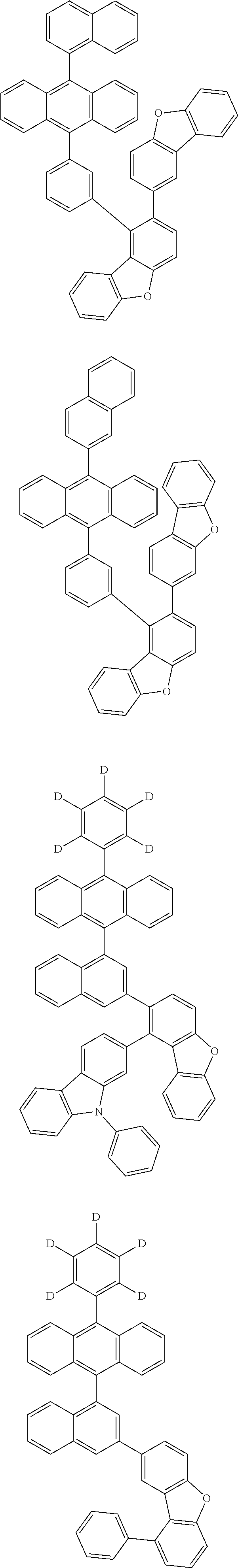

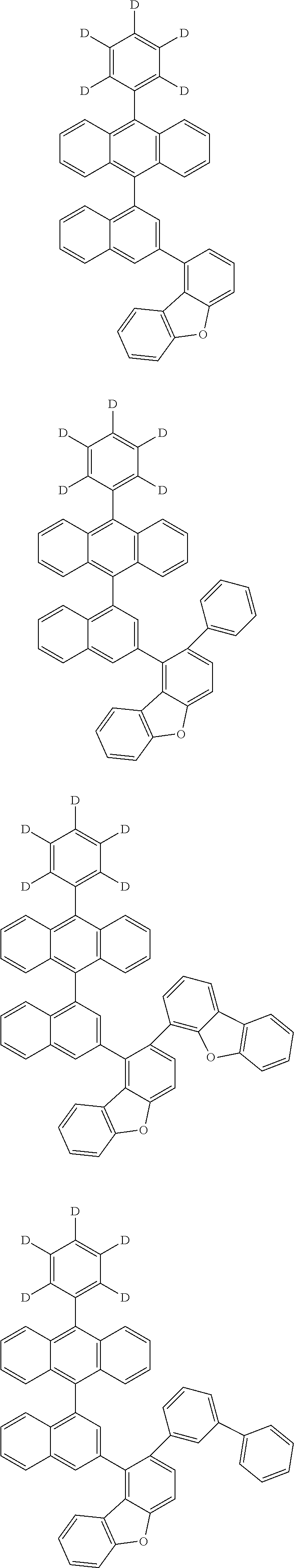 [SMILES: [2H]c1c([2H])c([2H])c(-c2c3ccccc3c(-c3cc(-c4cccc5oc6ccccc6c45)cc4ccccc34)c3ccccc23)c([2H])c1[2H] ; [2H]c1c([2H])c([2H])c(-c2c3ccccc3c(-c3cc(-c4c(-c5ccccc5)ccc5oc6ccccc6c45)cc4ccccc34)c3ccccc23)c([2H])c1[2H] ; [2H]c1c([2H])c([2H])c(-c2c3ccccc3c(-c3cc(-c4c(-c5cccc6c5oc5ccccc56)ccc5oc6ccccc6c45)cc4ccccc34)c3ccccc23)c([2H])c1[2H] ; [2H]c1c([2H])c([2H])c(-c2c3ccccc3c(-c3cc(-c4c(-c5cccc(-c6ccccc6)c5)ccc5oc6ccccc6c45)cc4ccccc34)c3ccccc23)c([2H])c1[2H]]

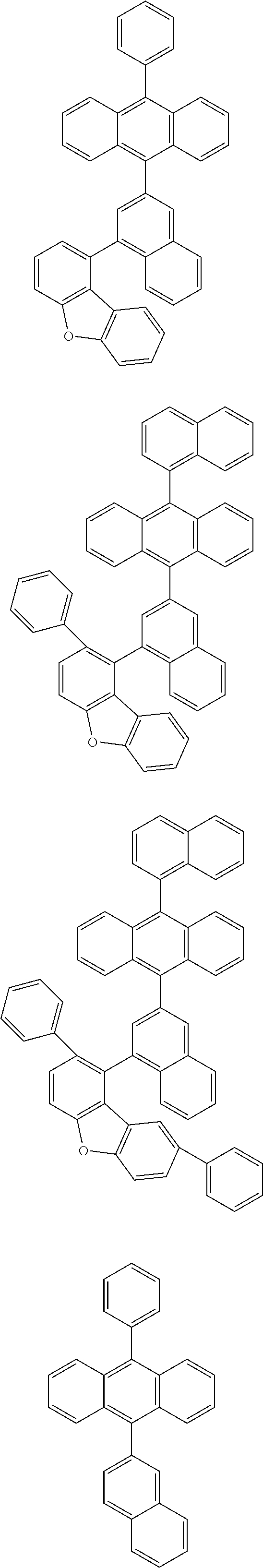

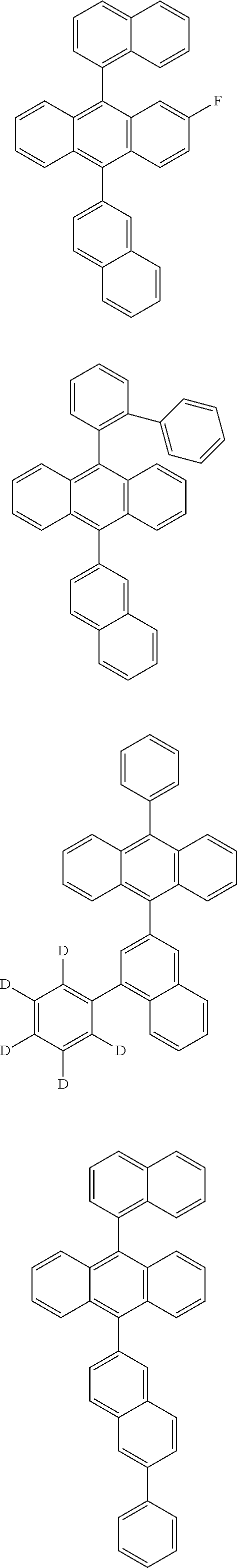

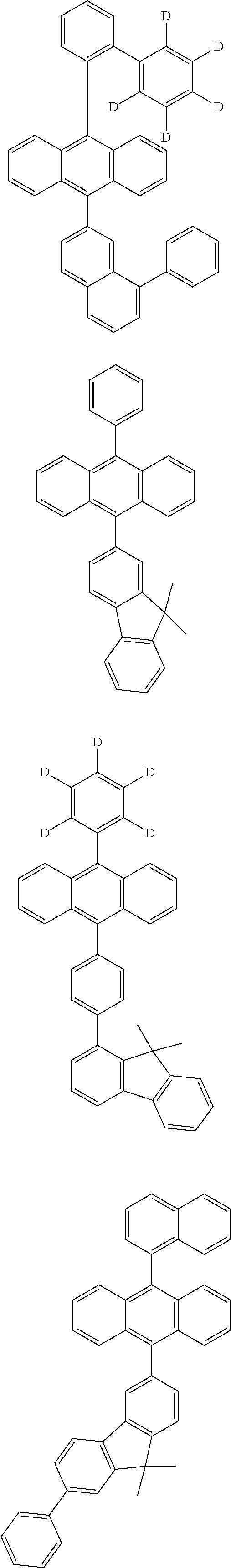

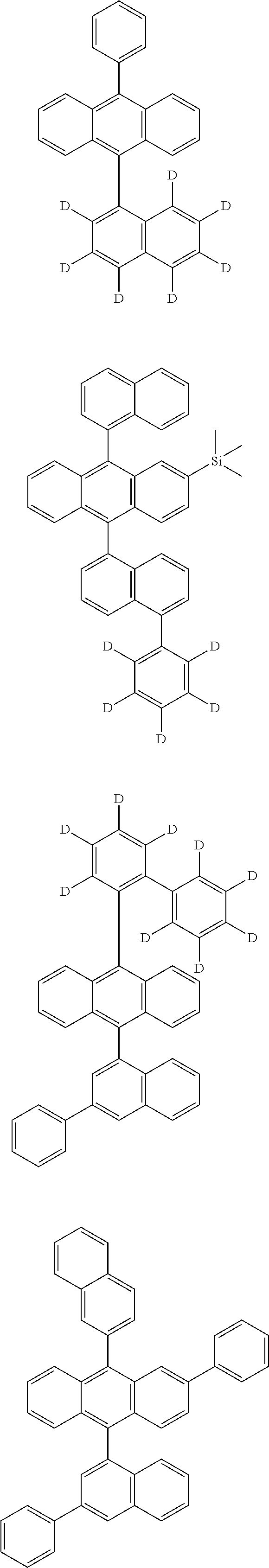

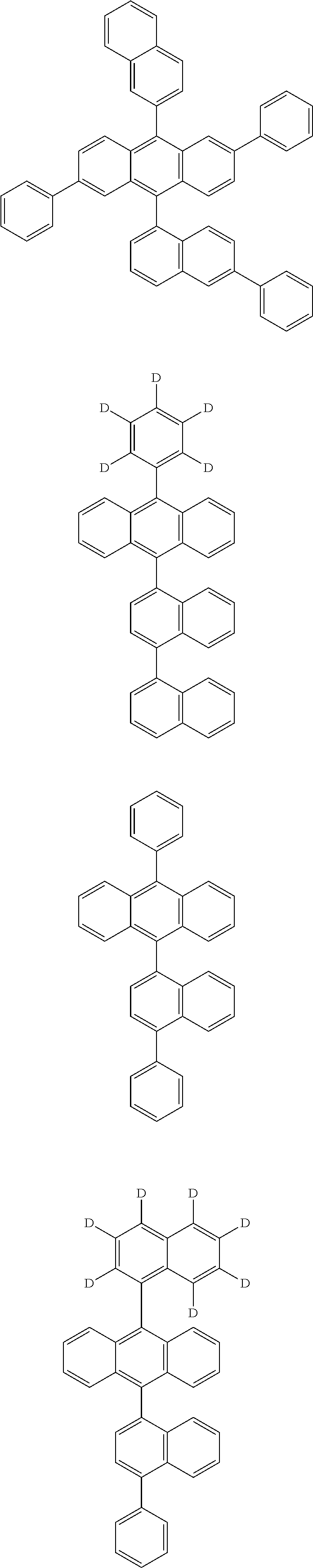

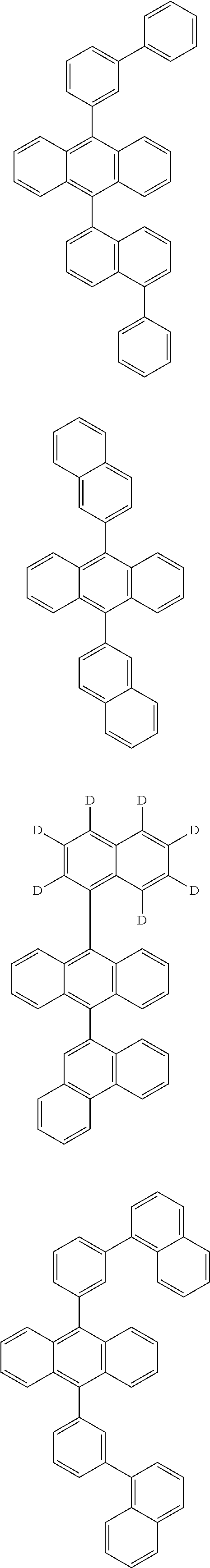

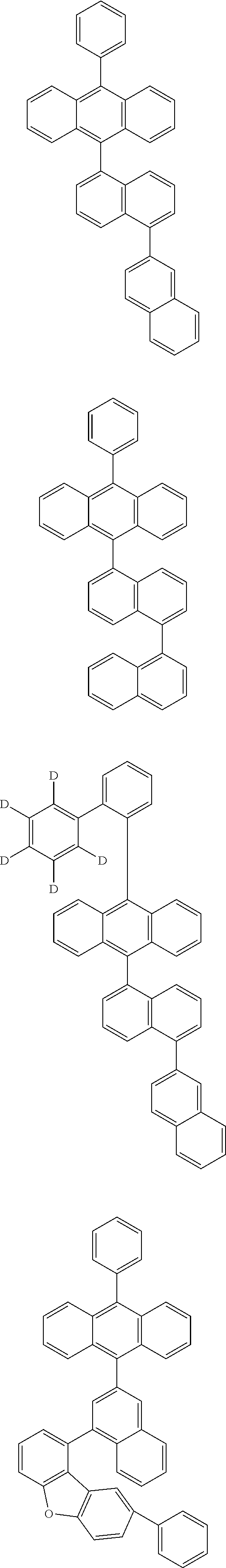

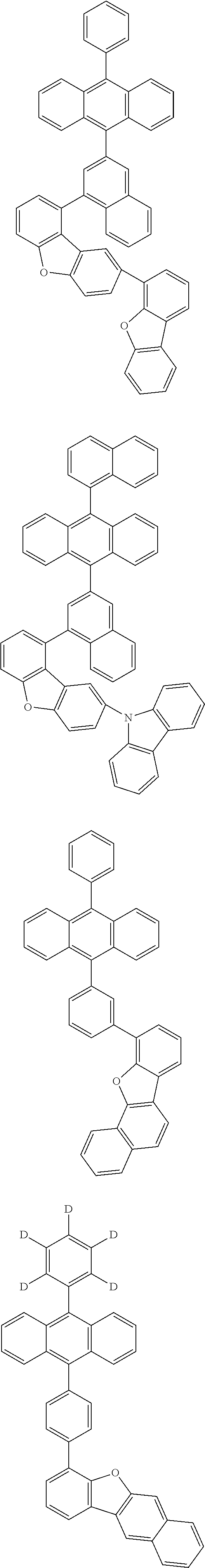 [SMILES: c1ccc(-c2c3ccccc3c(-c3cc(-c4cccc5oc6ccc(-c7cccc8c7oc7ccccc78)cc6c45)c4ccccc4c3)c3ccccc23)cc1 ; c1ccc2c(-c3c4ccccc4c(-c4cc(-c5cccc6oc7ccc(-n8c9ccccc9c9ccccc98)cc7c56)c5ccccc5c4)c4ccccc34)cccc2c1 ; c1ccc(-c2c3ccccc3c(-c3cccc(-c4cccc5c4oc4c6ccccc6ccc54)c3)c3ccccc23)cc1 ; [2H]c1c([2H])c([2H])c(-c2c3ccccc3c(-c3ccc(-c4cccc5c4oc4cc6ccccc6cc45)cc3)c3ccccc23)c([2H])c1[2H]]

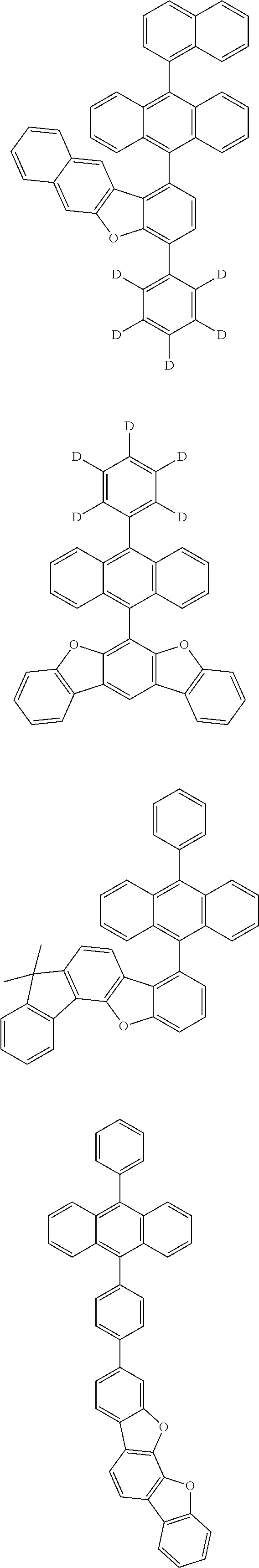 [SMILES: [2H]c1c([2H])c([2H])c(-c2ccc(-c3c4ccccc4c(-c4cccc5ccccc45)c4ccccc34)c3c2oc2cc4ccccc4cc23)c([2H])c1[2H] ; [2H]c1c([2H])c([2H])c(-c2c3ccccc3c(-c3c4oc5ccccc5c4cc4c3oc3ccccc34)c3ccccc23)c([2H])c1[2H] ; CC1(C)c2ccccc2-c2c1ccc1c2oc2cccc(-c3c4ccccc4c(-c4ccccc4)c4ccccc34)c21 ; c1ccc(-c2c3ccccc3c(-c3ccc(-c4ccc5c(c4)oc4c5ccc5c6ccccc6oc54)cc3)c3ccccc23)cc1]

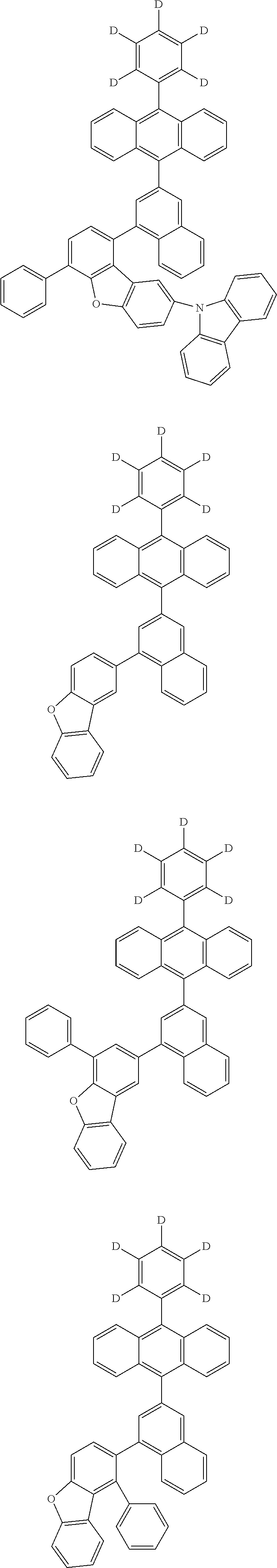

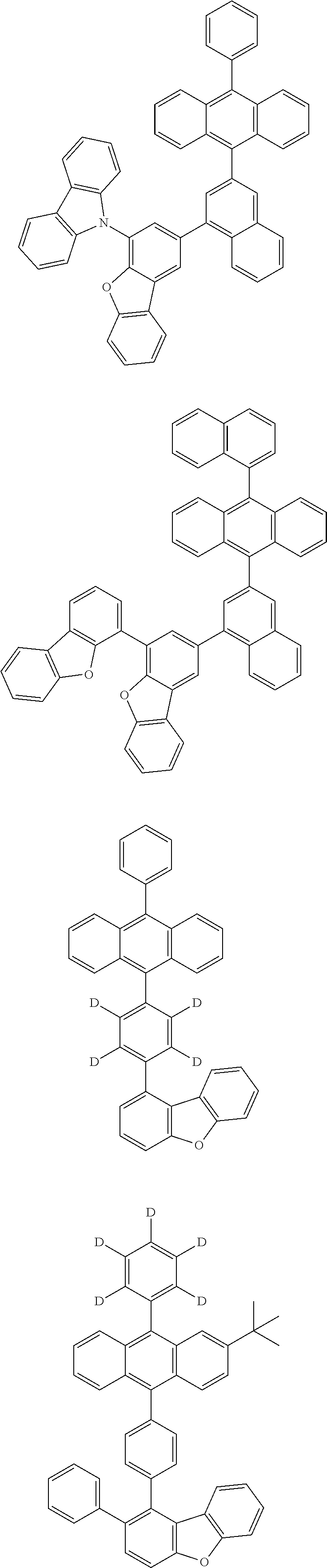 [SMILES: c1ccc(-c2c3ccccc3c(-c3cc(-c4cc(-n5c6ccccc6c6ccccc65)c5oc6ccccc6c5c4)c4ccccc4c3)c3ccccc23)cc1 ; c1ccc2c(-c3cc(-c4cccc5c4oc4ccccc45)c4oc5ccccc5c4c3)cc(-c3c4ccccc4c(-c4cccc5ccccc45)c4ccccc34)cc2c1 ; [2H]c1c([2H])c(-c2cccc3oc4ccccc4c23)c([2H])c([2H])c1-c1c2ccccc2c(-c2ccccc2)c2ccccc12 ; [2H]c1c([2H])c([2H])c(-c2c3ccccc3c(-c3ccc(-c4c(-c5ccccc5)ccc5oc6ccccc6c45)cc3)c3ccc(C(C)(C)C)cc23)c([2H])c1[2H]]

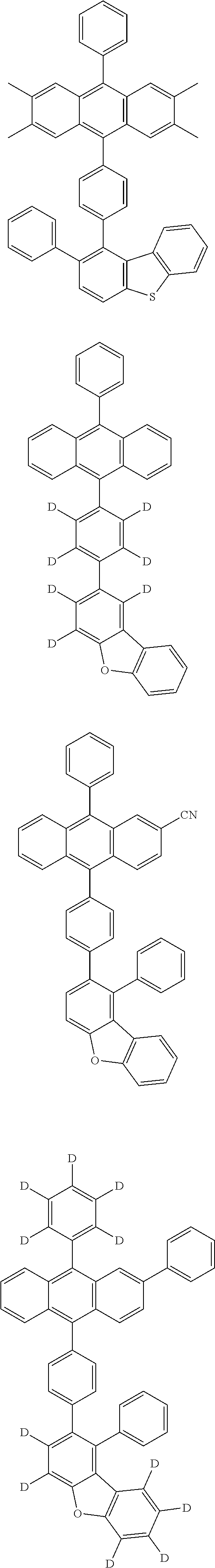 [SMILES: Cc1cc2c(-c3ccccc3)c3cc(C)c(C)cc3c(-c3ccc(-c4c(-c5ccccc5)ccc5sc6ccccc6c45)cc3)c2cc1C ; [2H]c1c([2H])c(-c2c3ccccc3c(-c3ccccc3)c3ccccc23)c([2H])c([2H])c1-c1c([2H])c([2H])c2oc3ccccc3c2c1[2H] ; N#Cc1ccc2c(-c3ccc(-c4ccc5oc6ccccc6c5c4-c4ccccc4)cc3)c3ccccc3c(-c3ccccc3)c2c1 ; [2H]c1c([2H])c([2H])c(-c2c3ccccc3c(-c3ccc(-c4c([2H])c([2H])c5oc6c([2H])c([2H])c([2H])c([2H])c6c5c4-c4ccccc4)cc3)c3ccc(-c4ccccc4)cc23)c([2H])c1[2H]]

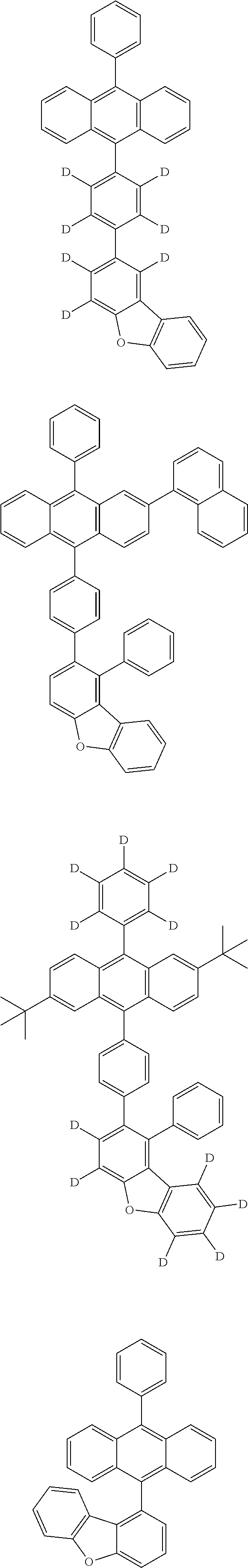 [SMILES: [2H]c1c([2H])c(-c2c3ccccc3c(-c3ccccc3)c3ccccc23)c([2H])c([2H])c1-c1c([2H])c([2H])c2oc3ccccc3c2c1[2H] ; c1ccc(-c2c3ccccc3c(-c3ccc(-c4ccc5oc6ccccc6c5c4-c4ccccc4)cc3)c3ccc(-c4cccc5ccccc45)cc23)cc1 ; [2H]c1c([2H])c([2H])c(-c2c3ccc(C(C)(C)C)cc3c(-c3ccc(-c4c([2H])c([2H])c5oc6c([2H])c([2H])c([2H])c([2H])c6c5c4-c4ccccc4)cc3)c3ccc(C(C)(C)C)cc23)c([2H])c1[2H] ; c1ccc(-c2c3ccccc3c(-c3cccc4oc5ccccc5c34)c3ccccc23)cc1]

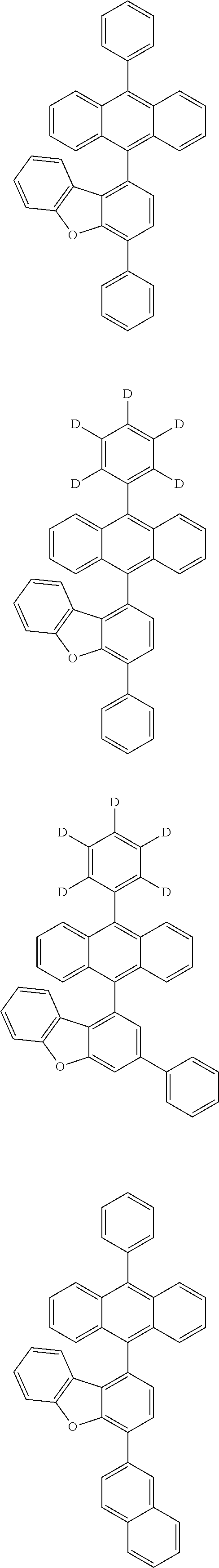 [SMILES: c1ccc(-c2c3ccccc3c(-c3ccc(-c4ccccc4)c4oc5ccccc5c34)c3ccccc23)cc1 ; [2H]c1c([2H])c([2H])c(-c2c3ccccc3c(-c3ccc(-c4ccccc4)c4oc5ccccc5c34)c3ccccc23)c([2H])c1[2H] ; [2H]c1c([2H])c([2H])c(-c2c3ccccc3c(-c3cc(-c4ccccc4)cc4oc5ccccc5c34)c3ccccc23)c([2H])c1[2H] ; c1ccc(-c2c3ccccc3c(-c3ccc(-c4ccc5ccccc5c4)c4oc5ccccc5c34)c3ccccc23)cc1]

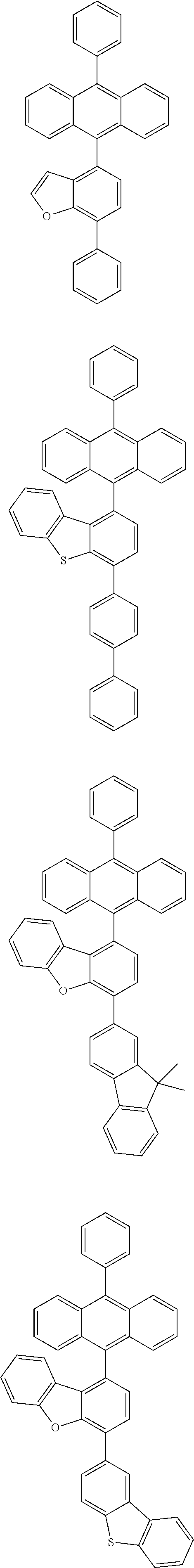 [SMILES: c1ccc(-c2c3ccccc3c(-c3ccc(-c4ccccc4)c4occc34)c3ccccc23)cc1 ; c1ccc(-c2ccc(-c3ccc(-c4c5ccccc5c(-c5ccccc5)c5ccccc45)c4c3sc3ccccc34)cc2)cc1 ; CC1(C)c2ccccc2-c2ccc(-c3ccc(-c4c5ccccc5c(-c5ccccc5)c5ccccc45)c4c3oc3ccccc34)cc21 ; c1ccc(-c2c3ccccc3c(-c3ccc(-c4ccc5sc6ccccc6c5c4)c4oc5ccccc5c34)c3ccccc23)cc1]

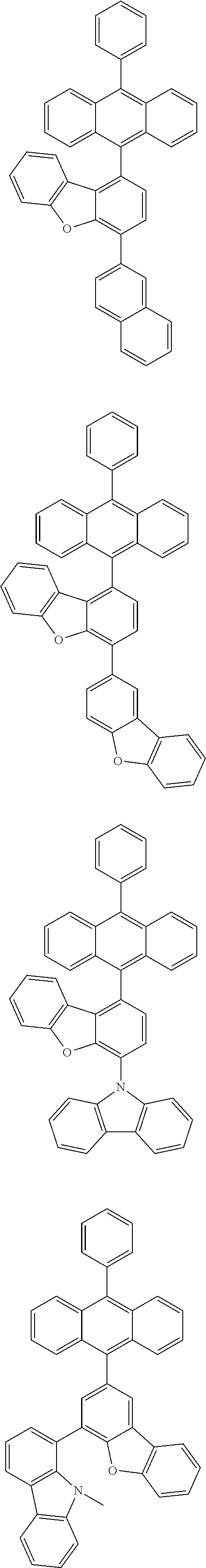 [SMILES: c1ccc(-c2c3ccccc3c(-c3ccc(-c4ccc5ccccc5c4)c4oc5ccccc5c34)c3ccccc23)cc1 ; c1ccc(-c2c3ccccc3c(-c3ccc(-c4ccc5oc6ccccc6c5c4)c4oc5ccccc5c34)c3ccccc23)cc1 ; c1ccc(-c2c3ccccc3c(-c3ccc(-n4c5ccccc5c5ccccc54)c4oc5ccccc5c34)c3ccccc23)cc1 ; Cn1c2ccccc2c2cccc(-c3cc(-c4c5ccccc5c(-c5ccccc5)c5ccccc45)cc4c3oc3ccccc34)c21]

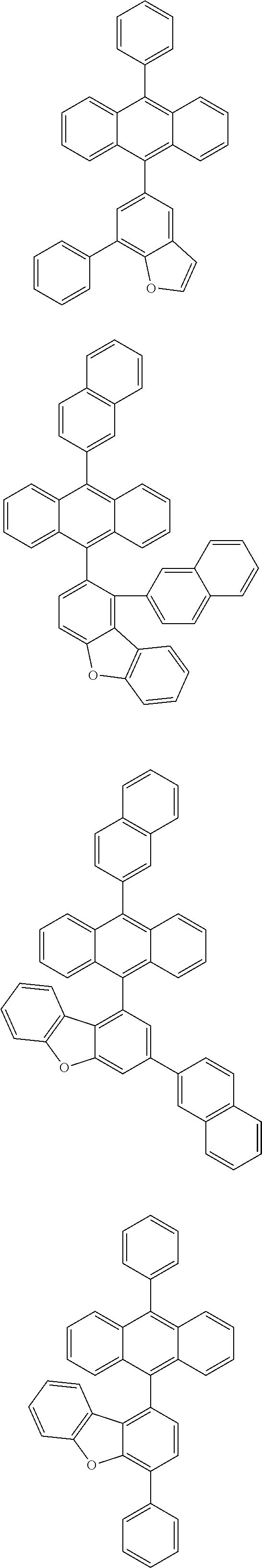 [SMILES: c1ccc(-c2c3ccccc3c(-c3cc(-c4ccccc4)c4occc4c3)c3ccccc23)cc1 ; c1ccc2cc(-c3c4ccccc4c(-c4ccc5oc6ccccc6c5c4-c4ccc5ccccc5c4)c4ccccc34)ccc2c1 ; c1ccc2cc(-c3cc(-c4c5ccccc5c(-c5ccc6ccccc6c5)c5ccccc45)c4c(c3)oc3ccccc34)ccc2c1 ; c1ccc(-c2c3ccccc3c(-c3ccc(-c4ccccc4)c4oc5ccccc5c34)c3ccccc23)cc1]

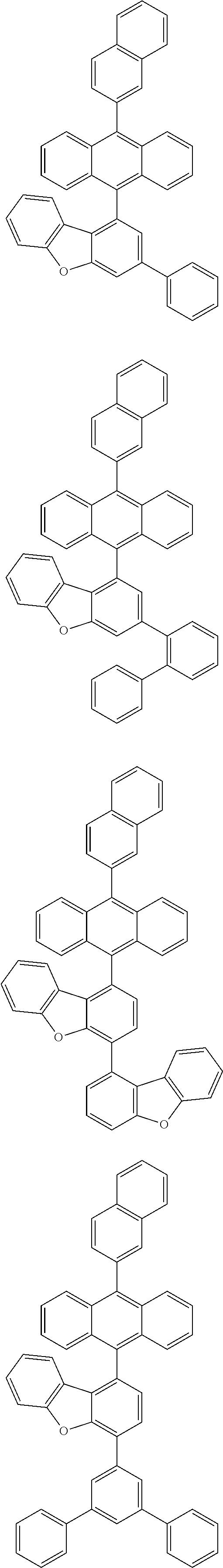 [SMILES: c1ccc(-c2cc(-c3c4ccccc4c(-c4ccc5ccccc5c4)c4ccccc34)c3c(c2)oc2ccccc23)cc1 ; c1ccc(-c2ccccc2-c2cc(-c3c4ccccc4c(-c4ccc5ccccc5c4)c4ccccc34)c3c(c2)oc2ccccc23)cc1 ; c1ccc2cc(-c3c4ccccc4c(-c4ccc(-c5cccc6oc7ccccc7c56)c5oc6ccccc6c45)c4ccccc34)ccc2c1 ; c1ccc(-c2cc(-c3ccccc3)cc(-c3ccc(-c4c5ccccc5c(-c5ccc6ccccc6c5)c5ccccc45)c4c3oc3ccccc34)c2)cc1]

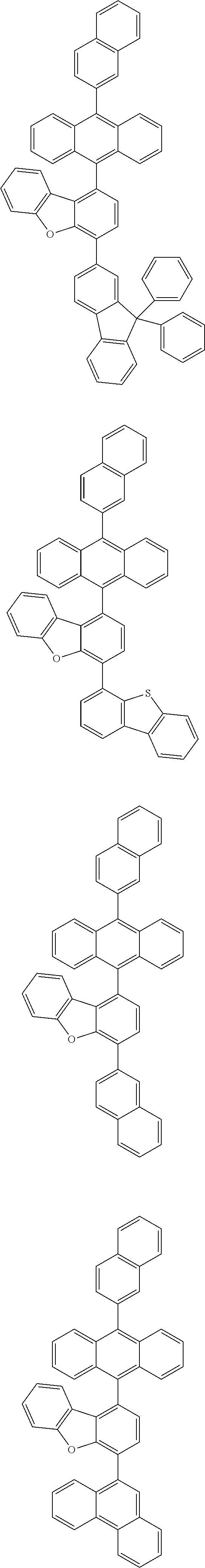 [SMILES: c1ccc(C2(c3ccccc3)c3ccccc3-c3ccc(-c4ccc(-c5c6ccccc6c(-c6ccc7ccccc7c6)c6ccccc56)c5c4oc4ccccc45)cc32)cc1 ; c1ccc2cc(-c3c4ccccc4c(-c4ccc(-c5cccc6c5sc5ccccc56)c5oc6ccccc6c45)c4ccccc34)ccc2c1 ; c1ccc2cc(-c3c4ccccc4c(-c4ccc(-c5ccc6ccccc6c5)c5oc6ccccc6c45)c4ccccc34)ccc2c1 ; c1ccc2cc(-c3c4ccccc4c(-c4ccc(-c5cc6ccccc6c6ccccc56)c5oc6ccccc6c45)c4ccccc34)ccc2c1]

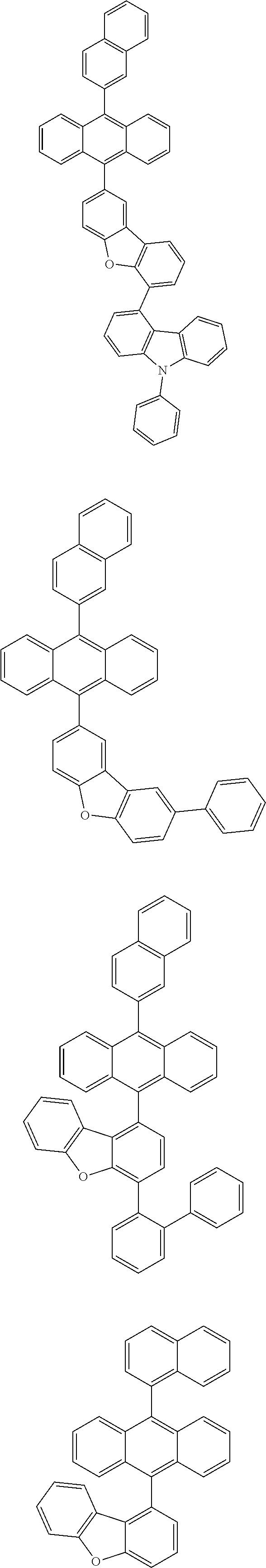 [SMILES: c1ccc(-n2c3ccccc3c3c(-c4cccc5c4oc4ccc(-c6c7ccccc7c(-c7ccc8ccccc8c7)c7ccccc67)cc45)cccc32)cc1 ; c1ccc(-c2ccc3oc4ccc(-c5c6ccccc6c(-c6ccc7ccccc7c6)c6ccccc56)cc4c3c2)cc1 ; c1ccc(-c2ccccc2-c2ccc(-c3c4ccccc4c(-c4ccc5ccccc5c4)c4ccccc34)c3c2oc2ccccc23)cc1 ; c1ccc2c(-c3c4ccccc4c(-c4cccc5oc6ccccc6c45)c4ccccc34)cccc2c1]

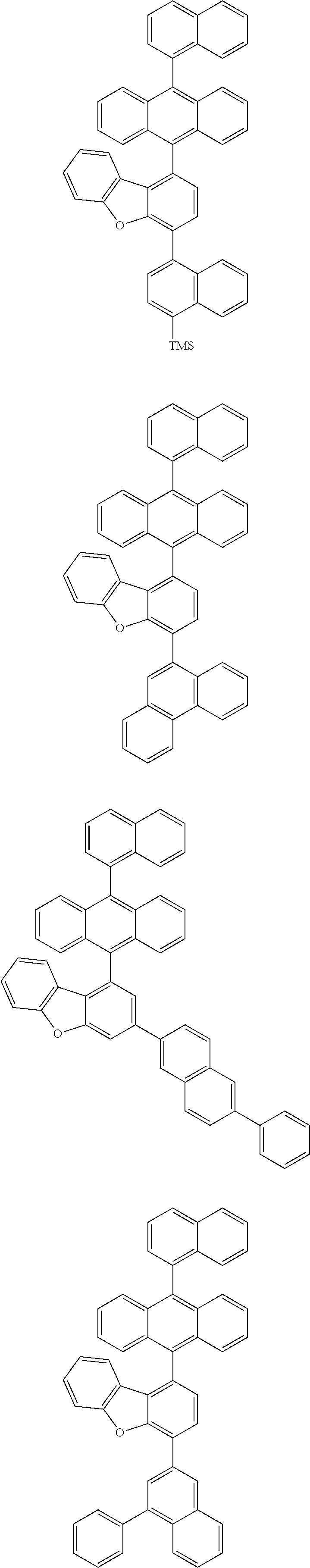 [SMILES: C[Si](C)(C)c1ccc(-c2ccc(-c3c4ccccc4c(-c4cccc5ccccc45)c4ccccc34)c3c2oc2ccccc23)c2ccccc12 ; c1ccc2c(-c3c4ccccc4c(-c4ccc(-c5cc6ccccc6c6ccccc56)c5oc6ccccc6c45)c4ccccc34)cccc2c1 ; c1ccc(-c2ccc3cc(-c4cc(-c5c6ccccc6c(-c6cccc7ccccc67)c6ccccc56)c5c(c4)oc4ccccc45)ccc3c2)cc1 ; c1ccc(-c2cc(-c3ccc(-c4c5ccccc5c(-c5cccc6ccccc56)c5ccccc45)c4c3oc3ccccc34)cc3ccccc23)cc1]

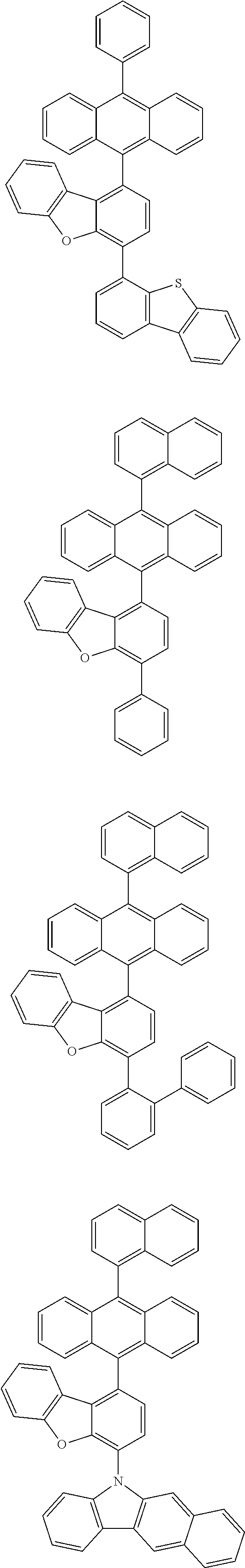 [SMILES: c1ccc(-c2c3ccccc3c(-c3ccc(-c4cccc5c4sc4ccccc45)c4oc5ccccc5c34)c3ccccc23)cc1 ; c1ccc(-c2ccc(-c3c4ccccc4c(-c4cccc5ccccc45)c4ccccc34)c3c2oc2ccccc23)cc1 ; c1ccc(-c2ccccc2-c2ccc(-c3c4ccccc4c(-c4cccc5ccccc45)c4ccccc34)c3c2oc2ccccc23)cc1 ; c1ccc2cc3c(cc2c1)c1ccccc1n3-c1ccc(-c2c3ccccc3c(-c3cccc4ccccc34)c3ccccc23)c2c1oc1ccccc12]

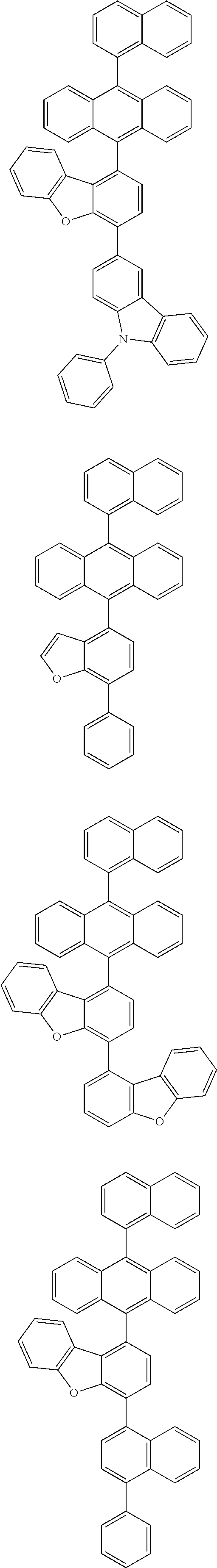 [SMILES: c1ccc(-n2c3ccccc3c3cc(-c4ccc(-c5c6ccccc6c(-c6cccc7ccccc67)c6ccccc56)c5c4oc4ccccc45)ccc32)cc1 ; c1ccc(-c2ccc(-c3c4ccccc4c(-c4cccc5ccccc45)c4ccccc34)c3ccoc23)cc1 ; c1ccc2c(-c3c4ccccc4c(-c4ccc(-c5cccc6oc7ccccc7c56)c5oc6ccccc6c45)c4ccccc34)cccc2c1 ; c1ccc(-c2ccc(-c3ccc(-c4c5ccccc5c(-c5cccc6ccccc56)c5ccccc45)c4c3oc3ccccc34)c3ccccc23)cc1]

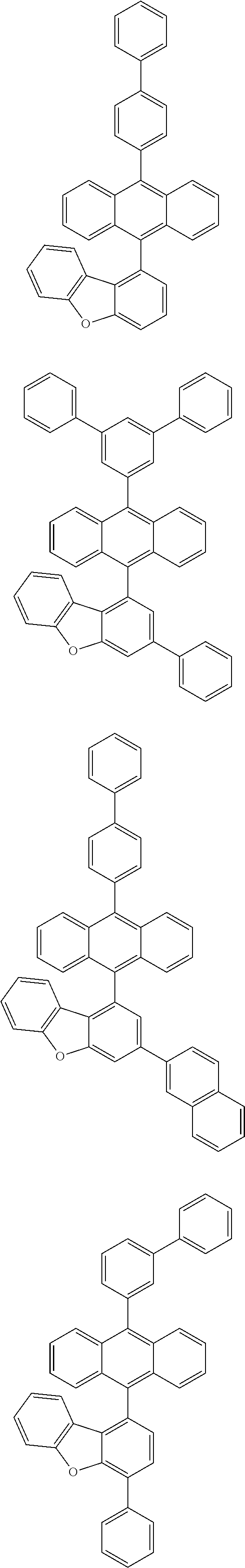 [SMILES: c1ccc(-c2ccc(-c3c4ccccc4c(-c4cccc5oc6ccccc6c45)c4ccccc34)cc2)cc1 ; c1ccc(-c2cc(-c3ccccc3)cc(-c3c4ccccc4c(-c4cc(-c5ccccc5)cc5oc6ccccc6c45)c4ccccc34)c2)cc1 ; c1ccc(-c2ccc(-c3c4ccccc4c(-c4cc(-c5ccc6ccccc6c5)cc5oc6ccccc6c45)c4ccccc34)cc2)cc1 ; c1ccc(-c2cccc(-c3c4ccccc4c(-c4ccc(-c5ccccc5)c5oc6ccccc6c45)c4ccccc34)c2)cc1]

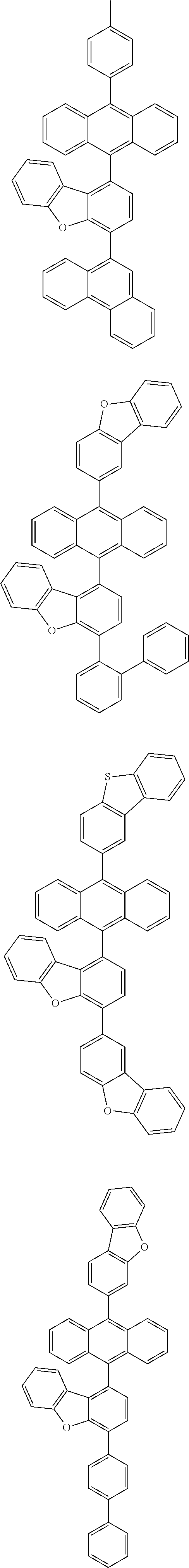

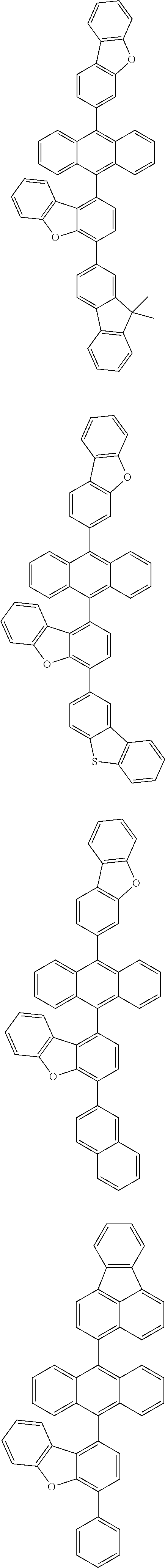 [SMILES: CC1(C)c2ccccc2-c2ccc(-c3ccc(-c4c5ccccc5c(-c5ccc6c(c5)oc5ccccc56)c5ccccc45)c4c3oc3ccccc34)cc21 ; c1ccc2c(c1)oc1cc(-c3c4ccccc4c(-c4ccc(-c5ccc6sc7ccccc7c6c5)c5oc6ccccc6c45)c4ccccc34)ccc12 ; c1ccc2cc(-c3ccc(-c4c5ccccc5c(-c5ccc6c(c5)oc5ccccc56)c5ccccc45)c4c3oc3ccccc34)ccc2c1 ; c1ccc(-c2ccc(-c3c4ccccc4c(-c4ccc5c6c(cccc46)-c4ccccc4-5)c4ccccc34)c3c2oc2ccccc23)cc1]

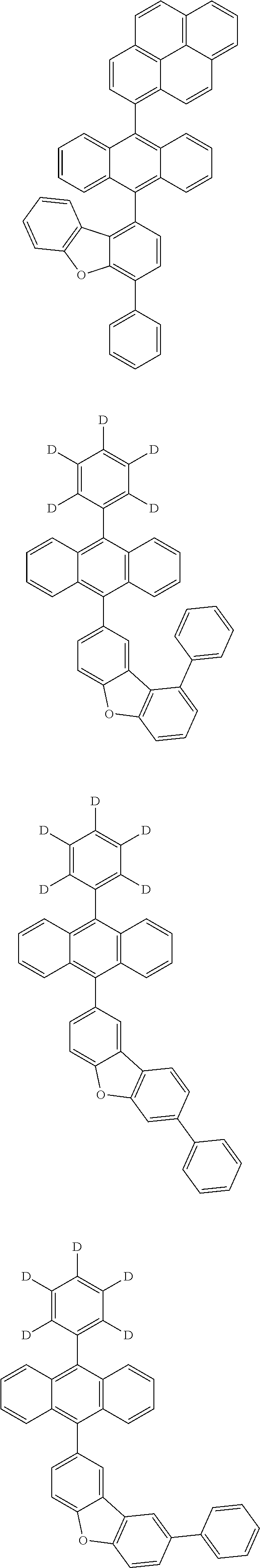 [SMILES: c1ccc(-c2ccc(-c3c4ccccc4c(-c4ccc5ccc6cccc7ccc4c5c67)c4ccccc34)c3c2oc2ccccc23)cc1 ; [2H]c1c([2H])c([2H])c(-c2c3ccccc3c(-c3ccc4oc5cccc(-c6ccccc6)c5c4c3)c3ccccc23)c([2H])c1[2H] ; [2H]c1c([2H])c([2H])c(-c2c3ccccc3c(-c3ccc4oc5cc(-c6ccccc6)ccc5c4c3)c3ccccc23)c([2H])c1[2H] ; [2H]c1c([2H])c([2H])c(-c2c3ccccc3c(-c3ccc4oc5ccc(-c6ccccc6)cc5c4c3)c3ccccc23)c([2H])c1[2H]]

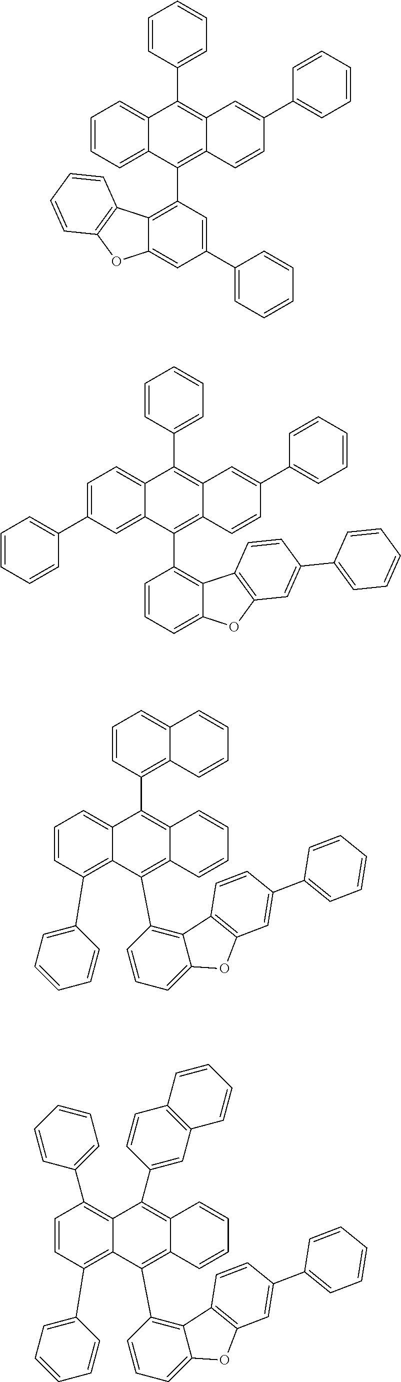 [SMILES: c1ccc(-c2cc(-c3c4ccccc4c(-c4ccccc4)c4cc(-c5ccccc5)ccc34)c3c(c2)oc2ccccc23)cc1 ; c1ccc(-c2ccc3c(c2)oc2cccc(-c4c5ccc(-c6ccccc6)cc5c(-c5ccccc5)c5ccc(-c6ccccc6)cc45)c23)cc1 ; c1ccc(-c2ccc3c(c2)oc2cccc(-c4c5ccccc5c(-c5cccc6ccccc56)c5cccc(-c6ccccc6)c45)c23)cc1 ; c1ccc(-c2ccc3c(c2)oc2cccc(-c4c5ccccc5c(-c5ccc6ccccc6c5)c5c(-c6ccccc6)ccc(-c6ccccc6)c45)c23)cc1]

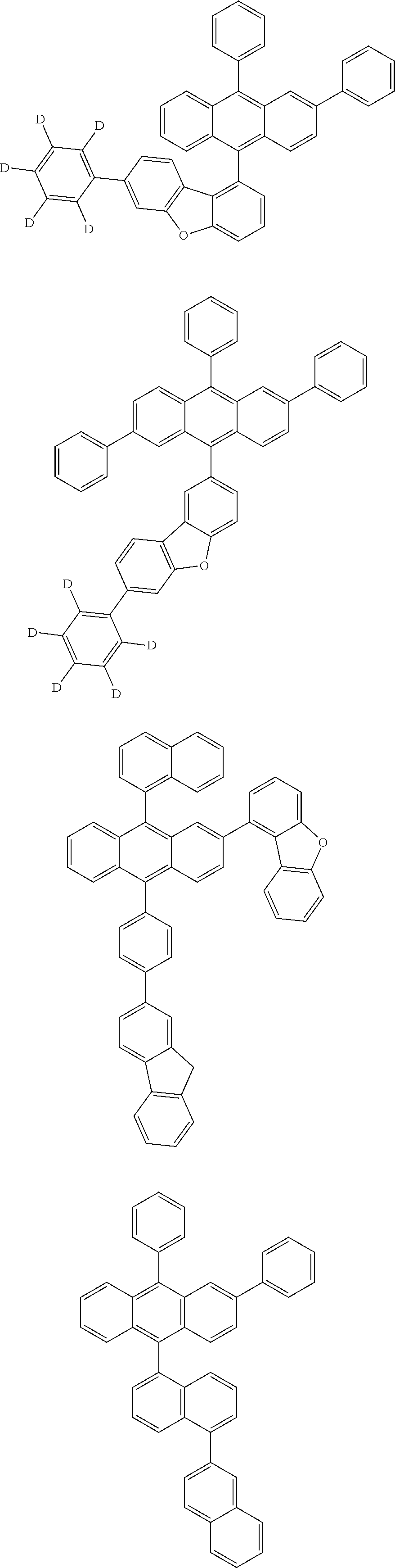

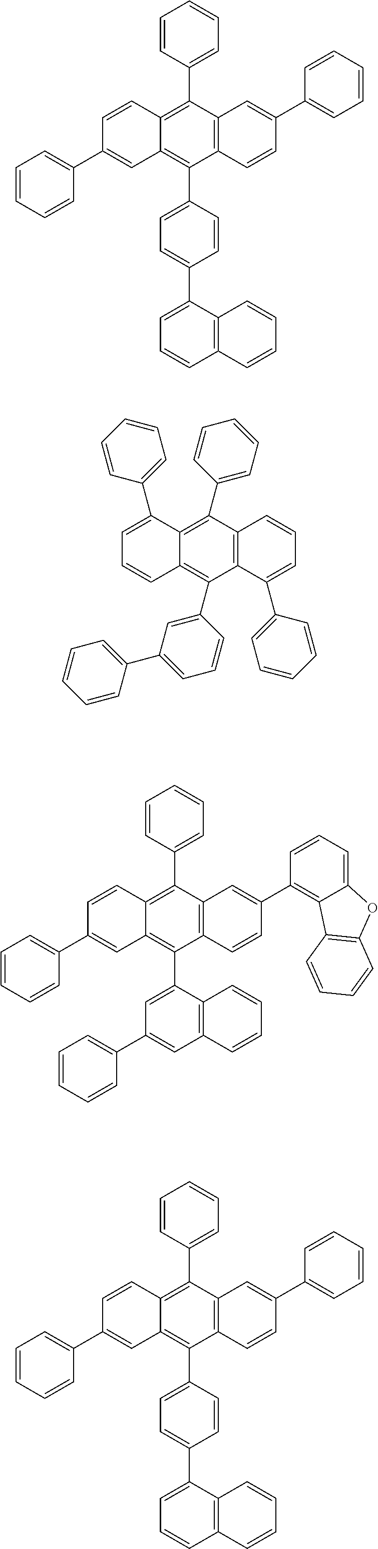

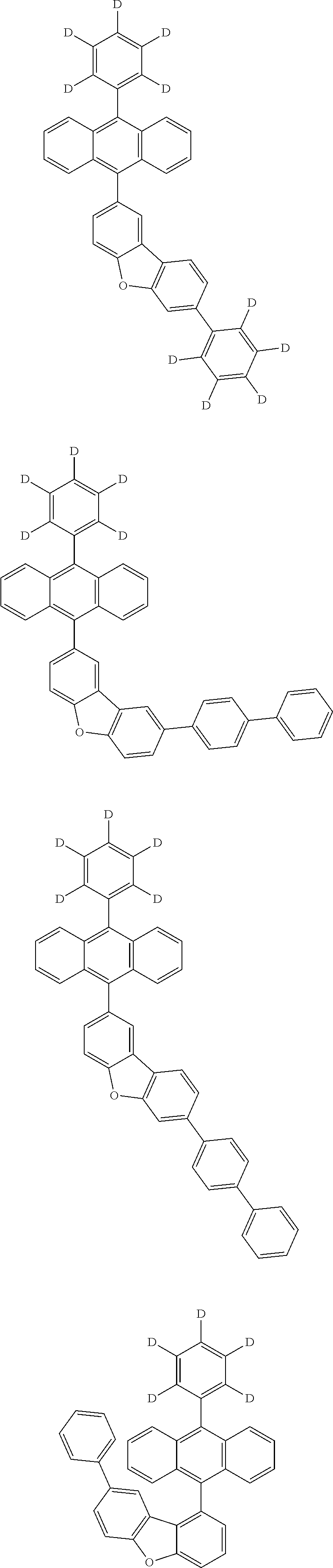 [SMILES: [2H]c1c([2H])c([2H])c(-c2ccc3c(c2)oc2ccc(-c4c5ccccc5c(-c5c([2H])c([2H])c([2H])c([2H])c5[2H])c5ccccc45)cc23)c([2H])c1[2H] ; [2H]c1c([2H])c([2H])c(-c2c3ccccc3c(-c3ccc4oc5ccc(-c6ccc(-c7ccccc7)cc6)cc5c4c3)c3ccccc23)c([2H])c1[2H] ; [2H]c1c([2H])c([2H])c(-c2c3ccccc3c(-c3ccc4oc5cc(-c6ccc(-c7ccccc7)cc6)ccc5c4c3)c3ccccc23)c([2H])c1[2H] ; [2H]c1c([2H])c([2H])c(-c2c3ccccc3c(-c3cccc4oc5ccc(-c6ccccc6)cc5c34)c3ccccc23)c([2H])c1[2H]]

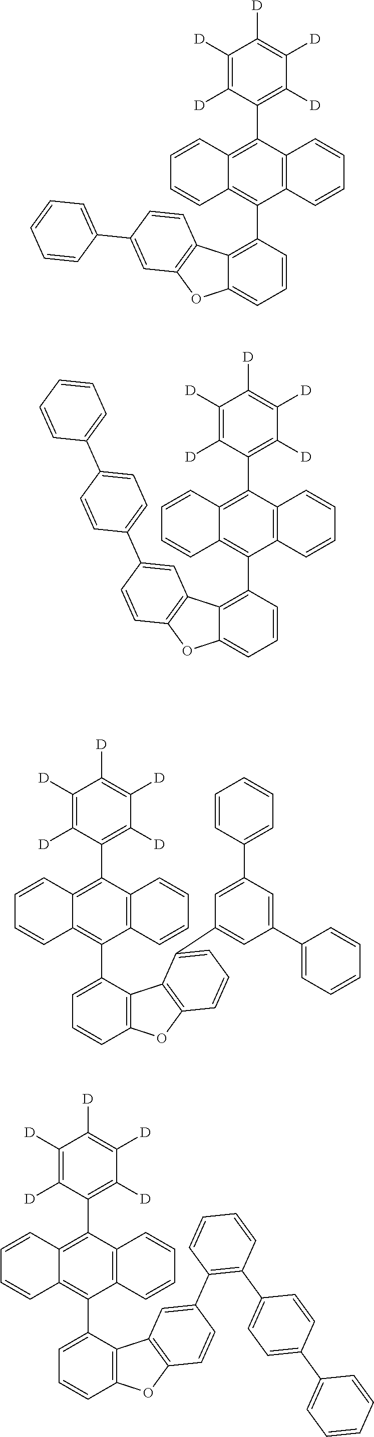 [SMILES: [2H]c1c([2H])c([2H])c(-c2c3ccccc3c(-c3cccc4oc5cc(-c6ccccc6)ccc5c34)c3ccccc23)c([2H])c1[2H] ; [2H]c1c([2H])c([2H])c(-c2c3ccccc3c(-c3cccc4oc5ccc(-c6ccc(-c7ccccc7)cc6)cc5c34)c3ccccc23)c([2H])c1[2H] ; [2H]c1c([2H])c([2H])c(-c2c3ccccc3c(-c3cccc4oc5cccc(-c6cc(-c7ccccc7)cc(-c7ccccc7)c6)c5c34)c3ccccc23)c([2H])c1[2H] ; [2H]c1c([2H])c([2H])c(-c2c3ccccc3c(-c3cccc4oc5ccc(-c6ccccc6-c6ccc(-c7ccccc7)cc6)cc5c34)c3ccccc23)c([2H])c1[2H]]

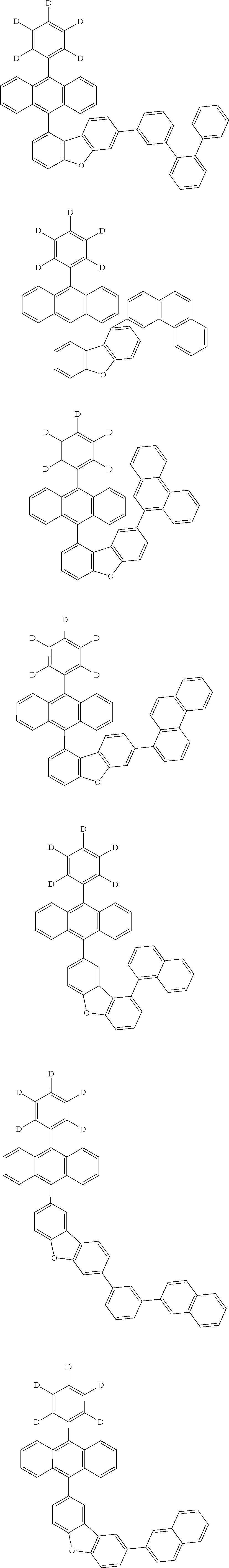

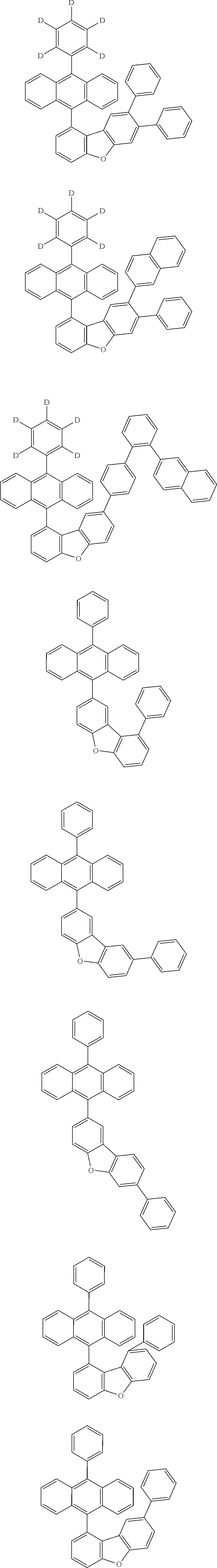

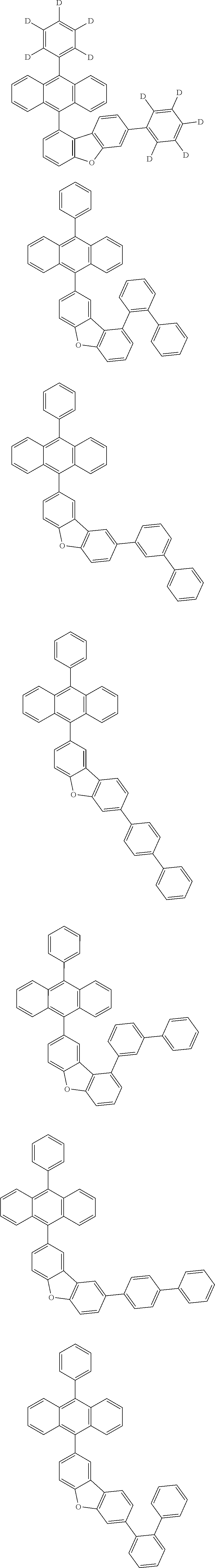

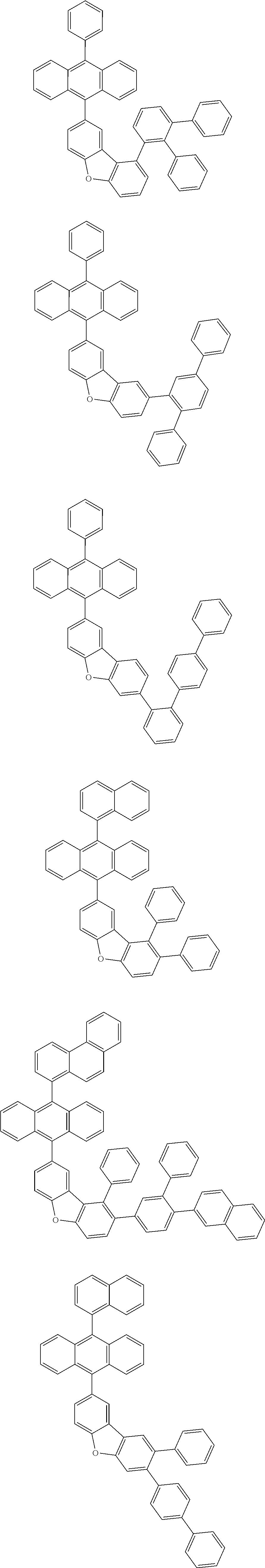

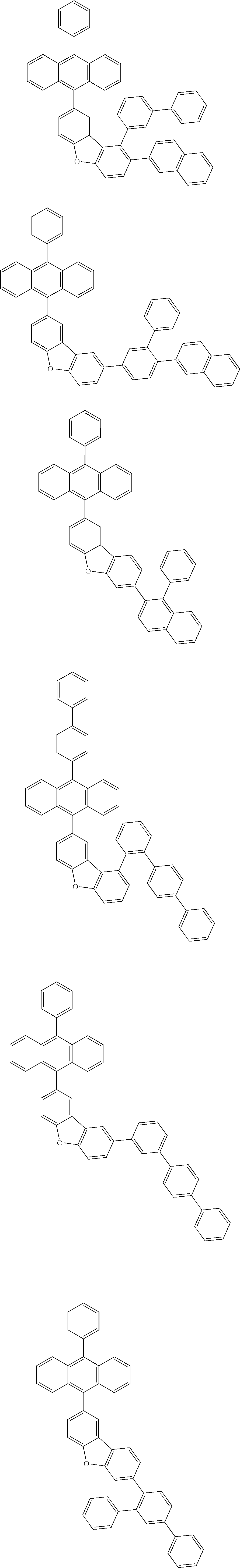

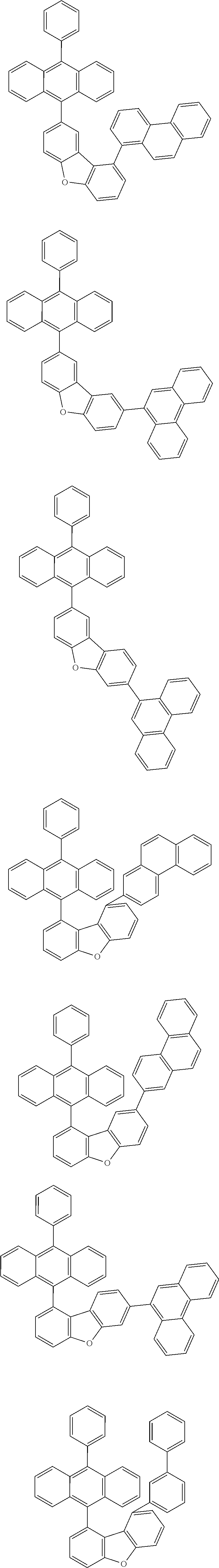

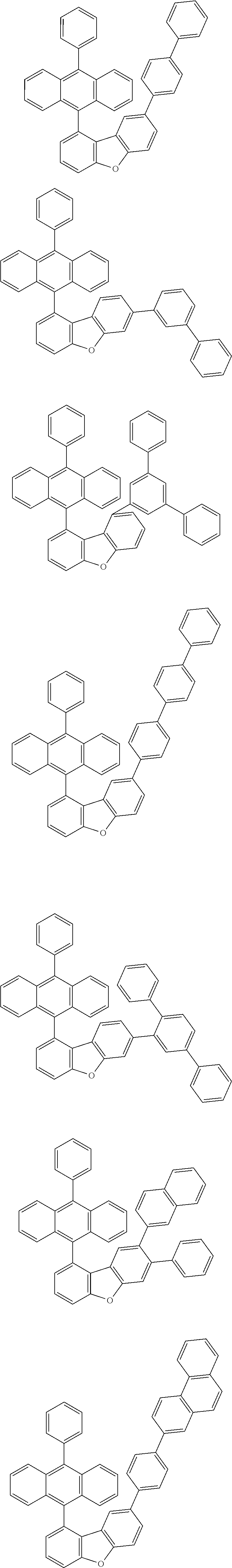

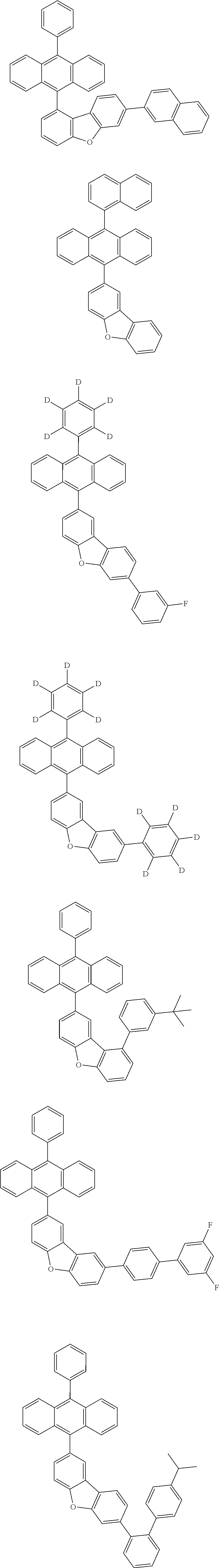

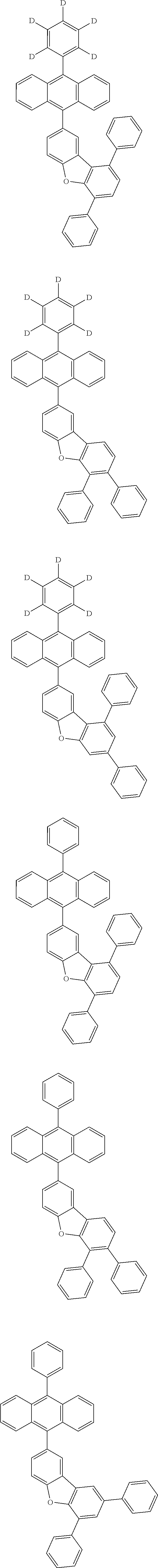

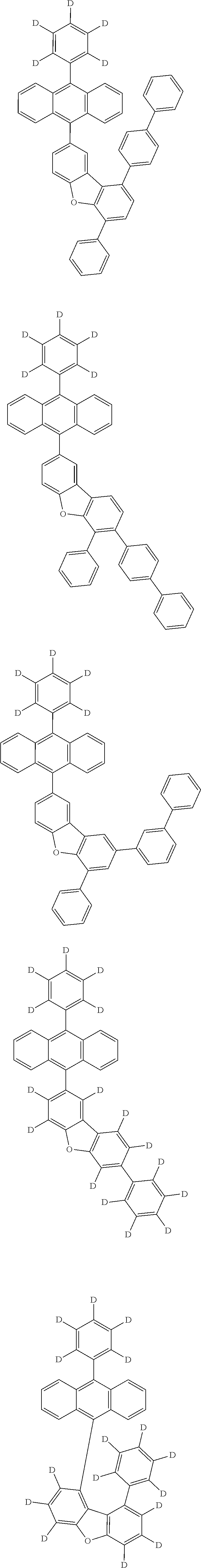

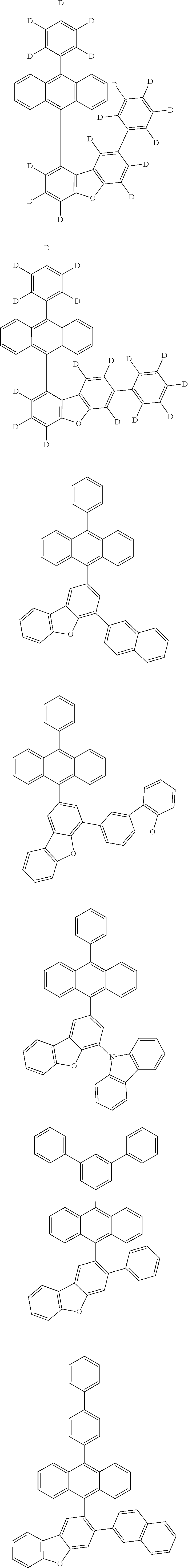

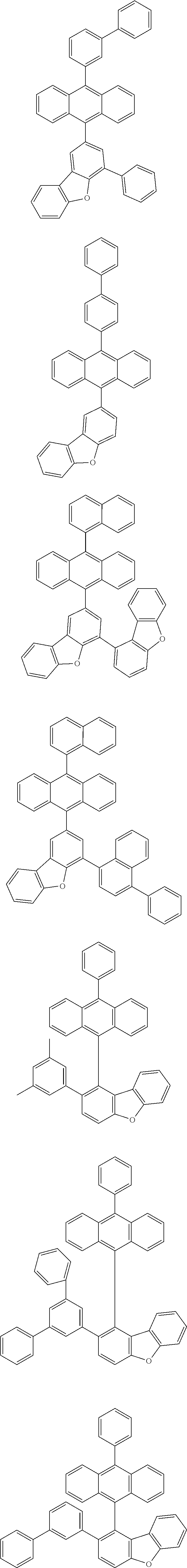

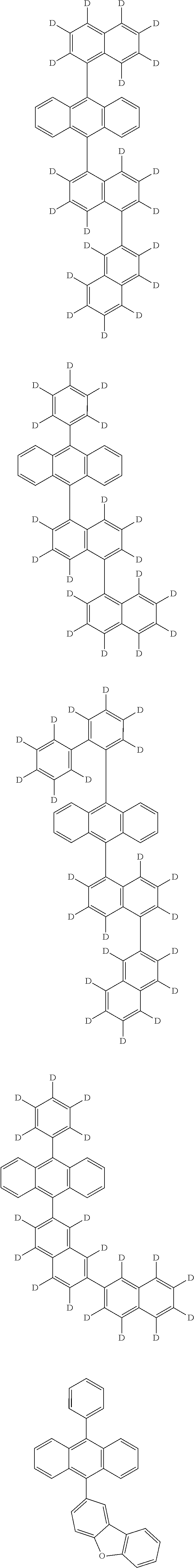

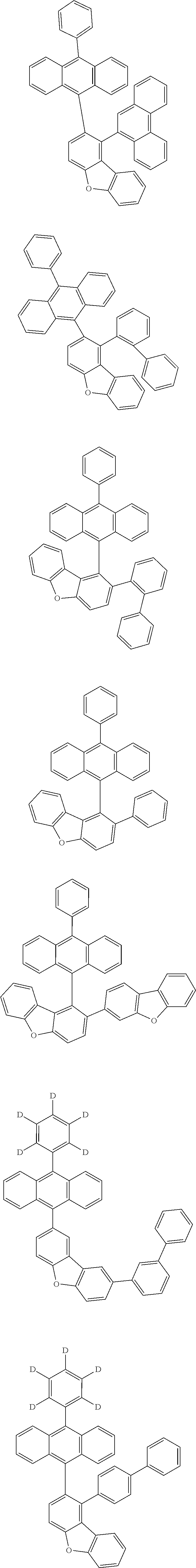

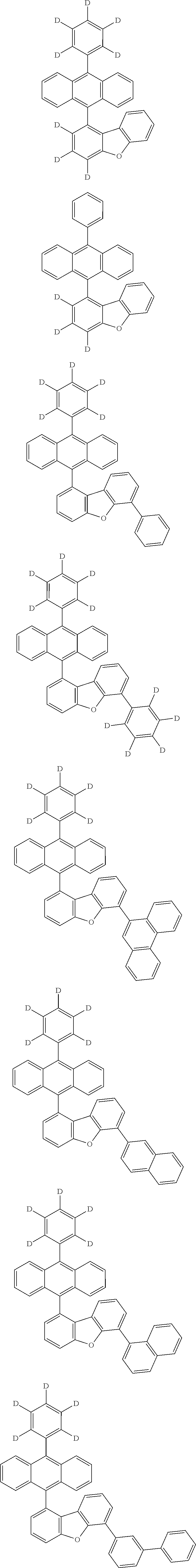

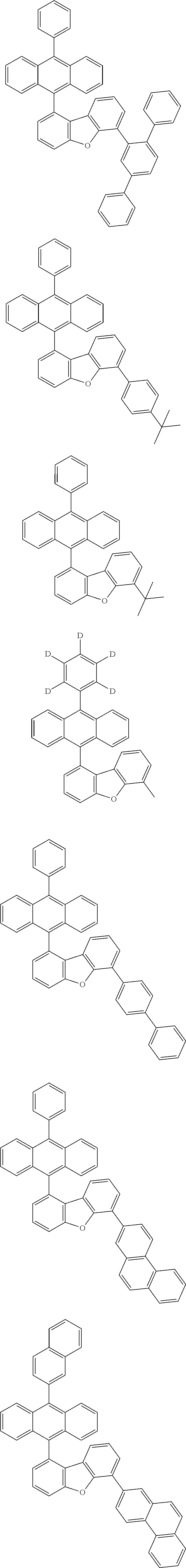

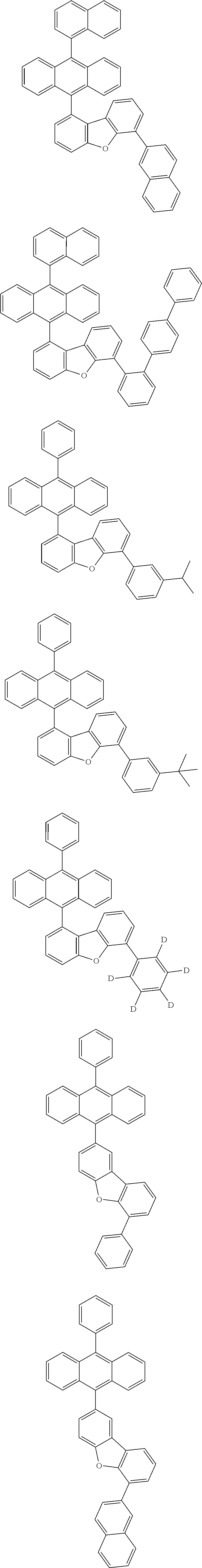

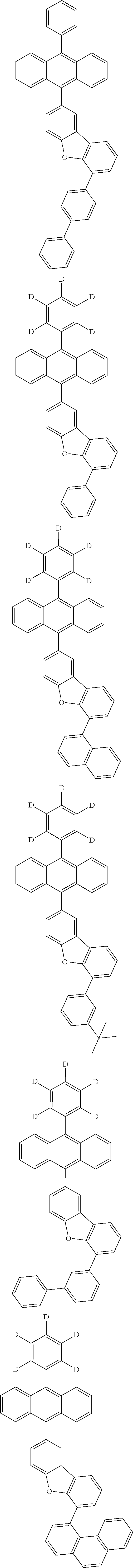

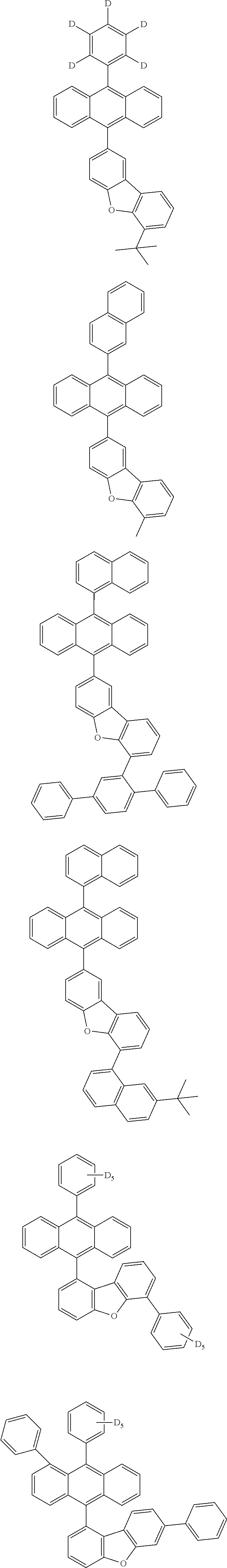

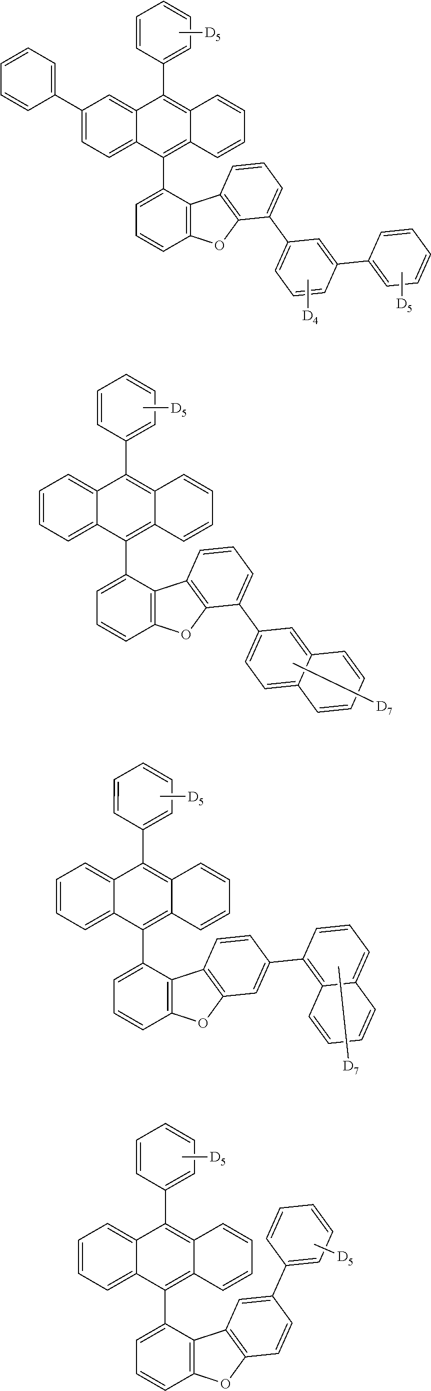

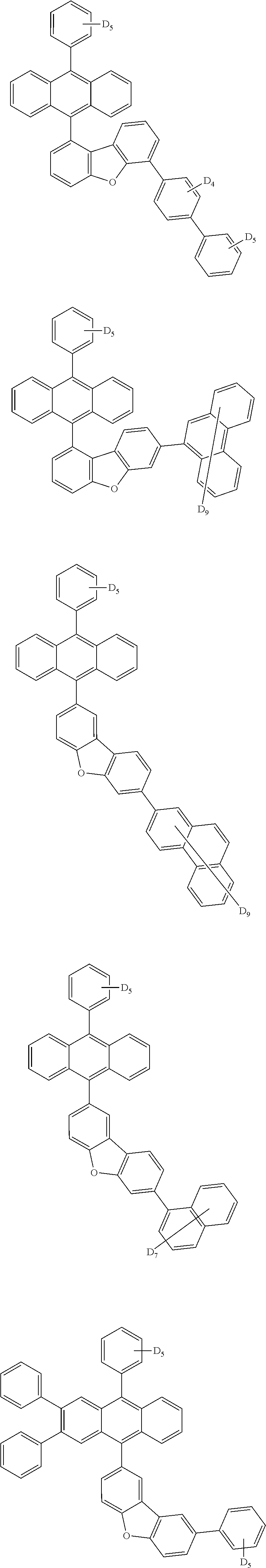

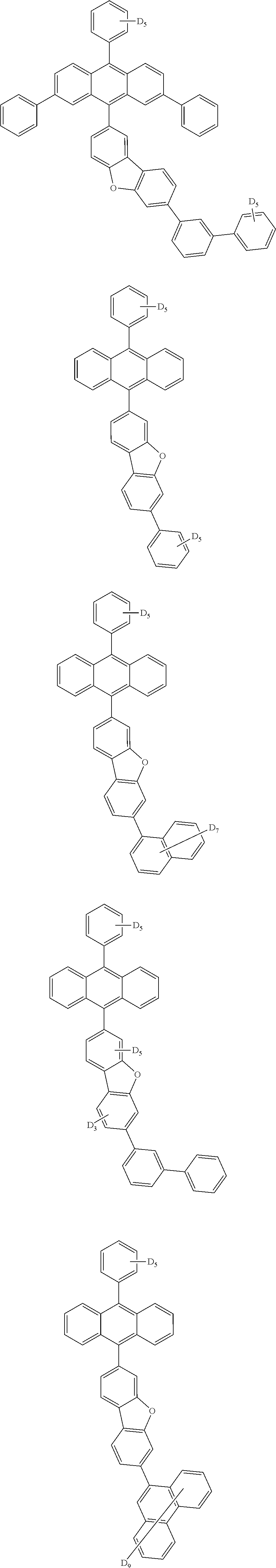

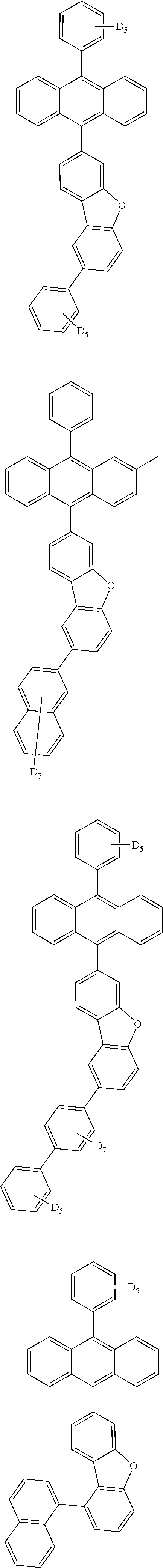

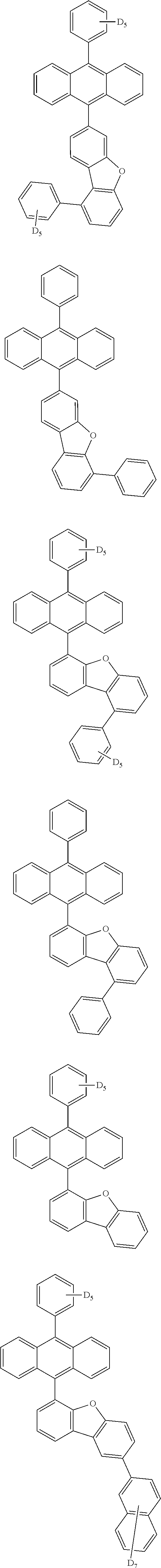

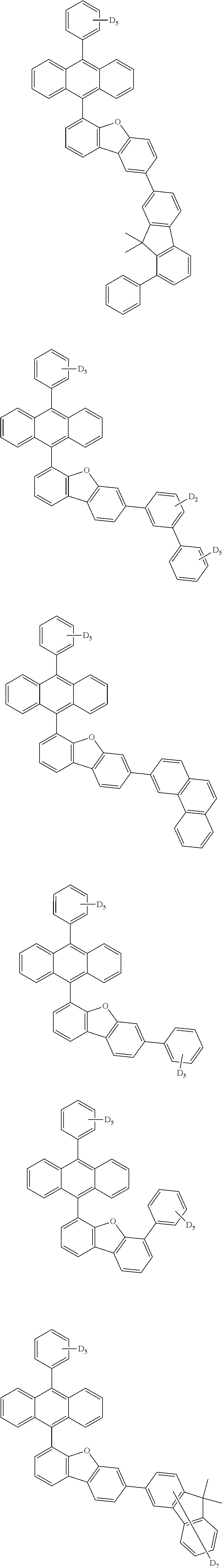

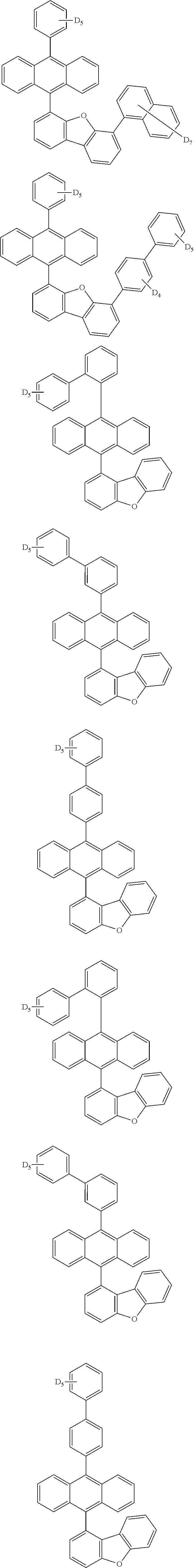

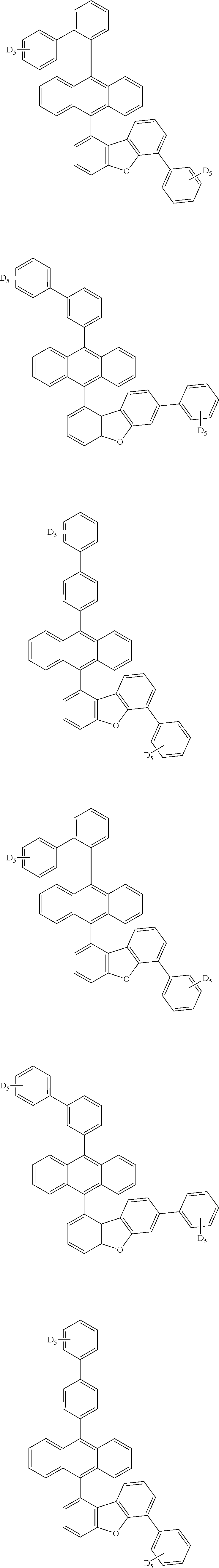

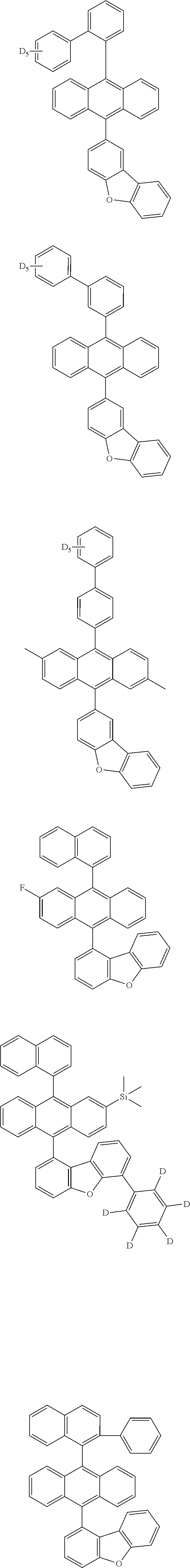

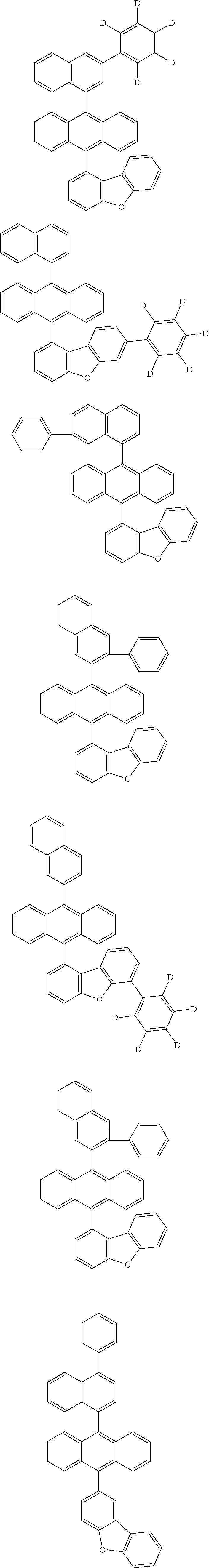

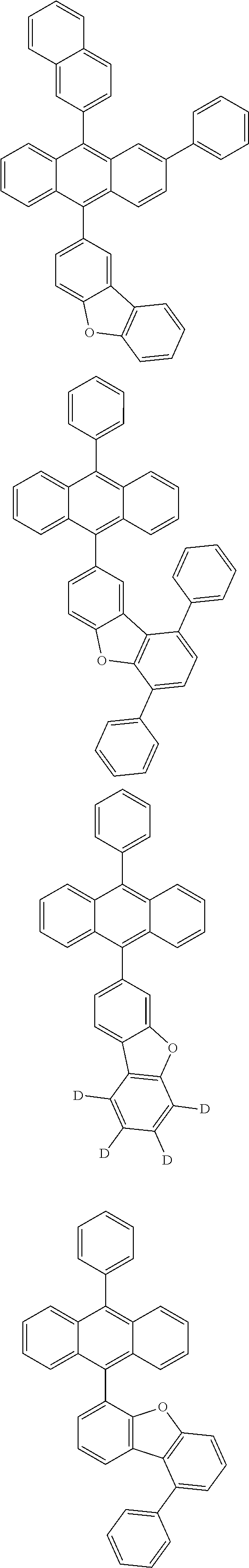

However, these compounds are not intended to limit the scope of Formula 2.

The organic layers of the organic light emitting device according to the present invention may form a monolayer structure. Alternatively, the organic layers may be stacked together to form a multilayer structure. For example, the organic layers may have a structure including a hole injecting layer, a hole transport layer, a hole blocking layer, a light emitting layer, an electron blocking layer, an electron transport layer, and an electron injecting layer but are not limited to this structure. The number of the organic layers is not limited and may be increased or decreased. Preferred structures of the organic layers of the organic light emitting device according to the present invention will be explained in more detail in the Examples section that follows.

A more detailed description will be given concerning exemplary embodiments of the organic light emitting device according to the present invention.

The organic light emitting device of the present invention includes an anode, a hole transport layer, a light emitting layer, an electron transport layer, and a cathode. The organic light emitting device of the present invention may optionally further include a hole injecting layer between the anode and the hole transport layer and an electron injecting layer between the electron transport layer and the cathode. If necessary, the organic light emitting device of the present invention may further include one or two intermediate layers such as a hole blocking layer or an electron blocking layer. The organic light emitting device of the present invention may further include one or more organic layers such as a capping layer that have various functions depending on the desired characteristics of the device.

A specific structure of the organic light emitting device according to one embodiment of the present invention, a method for fabricating the device, and materials for the organic layers are as follows.

First, an anode material is coated on a substrate to form an anode. The substrate may be any of those used in general organic light emitting devices. The substrate is preferably an organic substrate or a transparent plastic substrate that is excellent in transparency, surface smoothness, ease of handling, and waterproofness. A highly transparent and conductive metal oxide such as indium tin oxide (ITO), indium zinc oxide (IZO), tin oxide (SnO₂) or zinc oxide (ZnO) is used as the anode material.

A hole injecting material is coated on the anode by vacuum thermal evaporation or spin coating to form a hole injecting layer. Then, a hole transport material is coated on the hole injecting layer by vacuum thermal evaporation or spin coating to form a hole transport layer.

The hole injecting material is not specially limited so long as it is usually used in the art. Specific examples of such materials include 4,4′,4″-tris(2-naphthylphenyl-phenylamino)triphenylamine (2-TNATA), N,N′-di(1-naphthyl)-N,N′-diphenylbenzidine (NPD), N,N′-diphenyl-N,N′-bis(3-methylphenyl)-1,1′-biphenyl-4,4′-diamine (TPD), and N,N′-diphenyl-N,N′-bis(4-(phenyl-m-tolylamino)phenyl)biphenyl-4,4′-diamine (DNTPD).

The hole transport material is not specially limited so long as it is commonly used in the art. Examples of such materials include N,N′-bis(3-methylphenyl)-N,N′-diphenyl-(1,1-biphenyl)-4,4′-diamine (TPD) and N,N′-di(naphthalen-1-yl)-N,N′-diphenylbenzidine (α-NPD).

Subsequently, a hole auxiliary layer and a light emitting layer are sequentially laminated on the hole transport layer. A hole blocking layer may be optionally formed on the light emitting layer by vacuum thermal evaporation or spin coating. The hole blocking layer is formed as a thin film and blocks holes from entering a cathode through the organic light emitting layer. This role of the hole blocking layer prevents the lifetime and efficiency of the device from deteriorating. A material having a very low highest occupied molecular orbital (HOMO) energy level is used for the hole blocking layer. The hole blocking material is not particularly limited so long as it can transport electrons and has a higher ionization potential than the light emitting compound. Representative examples of suitable hole blocking materials include BAlq, BCP, and TPBI.

Examples of materials for the hole blocking layer include, but are not limited to, BAlq, BCP, Bphen, TPBI, TAZ, BeBq₂, OXD-7, and Liq.

An electron transport layer is deposited on the hole blocking layer by vacuum thermal evaporation or spin coating, and an electron injecting layer is formed thereon. A cathode metal is deposited on the electron injecting layer by vacuum thermal evaporation to form a cathode, completing the fabrication of the organic light emitting device.

For example, lithium (Li), magnesium (Mg), aluminum (Al), aluminum-lithium (Al—Li), calcium (Ca), magnesium-indium (Mg—In) or magnesium-silver (Mg—Ag) may be used as the metal for the formation of the cathode. The organic light emitting device may be of top emission type. In this case, a transmissive material such as ITO or IZO may be used to form the cathode.

A material for the electron transport layer functions to stably transport electrons injected from the cathode. The electron transport material may be any of those known in the art and examples thereof include, but are not limited to, quinoline derivatives, particularly tris(8-quinolinolato)aluminum (Alq₃), TAZ, Balq, beryllium bis(benzoquinolin-10-olate) (Bebq2), and oxadiazole derivatives such as PBD, BMD, and BND.

Each of the organic layers can be formed by a monomolecular deposition or solution process. According to the monomolecular deposition process, the material for each layer is evaporated into a thin film under heat and vacuum or reduced pressure. According to the solution process, the material for each layer is mixed with a suitable solvent and the mixture is then formed into a thin film by a suitable method such as ink-jet printing, roll-to-roll coating, screen printing, spray coating, dip coating or spin coating.

The organic light emitting device of the present invention can be used in a display or lighting system selected from flat panel displays, flexible displays, monochromatic flat panel lighting systems, white flat panel lighting systems, flexible monochromatic lighting systems, flexible white lighting systems, displays for automotive applications, displays for virtual reality, and displays for augmented reality.

The present invention will be more specifically explained with reference to the following synthesis examples and fabrication examples. However, these examples are provided to assist in understanding the invention and are not intended to limit the scope of the present invention.

### Synthesis Example 1: Preparation of 1

### Synthesis Example 1-1: Synthesis of A-1

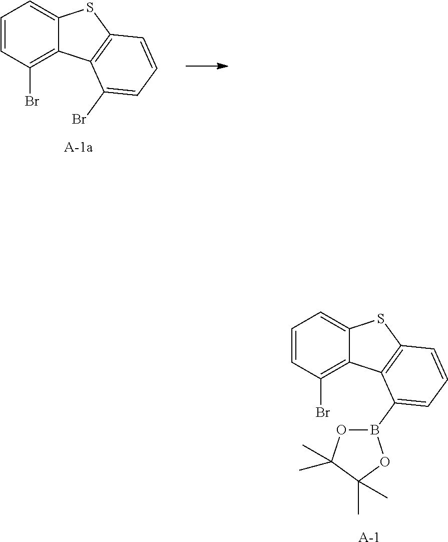

40 g of A-1a, 35.6 g of bis(pinacolato)diboron, 4.3 g of (1,1-bis(diphenylphosphino)ferrocene)dichloropalladium(II), 34.5 g of potassium acetate, and 500 mL of 1,4-dioxane were placed in a nitrogen-purged reactor and heated to 100° C. After 4 h, the mixture was cooled down to room temperature and extracted with ethyl acetate. The organic layer was dried over magnesium sulfate, filtered, and concentrated under reduced pressure. Purification by silica gel column chromatography afforded A-1 (33 g, 72.5%).

### Synthesis Example 1-2: Synthesis of A-2

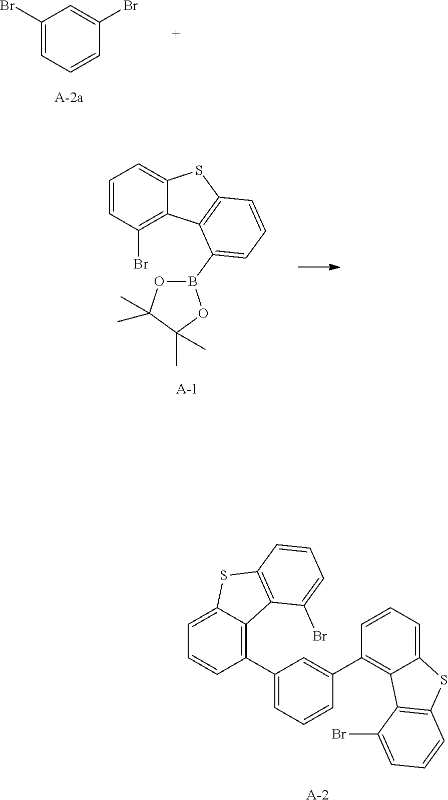

20 g of A-2a, 69.3 g of A-1, 2 g of tetrakis(triphenylphosphine)palladium(0), 29.3 g of potassium carbonate, 280 mL of tetrahydrofuran, and 70 ml of water were placed in a nitrogen-purged reactor. After 16 h, the temperature was allowed to drop to room temperature and ethyl acetate and water were added for layer separation. The organic layer was concentrated under reduced pressure and purified by silica gel column chromatography to afford A-2 (35.7 g, 70.1%).

### Synthesis Example 1-3: Synthesis of 1

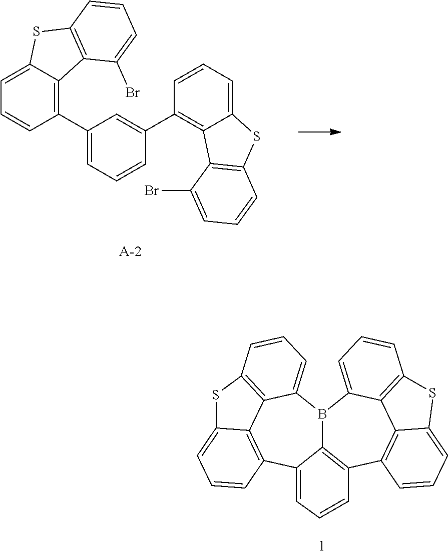 [SMILES: Brc1cccc2sc3cccc(-c4cccc(-c5cccc6sc7cccc(Br)c7c56)c4)c3c12 ; "A-2" ; c1cc2c3c(c1)-c1cccc4sc5cccc(c5c14)B3c1cccc3sc4cccc-2c4c13]

20 g of A-2 and 240 mL of tert-butylbenzene were placed in a nitrogen-purged reactor and 59 mL of n-butyllithium was added dropwise thereto at −78° C. After dropwise addition, the mixture was stirred at 60° C. for 3 h. Thereafter, nitrogen was blown into the mixture at 60° C. to remove heptane. After cooling to −78° C., 16.7 g of boron tribromide was added dropwise. The resulting mixture was stirred at room temperature for 1 h. After dropwise addition of 8.6 g of N,N-diisopropylethylamine at 0° C., stirring was continued at 120° C. for 2 h. After completion of the reaction, the reaction mixture was added with an aqueous sodium acetate solution at room temperature, stirred, and extracted with ethyl acetate. The organic layer was concentrated and purified by silica gel column chromatography to afford 1 (1.5 g, 10%).

MS (MALDI-TOF): m/z 450.07 [M⁺]

### Synthesis Example 2: Preparation of 8

### Synthesis Example 2-1: Synthesis of B-1

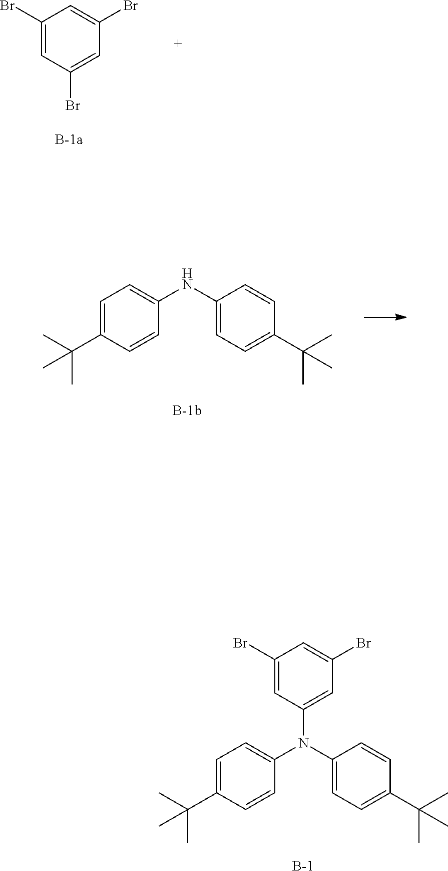

25 g of B-1b and 7.6 g of sodium tert-butoxide were added to 300 ml of toluene in a nitrogen-purged reactor, followed by stirring at room temperature for 10 min. Thereafter, to the mixture were added 22.4 g of B-1a, 1.6 g of tri-tert-butylphosphine, and 1.2 g of tris(dibenzylideneacetone)dipalladium. The temperature was slowly raised to 90° C. The resulting mixture was allowed to react for 16 h. After completion of the reaction, the reaction mixture was cooled to room temperature and extracted with water and toluene. The organic layer was separated, dried over magnesium sulfate, concentrated under reduced pressure, and purified by silica gel column chromatography to afford B-1 (25 g, 61.1%).

### Synthesis Example 2-2: Synthesis of B-2

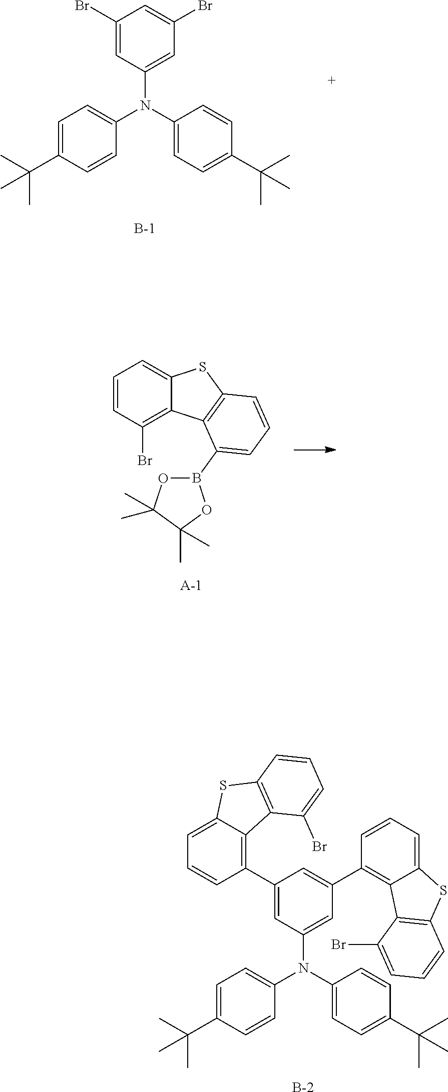

B-2 (yield 68.3%) was synthesized in the same manner as in Synthesis Example 1-2, except that B-1 was used instead of A-2a.

### Synthesis Example 2-3: Synthesis of 8

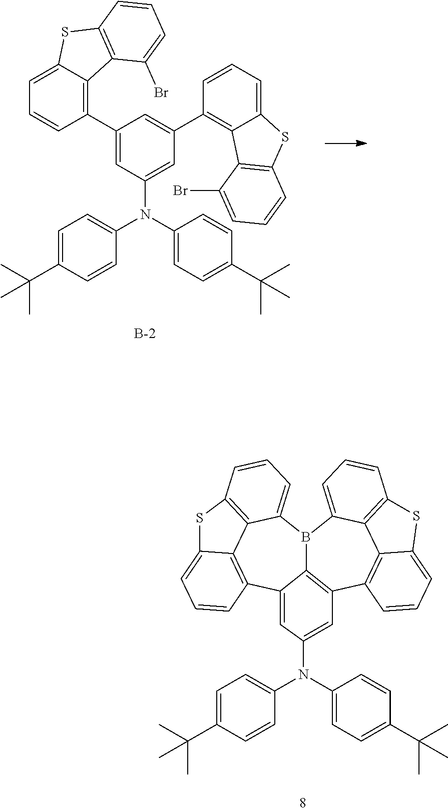

8 (yield 10.7%) was synthesized in the same manner as in Synthesis Example 1-3, except that B-2 was used instead of A-2.

MS (MALDI-TOF): m/z 729.27 [M⁺]

### Synthesis Example 3: Preparation of 11

### Synthesis Example 3-1: Synthesis of C-1

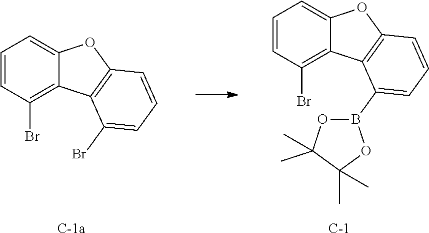

C-1 (yield 70.5%) was synthesized in the same manner as in Synthesis Example 1-1, except that C-1a was used instead of A-1a.

### Synthesis Example 3-2: Synthesis of C-2

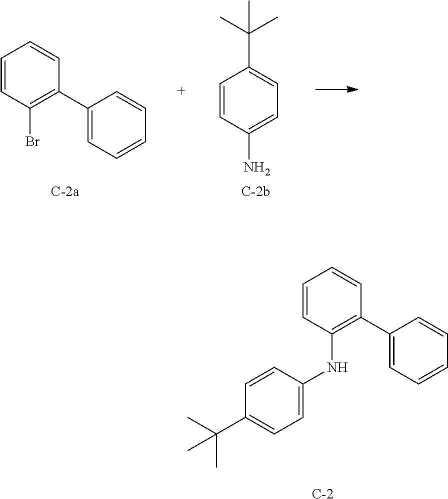

C-2 (yield 85%) was synthesized in the same manner as in Synthesis Example 2-1, except that C-2a and C-2b were used instead of B-1a and B-1b, respectively.

### Synthesis Example 3-3: Synthesis of C-3

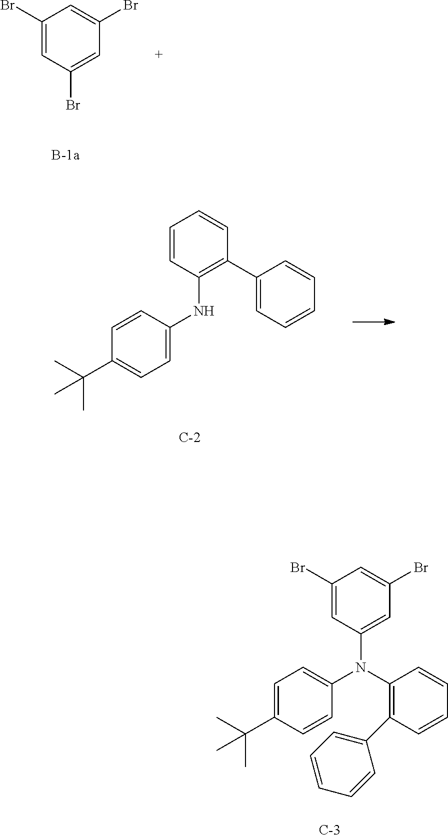

C-3 (yield 59.3%) was synthesized in the same manner as in Synthesis Example 2-1, except that C-2 was used instead of B-1b.

### Synthesis Example 3-4: Synthesis of C-4

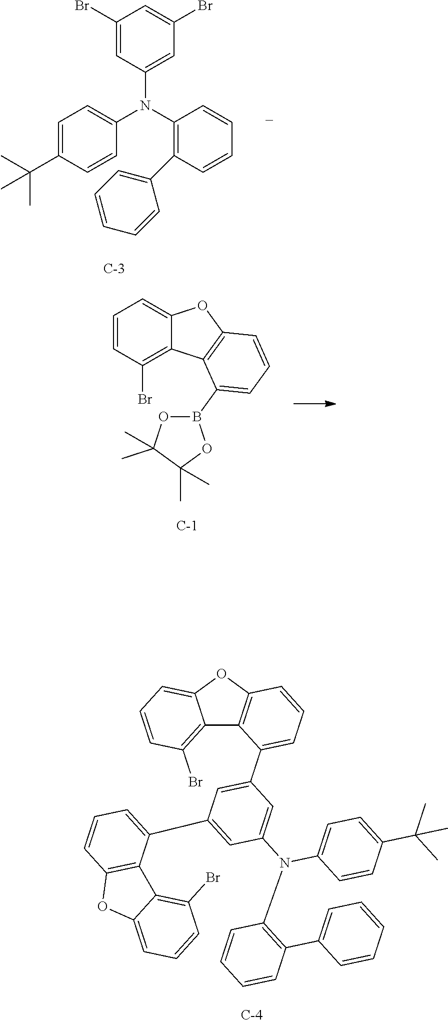

C-4 (yield 69%) was synthesized in the same manner as in Synthesis Example 1-2, except that C-3 and C-1 were used instead of A-2a and A-1, respectively.

### Synthesis Example 3-5: Synthesis of 11

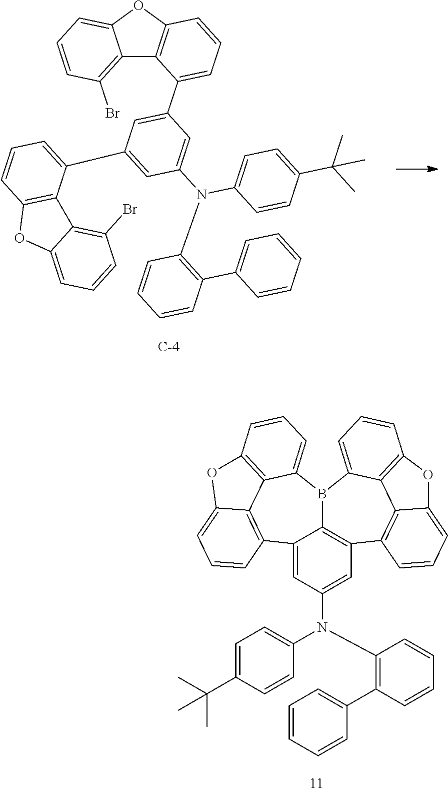

11 (yield 10.4%) was synthesized in the same manner as in Synthesis Example 1-3, except that C-4 was used instead of A-2.

MS (MALDI-TOF): m/z 717.28 [M⁺]

### Synthesis Example 4: Preparation of 15

### Synthesis Example 4-1: Synthesis of D-1

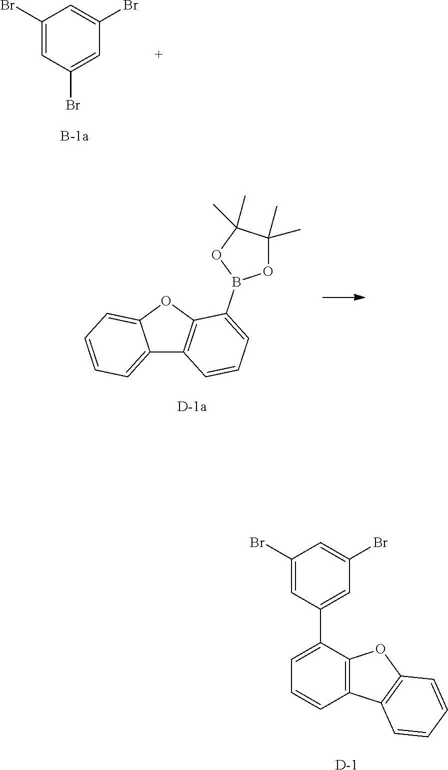

D-1 (yield 59.3%) was synthesized in the same manner as in Synthesis Example 1-2, except that D-1a and B-1a were used instead of A-1 and A-2a, respectively.

### Synthesis Example 4-2: Synthesis of D-2

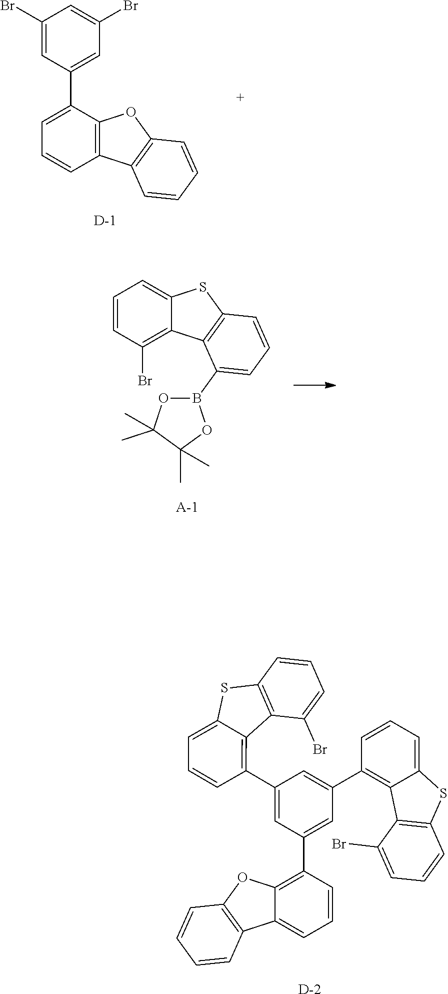

D-2 (yield 67.7%) was synthesized in the same manner as in Synthesis Example 1-2, except that D-1 was used instead of A-2a.

### Synthesis Example 4-3: Synthesis of 15

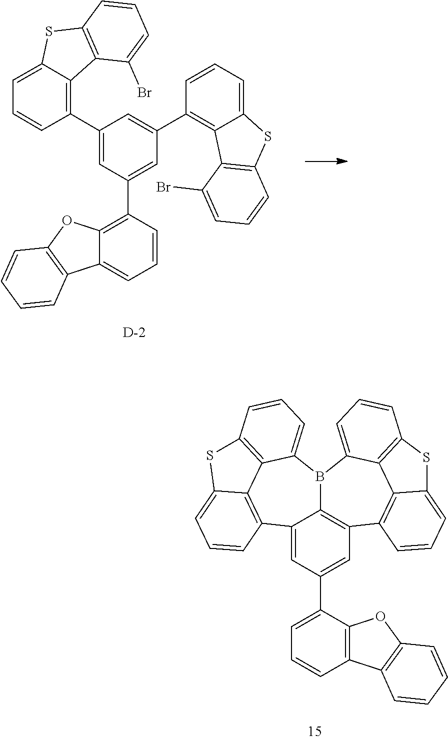

15 (yield 11%) was synthesized in the same manner as in Synthesis Example 1-3, except that D-2 was used instead of A-2.

MS (MALDI-TOF): m/z 616.11 [M⁺]

### Synthesis Example 5: Preparation of 36

### Synthesis Example 5-1: Synthesis of E-1

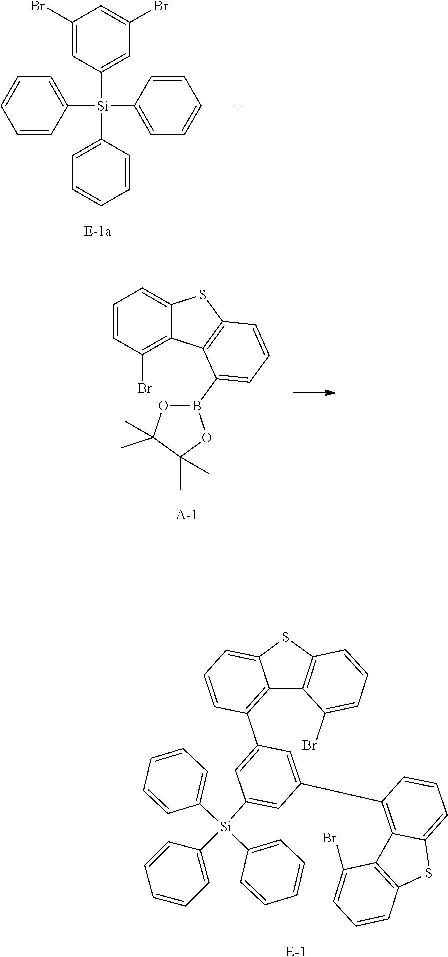

E-1 (yield 72.3%) was synthesized in the same manner as in Synthesis Example 1-2, except that E-1a was used instead of A-2a.

### Synthesis Example 5-2: Synthesis of 36

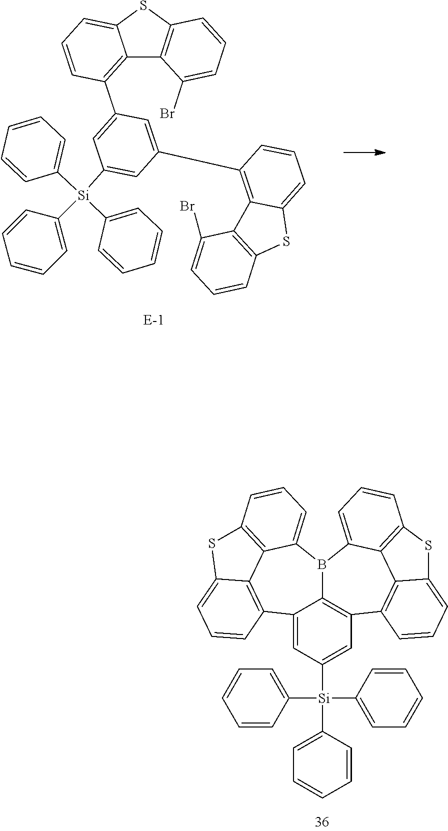 [SMILES: Brc1cccc2sc3cccc(-c4cc(-c5cccc6sc7cccc(Br)c7c56)cc([Si](c5ccccc5)(c5ccccc5)c5ccccc5)c4)c3c12 ; "E-1" ; c1ccc([Si](c2ccccc2)(c2ccccc2)c2cc3c4c(c2)-c2cccc5sc6cccc(c6c25)B4c2cccc4sc5cccc-3c5c24)cc1]

36 (yield 11.2%) was synthesized in the same manner as in Synthesis Example 1-3, except that E-1 was used instead of A-2.

MS (MALDI-TOF): m/z 708.16 [M⁺]

### Synthesis Example 6: Preparation of 45

### Synthesis Example 6-1: Synthesis of F-1

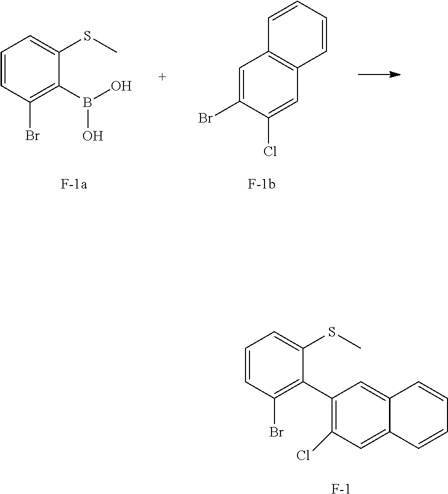

10 g of F-1a, 10.7 g of F-1b, 1.4 g of Pd(PPh₃)₄, and 4.8 g of NaOH were dissolved in THF and a small amount of water in a nitrogen-purged reactor, followed by stirring under reflux for 24 h. After completion of the reaction, the reaction solution was cooled to room temperature and extracted with MC. The organic layer was dried over magnesium sulfate, filtered, and concentrated under reduced pressure. Purification by silica gel column chromatography afforded F-1 (12 g, 81.4%).

### Synthesis Example 6-2: Synthesis of F-2

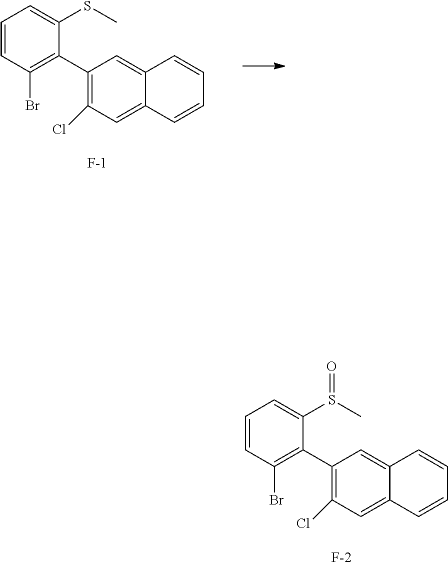

20 g of F-1, 1.9 g of hydrogen peroxide, and 150 mL of acetic acid were stirred under reflux in a nitrogen-purged reactor for 24 h. After completion of the reaction, the reaction solution was cooled to room temperature and extracted with ethyl acetate. The organic layer was dried over magnesium sulfate, filtered, and concentrated under reduced pressure. Purification by silica gel column chromatography afforded F-2 (18.3 g, 87.6%).

### Synthesis Example 6-3: Synthesis of F-3

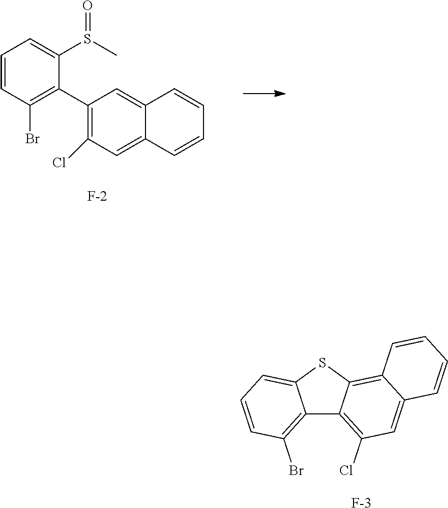

20 g of F-2 and 35 mL of sulfuric acid were stirred under reflux in a reactor for 24 h. After completion of the reaction, the product was neutralized and filtered. The resulting solid was recrystallized to afford F-3 (14.7 g, 80.3%).

### Synthesis Example 6-4: Synthesis of F-4

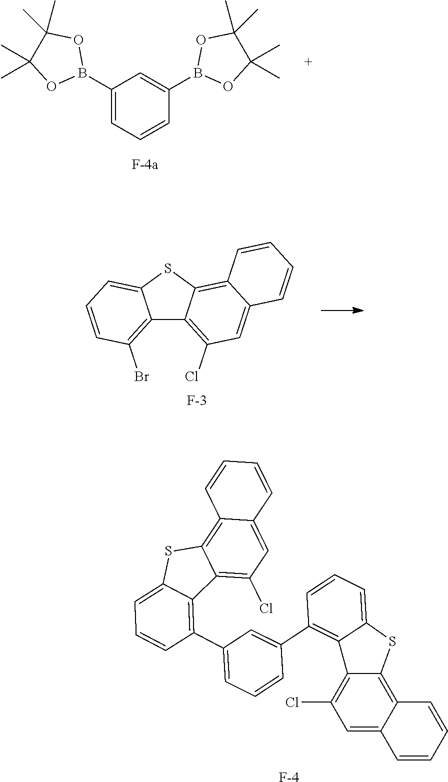

F-4 (yield 71%) was synthesized in the same manner as in Synthesis Example 1-2, except that F-3 and F-4a were used instead of A-2a and A-1, respectively.

### Synthesis Example 6-5: Synthesis of 45

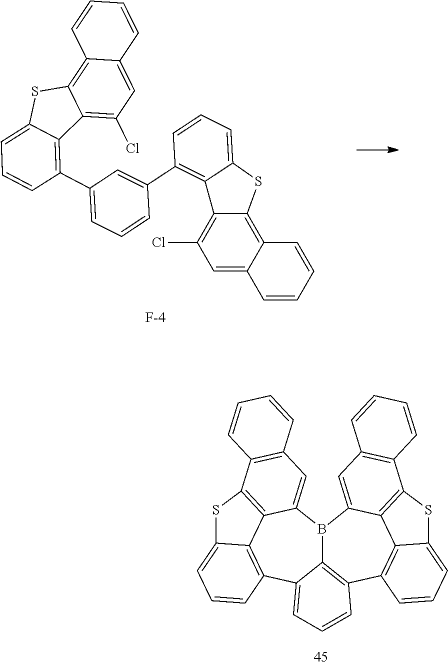

45 (yield 8.7%) was synthesized in the same manner as in Synthesis Example 1-3, except that F-4 was used instead of A-2.

MS (MALDI-TOF): m/z 550.10 [M⁺]

### Synthesis Example 7: Preparation of 48

### Synthesis Example 7-1: Synthesis of G-1

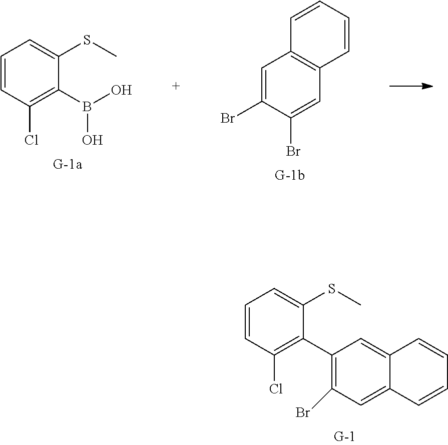 [SMILES: CSc1cccc(Cl)c1B(O)O ; Brc1cc2ccccc2cc1Br ; CSc1cccc(Cl)c1-c1cc2ccccc2cc1Br]

G-1 (yield 82%) was synthesized in the same manner as in Synthesis Example 6-1, except that G-1a and G-1b were used instead of F-1a and F-1b, respectively.

### Synthesis Example 7-2: Synthesis of G-2

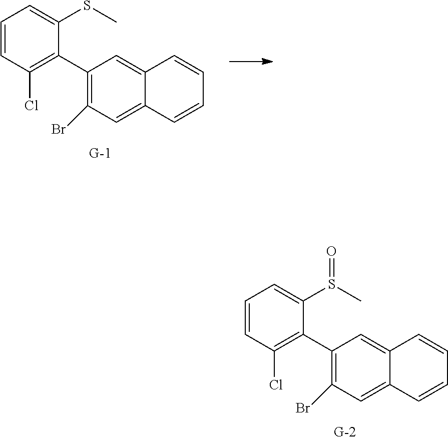 [SMILES: CSc1cccc(Cl)c1-c1cc2ccccc2cc1Br ; CS(=O)c1cccc(Cl)c1-c1cc2ccccc2cc1Br]

G-2 (yield 85%) was synthesized in the same manner as in Synthesis Example 6-2, except that G-1 was used instead of F-1.

### Synthesis Example 7-3: Synthesis of G-3

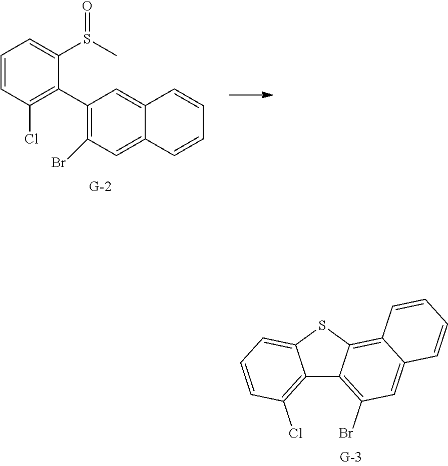 [SMILES: CS(=O)c1cccc(Cl)c1-c1cc2ccccc2cc1Br ; Clc1cccc2sc3c4ccccc4cc(Br)c3c12]

G-3 (yield 81%) was synthesized in the same manner as in Synthesis Example 6-3, except that G-2 was used instead of F-2.

### Synthesis Example 7-4: Synthesis of G-4

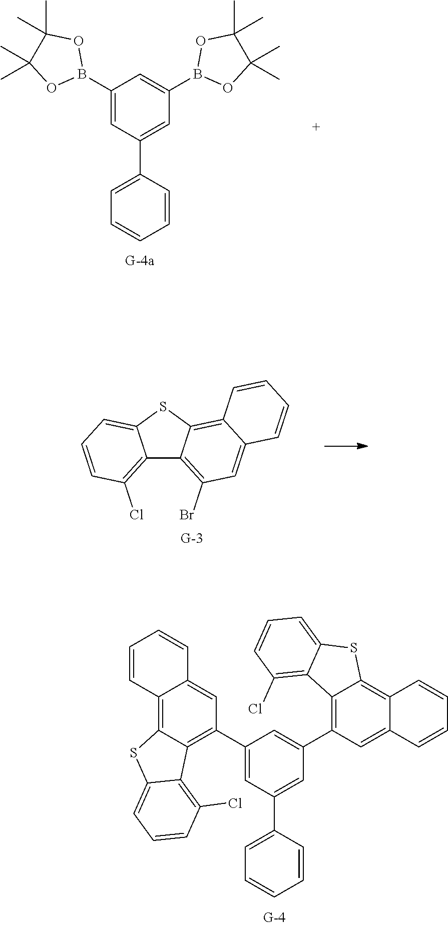

G-4 (yield 73%) was synthesized in the same manner as in Synthesis Example 6-4, except that G-4a and G-3 were used instead of F-4a and F-3, respectively.

### Synthesis Example 7-5: Synthesis of 48

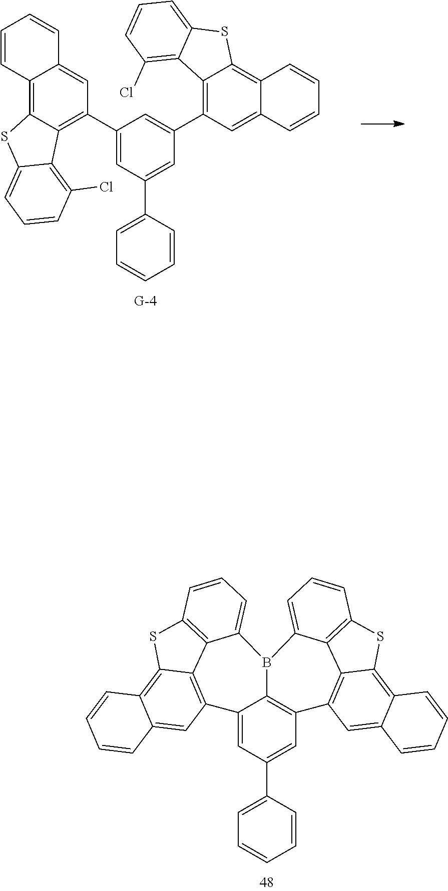 [SMILES: Clc1cccc2sc3c4ccccc4cc(-c4cc(-c5ccccc5)cc(-c5cc6ccccc6c6sc7cccc(Cl)c7c56)c4)c3c12 ; c1ccc(-c2cc3c4c(c2)-c2cc5ccccc5c5sc6cccc(c6c25)B4c2cccc4sc5c6ccccc6cc-3c5c24)cc1]

48 (yield 11%) was synthesized in the same manner as in Synthesis Example 1-3, except that G-4 was used instead of A-2.

MS (MALDI-TOF): m/z 626.13 [M⁺]

### Synthesis Example 8: Preparation of 55

### Synthesis Example 8-1: Synthesis of H-1

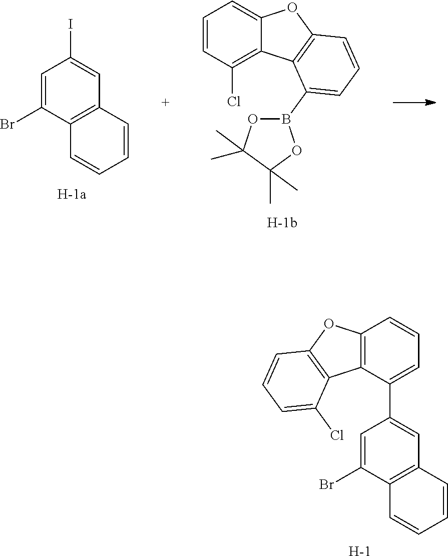

H-1 (yield 66.4%) was synthesized in the same manner as in Synthesis Example 1-2, except that H-1a and H-1b were used instead of A-2a and A-1, respectively.

### Synthesis Example 8-2: Synthesis of H-2

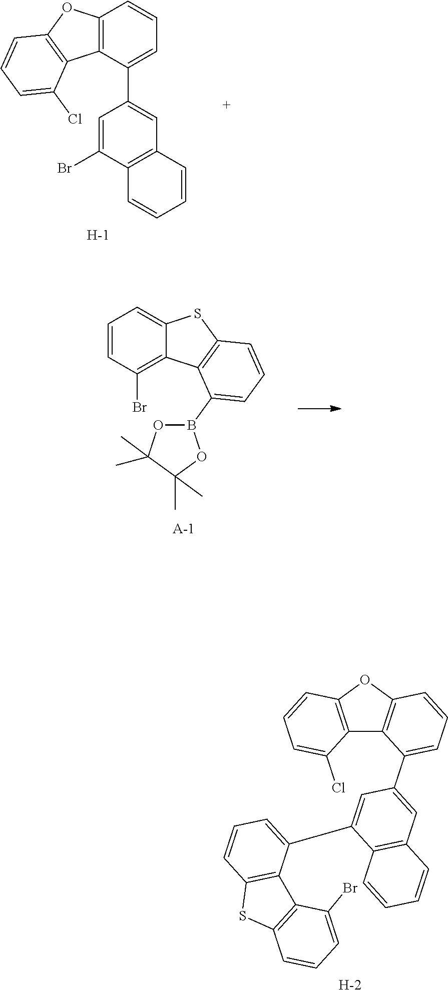

H-2 (yield 71.2%) was synthesized in the same manner as in Synthesis Example 1-2, except that H-1 was used instead of A-2a.

### Synthesis Example 8-3: Synthesis of 55

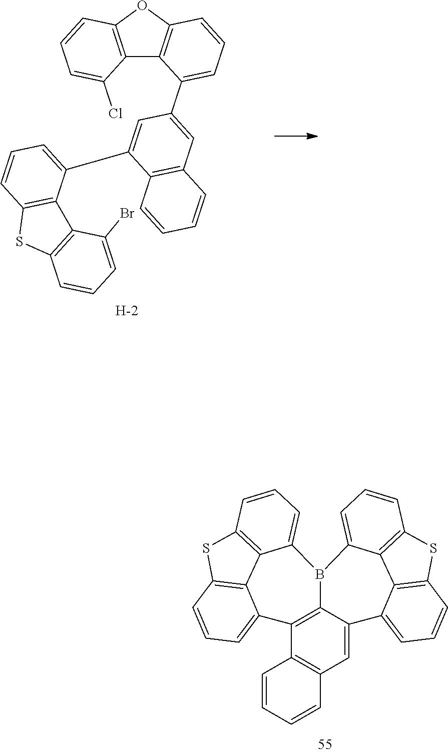

55 (yield 9.7%) was synthesized in the same manner as in Synthesis Example 1-3, except that H-2 was used instead of A-2.

MS (MALDI-TOF): m/z 484.11 [M⁺]

### Synthesis Example 9: Preparation of 2

### Synthesis Example 9-1: Synthesis of 1-1

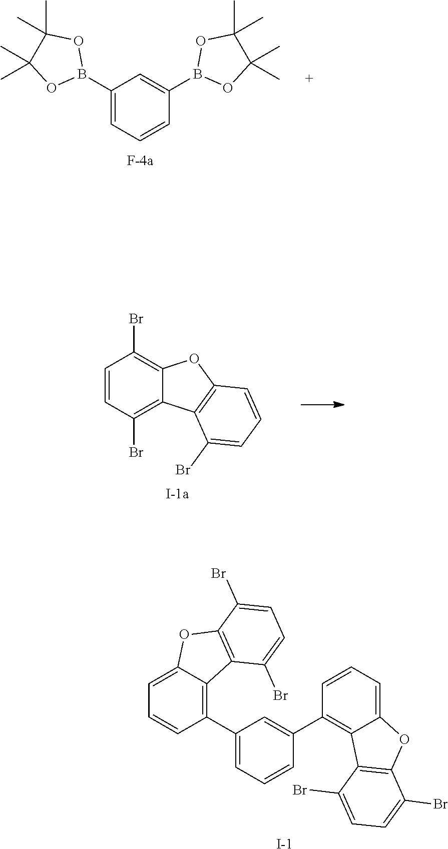

I-1 (yield 74.7%) was synthesized in the same manner as in Synthesis Example 1-2, except that I-1a and F-4a were used instead of A-2a and A-1, respectively.

### Synthesis Example 9-2: Synthesis of 1-2

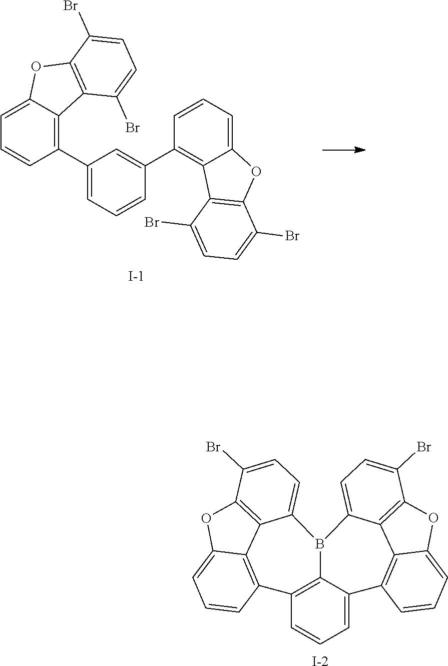

I-2 (yield 12.1%) was synthesized in the same manner as in Synthesis Example 1-3, except that I-1 was used instead of A-2.

### Synthesis Example 9-3: Synthesis of 2

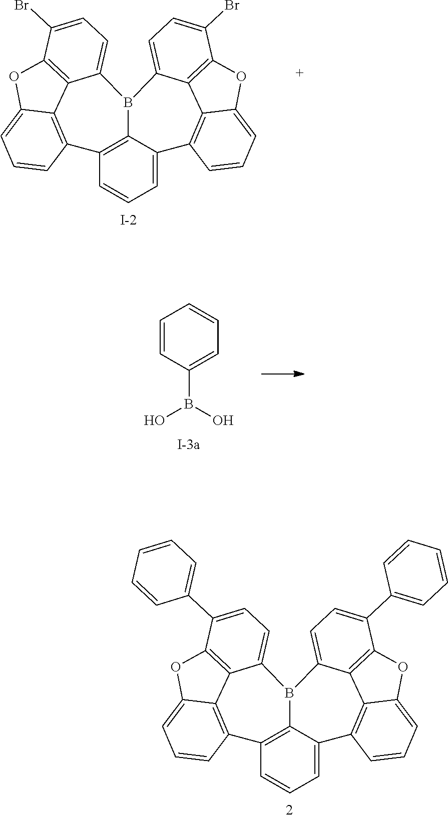

2 (yield 82.9%) was synthesized in the same manner as in Synthesis Example 6-1, except that I-3a and I-2 were used instead of F-1a and F-1b, respectively.

MS (MALDI-TOF): m/z 570.18 [M⁺]

### Synthesis Example 10: Preparation of 43

### Synthesis Example 10-1: Synthesis of J-1

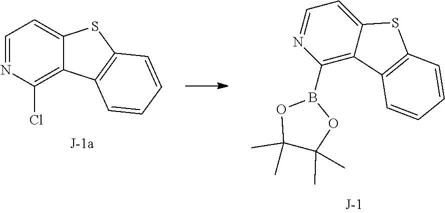 [SMILES: Clc1nccc2sc3ccccc3c12 ; CC1(C)OB(c2nccc3sc4ccccc4c23)OC1(C)C]

J-1 (yield 65.4%) was synthesized in the same manner as in Synthesis Example 1-1, except that J-1a was used instead of A-1a.

### Synthesis Example 10-2: Synthesis of J-2

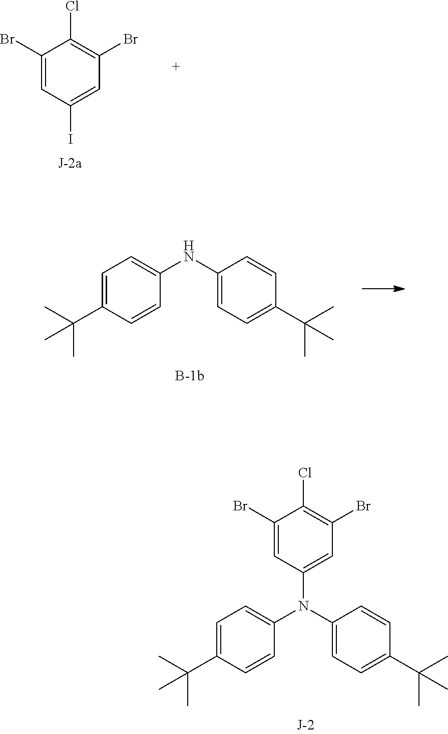

J-2 (yield 52%) was synthesized in the same manner as in Synthesis Example 2-1, except that J-2a was used instead of B-1a.

### Synthesis Example 10-3: Synthesis of J-3

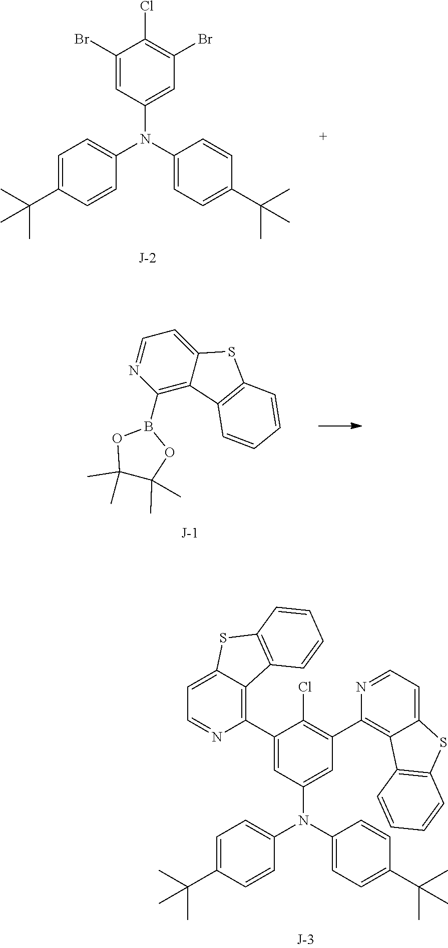

J-3 (yield 61.5%) was synthesized in the same manner as in Synthesis Example 1-2, except that J-2 and J-1 were used instead of A-2a and A-1, respectively.

### Synthesis Example 10-4: Synthesis of 43

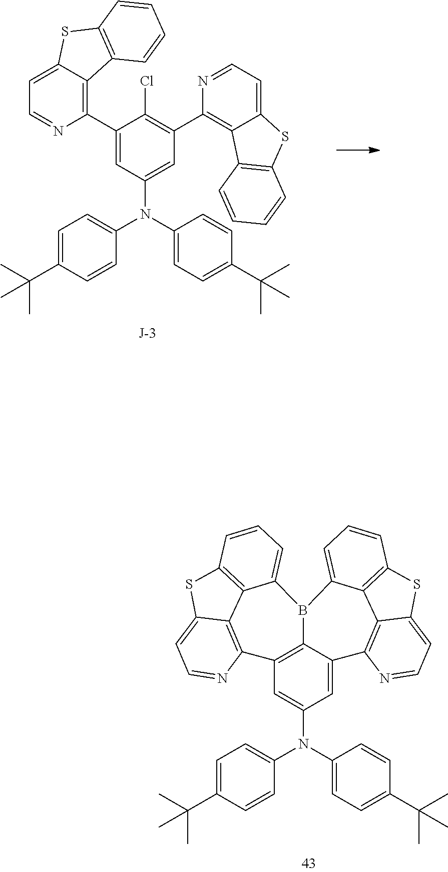

43 (yield 11.7%) was synthesized in the same manner as in Synthesis Example 1-3, except that J-3 was used instead of A-2.

MS (MALDI-TOF): m/z 731.26 [M⁺]

### Examples 1-10: Fabrication of Organic Light Emitting Devices

ITO glass was patterned to have a light emitting area of 2 mm×2 mm, followed by cleaning. After the cleaned ITO glass was mounted in a vacuum chamber, the base pressure was adjusted to 1×10⁻⁷ torr. The compound represented by Acceptor-1 as an electron acceptor and the compound represented by Formula F were deposited in a ratio of 2:98 on the ITO to form a 100 Å thick hole injecting layer. The compound represented by Formula F was used to form a 550 Å thick hole transport layer. Subsequently, the compound represented by Formula G was used to form a 50 Å thick electron blocking layer. A mixture of the host represented by BH-1 and the inventive compound (2 wt %) shown in Table 1 was used to form a 200 Å thick light emitting layer. Thereafter, the compound represented by Formula H was used to form a 50 Å hole blocking layer on the light emitting layer. A mixture of the compound represented by Formula E-1 and the compound represented by Formula E-2 in a ratio of 1:1 was used to form a 250 Å thick electron transport layer on the hole blocking layer. The compound represented by Formula E-2 was used to form a 10 Å thick electron injecting layer on the electron transport layer. Al was used to form a 1000 Å thick Al electrode on the electron injecting layer, completing the fabrication of an organic light emitting device. The luminescent properties of the organic light emitting device were measured at 0.4 mA.

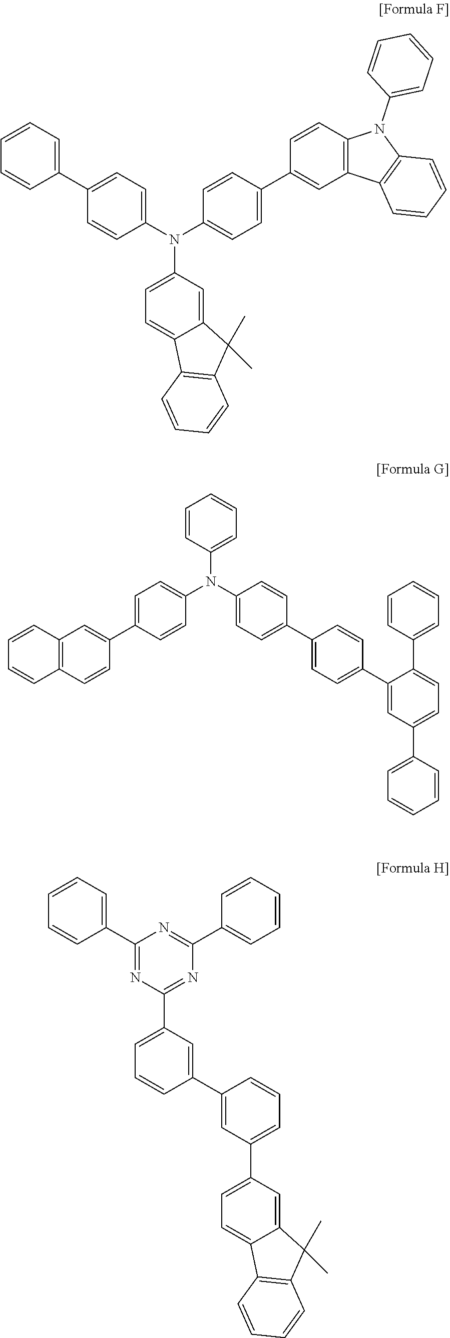 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(-c3ccccc3)c(-c3ccc(-c4ccc(N(c5ccccc5)c5ccc(-c6ccc7ccccc7c6)cc5)cc4)cc3)c2)cc1 ; CC1(C)c2ccccc2-c2ccc(-c3cccc(-c4cccc(-c5nc(-c6ccccc6)nc(-c6ccccc6)n5)c4)c3)cc21]

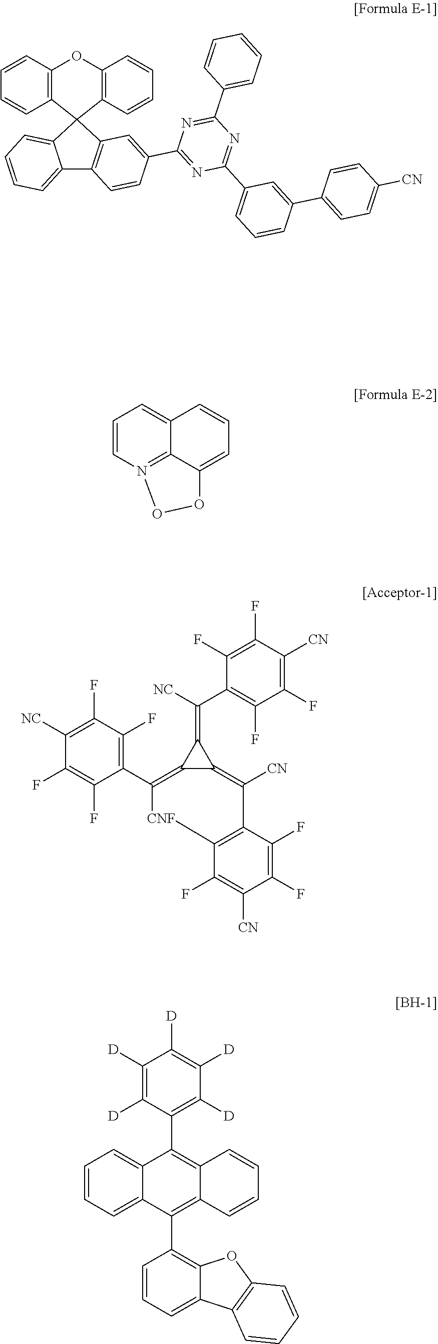

### Comparative Example 1

An organic light emitting device was fabricated in the same manner as in Examples 1-10, except that RD-1 was used instead of the inventive compound. The luminescent properties of the organic light emitting device were measured at 0.4 mA. The structure of RD-1 is as follow:

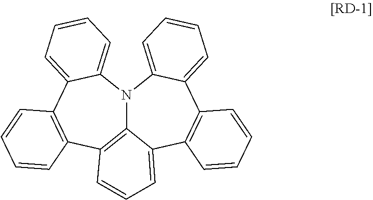 [SMILES: c1ccc2c(c1)-c1ccccc1N1c3ccccc3-c3ccccc3-c3cccc-2c31]

The organic light emitting devices of Examples 1-10 and Comparative Example 1 were measured for external quantum efficiency and lifetime. The results are shown in Table 1.

TABLE 1

| | | Efficiency | Lifetime |
|---|---|---|---|
| Example No. | Dopant | (EQE, %) | (T97, hr) |
| Example 1 | 1 | 7.1 | 115 |
| Example 2 | 2 | 7.2 | 120 |
| Example 3 | 8 | 8.2 | 140 |
| Example 4 | 11 | 7.8 | 130 |
| Example 5 | 15 | 8.0 | 125 |
| Example 6 | 36 | 8.6 | 145 |
| Example 7 | 43 | 7.5 | 110 |
| Example 8 | 45 | 7.4 | 115 |
| Example 9 | 48 | 7.5 | 120 |
| Example 10 | 55 | 6.8 | 100 |
| Comparative Example 1 | RD-1 | 4.9 | 55 |

As can be seen from the results in Table 1, the organic light emitting devices of Examples 1-10, each of which employed the inventive dopant compound for the light emitting layer, had high quantum efficiencies and improved life characteristics compared to the organic light emitting device of Comparative Example 1, which employed the compound whose specific structure is contrasted with those of the inventive compounds. These results concluded that the use of the inventive compounds makes the organic light emitting devices highly efficient and long lasting.

What is claimed is:

1. A polycyclic compound represented by Formula 1: 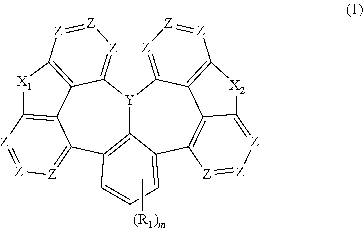
wherein
Y is selected from B, N, P═O, and P═S,
each Z is independently CR or N,
X₁ and X₂ are the same as or different from each other and are each independently selected from O, S, Se, NR₂, CR₃R₄, SiR₅R₆, and GeR₇R₈,
R and R₁ to R₈ are the same as or different from each other and are each independently selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, cyclic groups in which a substituted or unsubstituted C₃-C₃₀ aliphatic ring and a C₅-C₃₀ aromatic ring are fused together, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, nitro, cyano, and halogen, with the proviso that adjacent ones of the groups R are optionally linked to each other to form an alicyclic or aromatic mono- or polycyclic ring, that R₃ and R₄ are optionally linked to each other to form an alicyclic or aromatic mono- or polycyclic ring, that R₅ and R₆ are optionally linked to each other to form an alicyclic or aromatic mono- or polycyclic ring, and that R₇ and R₅ are optionally linked to each other to form an alicyclic or aromatic mono- or polycyclic ring, and
m is an integer of 3, with the proviso that adjacent ones of the groups R₁ are optionally linked to each other to form an alicyclic or aromatic mono- or polycyclic ring,
the “substituted” in the definitions of Z, X₁, X₂, and R₁ in Formula 1 indicating substitution with one or more substituents selected from deuterium, C₁-C₂₄ alkyl, C₁-C₂₄ haloalkyl, C₂-C₂₄ alkenyl, C₂-C₂₄ alkynyl, C₃-C₃₀ cycloalkyl, C₁-C₂₄ heteroalkyl, C₆-C₃₀ aryl, C₇-C₃₀ arylalkyl, C₇-C₃₀ alkylaryl, C₂-C₃₀ heteroaryl, C₂-C₃₀ heteroarylalkyl, cyclic groups in which a C₃-C₂₄ aliphatic ring and a C₅-C₂₄ aromatic ring are fused together, C₁-C₂₄ alkoxy, C₁-C₃₀ amine, C₁-C₃₀ silyl, C₁-C₃₀ germanium, C₆-C₂₄ aryloxy, C₆-C₂₄ arylthionyl, cyano, halogen, hydroxyl, and nitro, or a combination thereof,
the “unsubstituted” in the same definition indicating having no substituent, one or more hydrogen atoms in each of the substituents being optionally replaced by deuterium atoms, and two or more adjacent ones of the substituents being optionally linked to each other to form an alicyclic or aromatic mono- or polycyclic ring.

2. The polycyclic compound according to claim 1, wherein Y in Formula 1 is B.

3. The polycyclic compound according to claim 1, wherein at least one of the groups R₁ in Formula 1 is other than hydrogen or deuterium.

4. The polycyclic compound according to claim 1, wherein X₁ and X₂ in Formula 1 are each independently O or S.

5. The polycyclic compound according to claim 1, wherein the compound represented by Formula 1 is selected from the following compounds 1 to 60:

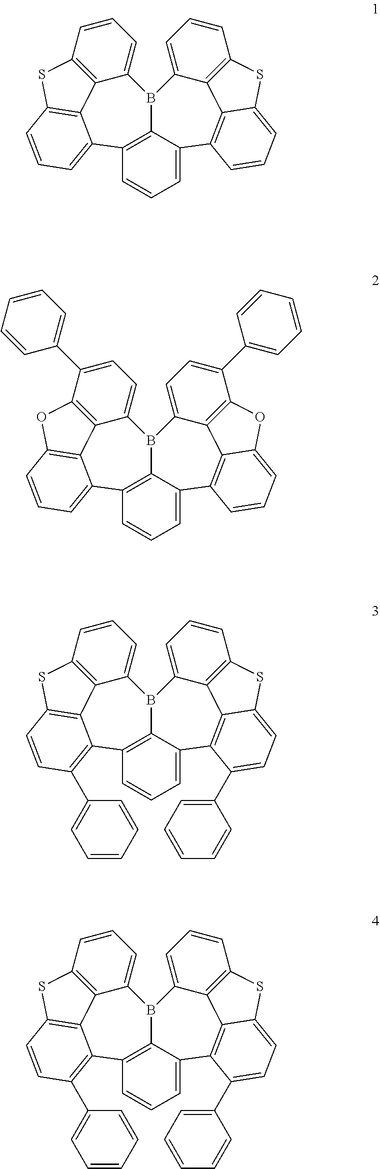 [SMILES: c1cc2c3c(c1)-c1cccc4sc5cccc(c5c14)B3c1cccc3sc4cccc-2c4c13 ; c1ccc(-c2ccc3c4c2oc2cccc(c24)-c2cccc4c2B3c2ccc(-c3ccccc3)c3oc5cccc-4c5c23)cc1 ; c1ccc(-c2ccc3sc4cccc5c4c3c2-c2cccc3c2B5c2cccc4sc5ccc(-c6ccccc6)c-3c5c24)cc1 ; c1ccc(-c2ccc3sc4cccc5c4c3c2-c2cccc3c2B5c2cccc4sc5ccc(-c6ccccc6)c-3c5c24)cc1]

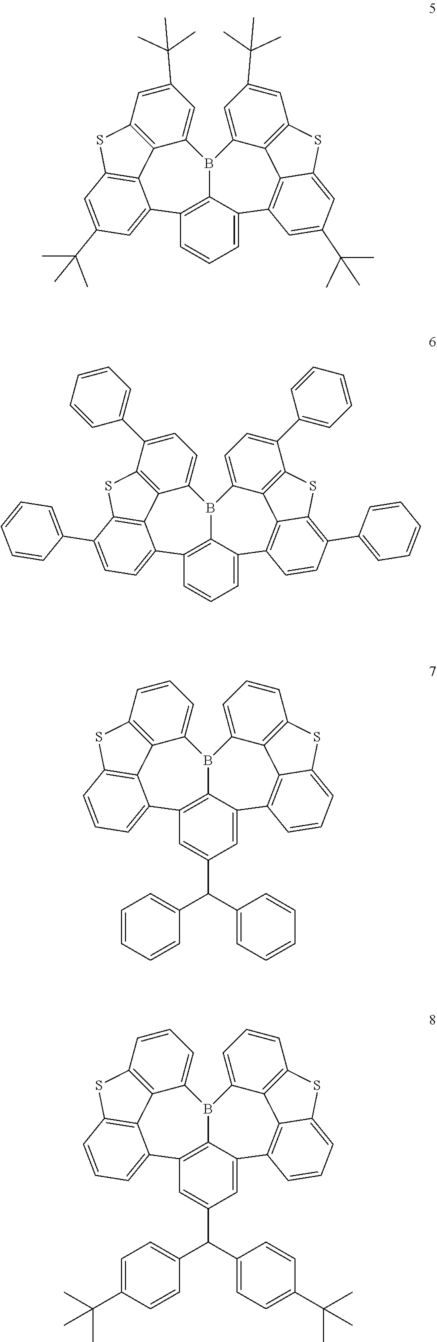

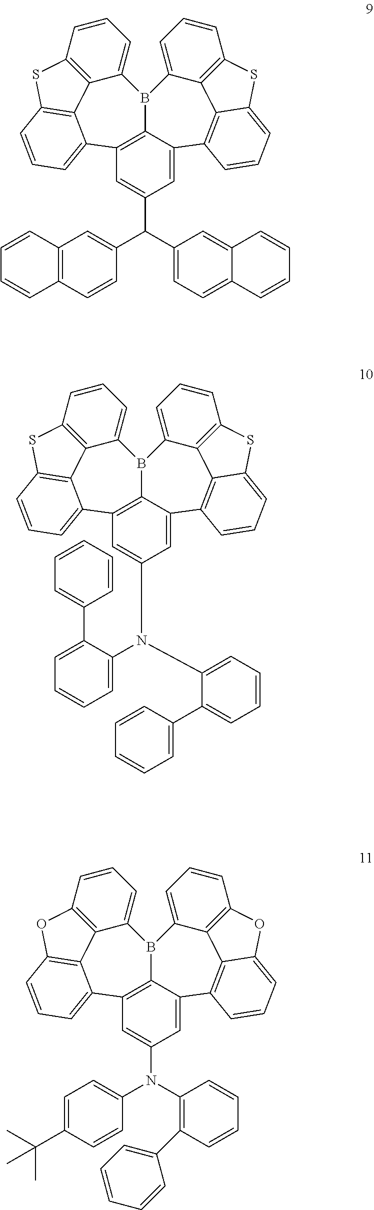 [SMILES: c1ccc2cc(C(c3cc4c5c(c3)-c3cccc6sc7cccc(c7c36)B5c3cccc5sc6cccc-4c6c35)c3ccc4ccccc4c3)ccc2c1 ; c1ccc(-c2ccccc2N(c2cc3c4c(c2)-c2cccc5sc6cccc(c6c25)B4c2cccc4sc5cccc-3c5c24)c2ccccc2-c2ccccc2)cc1 ; CC(C)(C)c1ccc(N(c2cc3c4c(c2)-c2cccc5oc6cccc(c6c25)B4c2cccc4oc5cccc-3c5c24)c2ccccc2-c2ccccc2)cc1]

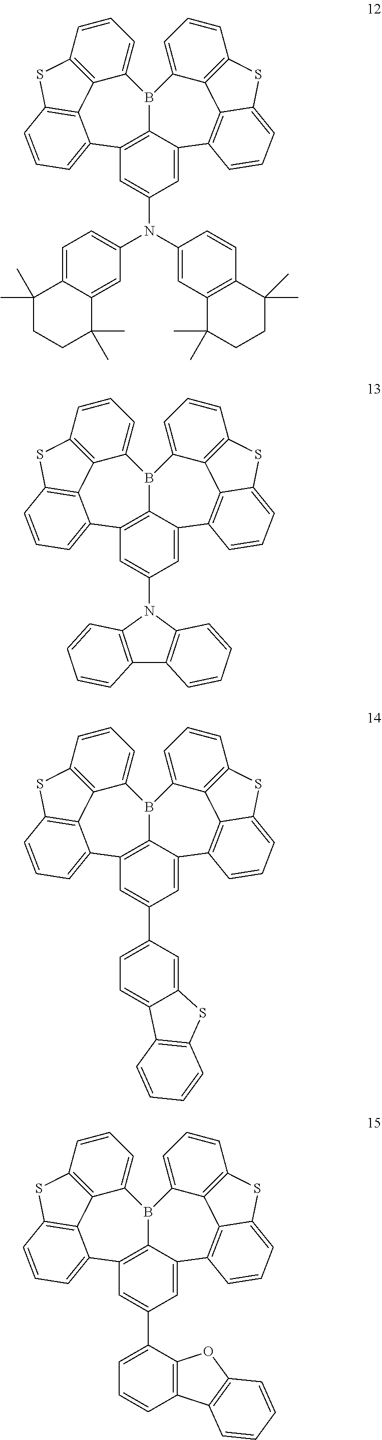

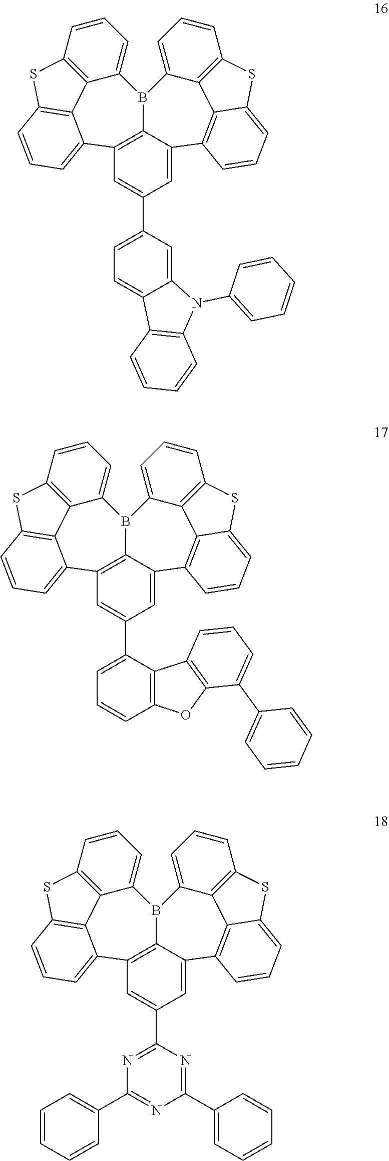 [SMILES: c1ccc(-n2c3ccccc3c3ccc(-c4cc5c6c(c4)-c4cccc7sc8cccc(c8c47)B6c4cccc6sc7cccc-5c7c46)cc32)cc1 ; c1ccc(-c2cccc3c2oc2cccc(-c4cc5c6c(c4)-c4cccc7sc8cccc(c8c47)B6c4cccc6sc7cccc-5c7c46)c23)cc1 ; c1ccc(-c2nc(-c3ccccc3)nc(-c3cc4c5c(c3)-c3cccc6sc7cccc(c7c36)B5c3cccc5sc6cccc-4c6c35)n2)cc1]

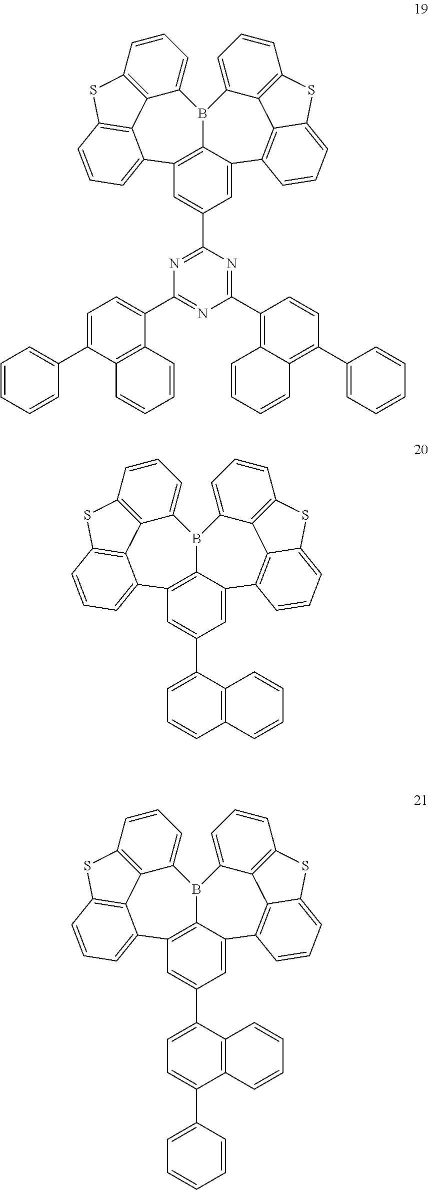 [SMILES: c1ccc(-c2ccc(-c3nc(-c4cc5c6c(c4)-c4cccc7sc8cccc(c8c47)B6c4cccc6sc7cccc-5c7c46)nc(-c4ccc(-c5ccccc5)c5ccccc45)n3)c3ccccc23)cc1 ; c1ccc2c(-c3cc4c5c(c3)-c3cccc6sc7cccc(c7c36)B5c3cccc5sc6cccc-4c6c35)cccc2c1 ; c1ccc(-c2ccc(-c3cc4c5c(c3)-c3cccc6sc7cccc(c7c36)B5c3cccc5sc6cccc-4c6c35)c3ccccc23)cc1]

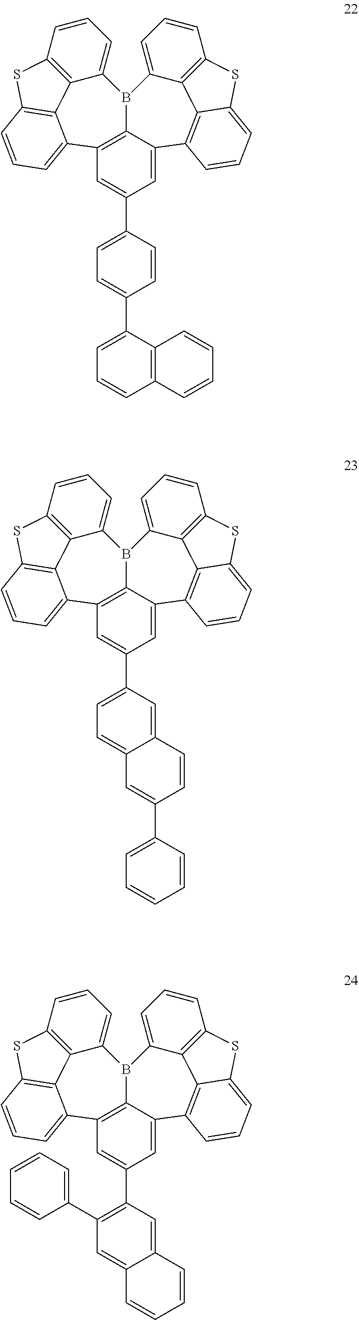 [SMILES: c1ccc2c(-c3ccc(-c4cc5c6c(c4)-c4cccc7sc8cccc(c8c47)B6c4cccc6sc7cccc-5c7c46)cc3)cccc2c1 ; c1ccc(-c2ccc3cc(-c4cc5c6c(c4)-c4cccc7sc8cccc(c8c47)B6c4cccc6sc7cccc-5c7c46)ccc3c2)cc1 ; c1ccc(-c2cc3ccccc3cc2-c2cc3c4c(c2)-c2cccc5sc6cccc(c6c25)B4c2cccc4sc5cccc-3c5c24)cc1]

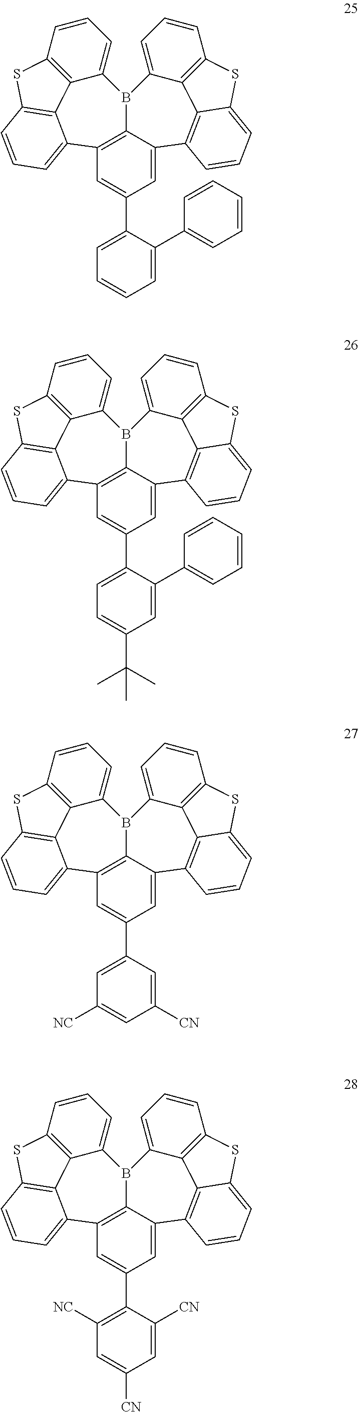 [SMILES: c1ccc(-c2ccccc2-c2cc3c4c(c2)-c2cccc5sc6cccc(c6c25)B4c2cccc4sc5cccc-3c5c24)cc1 ; CC(C)(C)c1ccc(-c2cc3c4c(c2)-c2cccc5sc6cccc(c6c25)B4c2cccc4sc5cccc-3c5c24)c(-c2ccccc2)c1 ; N#Cc1cc(C#N)cc(-c2cc3c4c(c2)-c2cccc5sc6cccc(c6c25)B4c2cccc4sc5cccc-3c5c24)c1 ; N#Cc1cc(C#N)c(-c2cc3c4c(c2)-c2cccc5sc6cccc(c6c25)B4c2cccc4sc5cccc-3c5c24)c(C#N)c1]

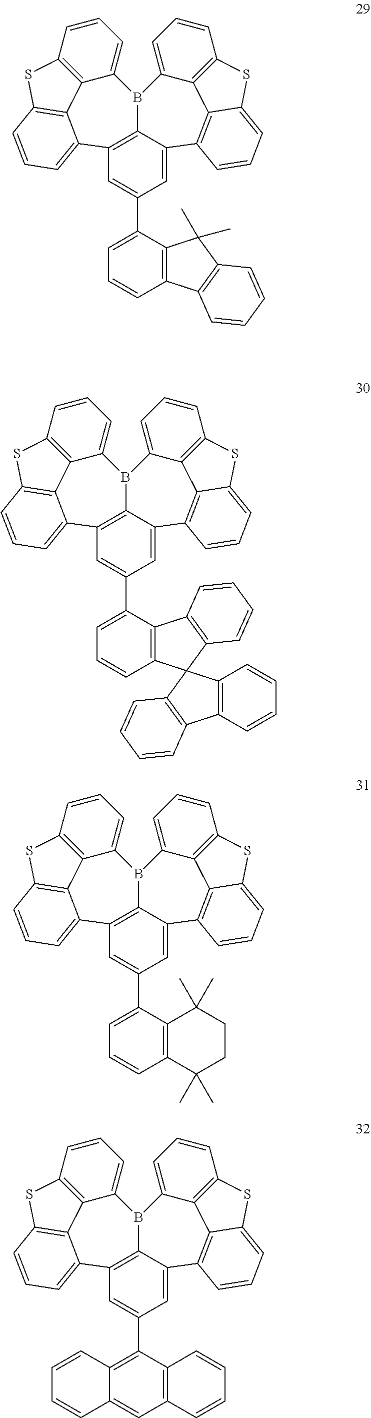

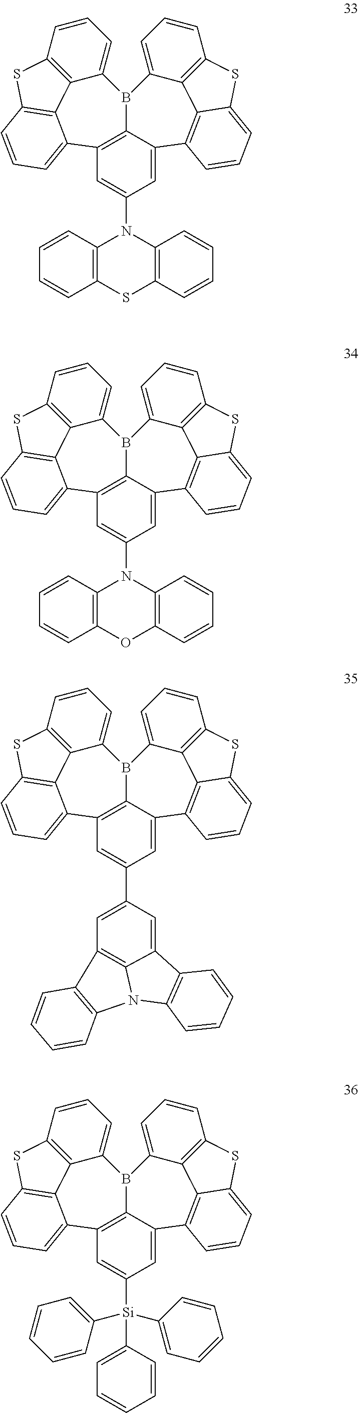 [SMILES: c1ccc2c(c1)Sc1ccccc1N2c1cc2c3c(c1)-c1cccc4sc5cccc(c5c14)B3c1cccc3sc4cccc-2c4c13 ; c1ccc2c(c1)Oc1ccccc1N2c1cc2c3c(c1)-c1cccc4sc5cccc(c5c14)B3c1cccc3sc4cccc-2c4c13 ; c1cc2c3c(c1)sc1cccc(c13)-c1cc(-c3cc4c5ccccc5n5c6ccccc6c(c3)c45)cc3c1B2c1cccc2sc4cccc-3c4c12 ; c1ccc([Si](c2ccccc2)(c2ccccc2)c2cc3c4c(c2)-c2cccc5sc6cccc(c6c25)B4c2cccc4sc5cccc-3c5c24)cc1]

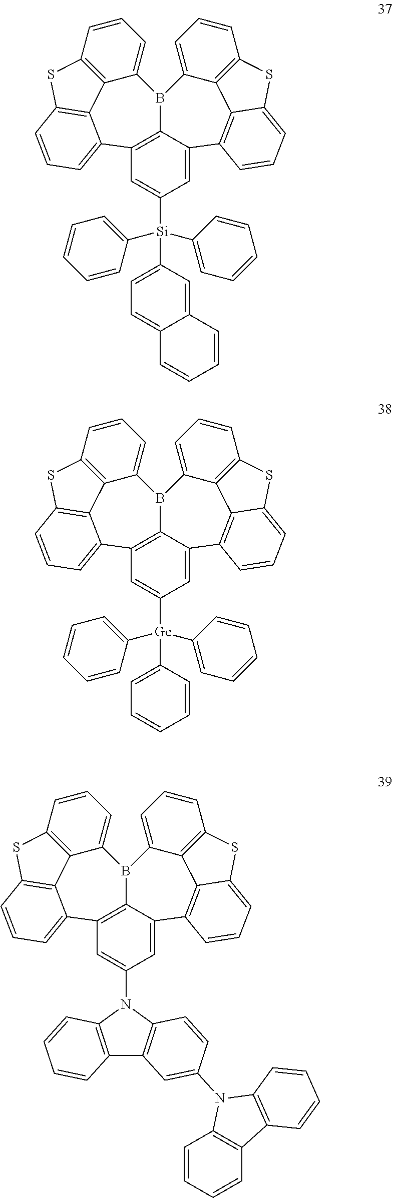

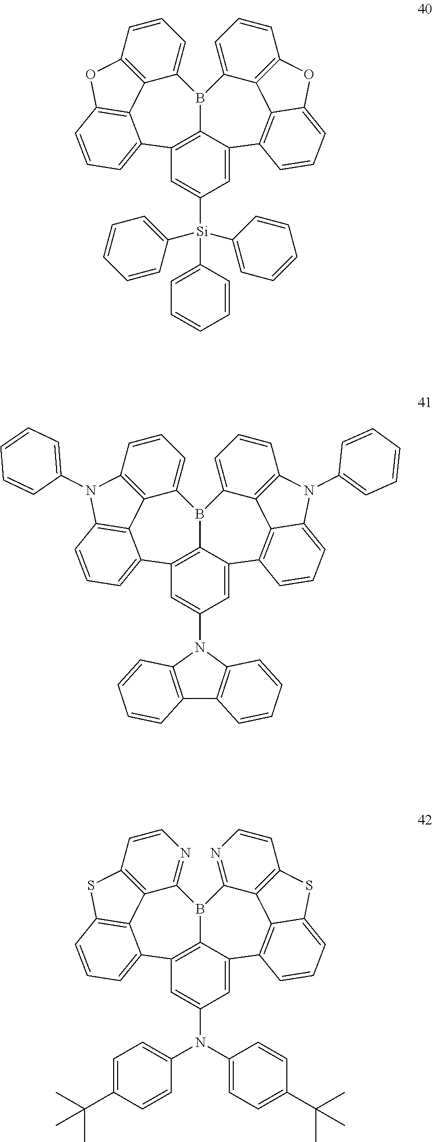 [SMILES: c1ccc([Si](c2ccccc2)(c2ccccc2)c2cc3c4c(c2)-c2cccc5oc6cccc(c6c25)B4c2cccc4oc5cccc-3c5c24)cc1 ; c1ccc(-n2c3cccc4c3c3c(cccc32)-c2cc(-n3c5ccccc5c5ccccc53)cc3c2B4c2cccc4c2c2c-3cccc2n4-c2ccccc2)cc1 ; CC(C)(C)c1ccc(N(c2ccc(C(C)(C)C)cc2)c2cc3c4c(c2)-c2cccc5sc6ccnc(c6c25)B4c2nccc4sc5cccc-3c5c24)cc1]

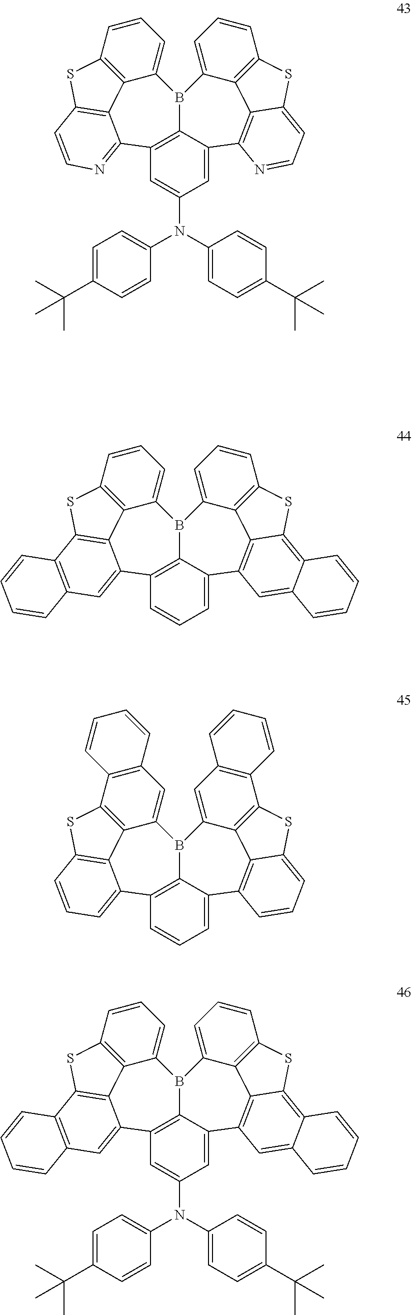 [SMILES: CC(C)(C)c1ccc(N(c2ccc(C(C)(C)C)cc2)c2cc3c4c(c2)-c2nccc5sc6cccc(c6c25)B4c2cccc4sc5ccnc-3c5c24)cc1 ; c1cc2c3c(c1)-c1cc4ccccc4c4sc5cccc(c5c14)B3c1cccc3sc4c5ccccc5cc-2c4c13 ; c1cc2c3c(c1)-c1cccc4sc5c6ccccc6cc(c5c14)B3c1cc3ccccc3c3sc4cccc-2c4c13 ; CC(C)(C)c1ccc(N(c2ccc(C(C)(C)C)cc2)c2cc3c4c(c2)-c2cc5ccccc5c5sc6cccc(c6c25)B4c2cccc4sc5c6ccccc6cc-3c5c24)cc1]

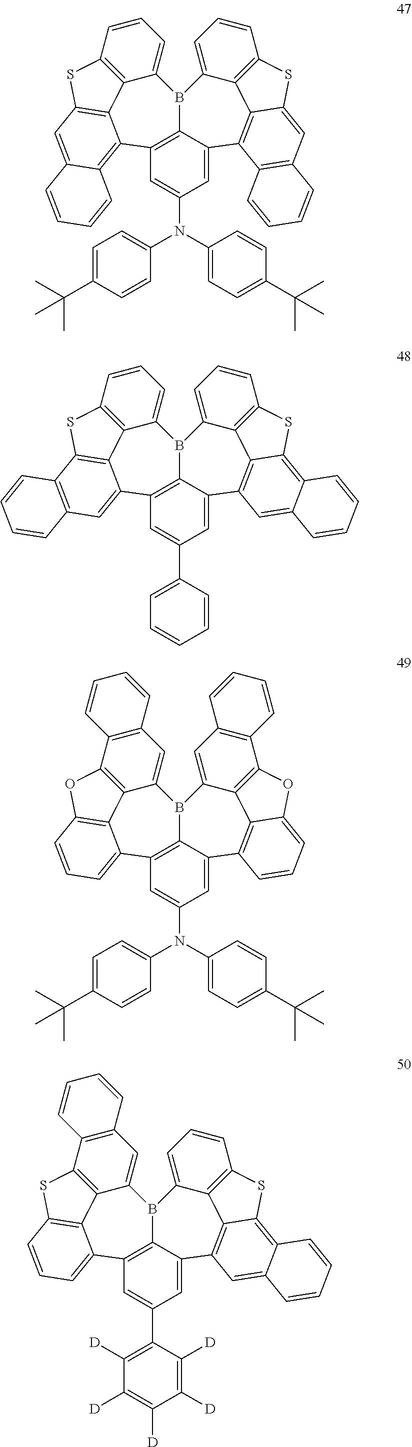

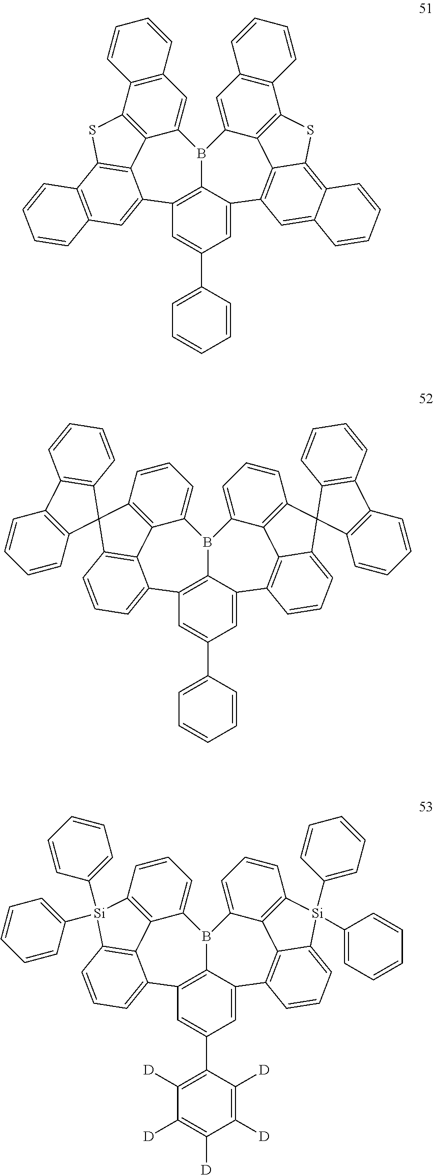 [SMILES: c1ccc(-c2cc3c4c(c2)-c2cc5ccccc5c5sc6c7ccccc7cc(c6c25)B4c2cc4ccccc4c4sc5c6ccccc6cc-3c5c24)cc1 ; c1ccc(-c2cc3c4c(c2)-c2cccc5c2-c2c(cccc2C52c5ccccc5-c5ccccc52)B4c2cccc4c2-c2c-3cccc2C42c3ccccc3-c3ccccc32)cc1 ; [2H]c1c([2H])c([2H])c(-c2cc3c4c(c2)-c2cccc5c2-c2c(cccc2[Si]5(c2ccccc2)c2ccccc2)B4c2cccc4c2-c2c-3cccc2[Si]4(c2ccccc2)c2ccccc2)c([2H])c1[2H]]

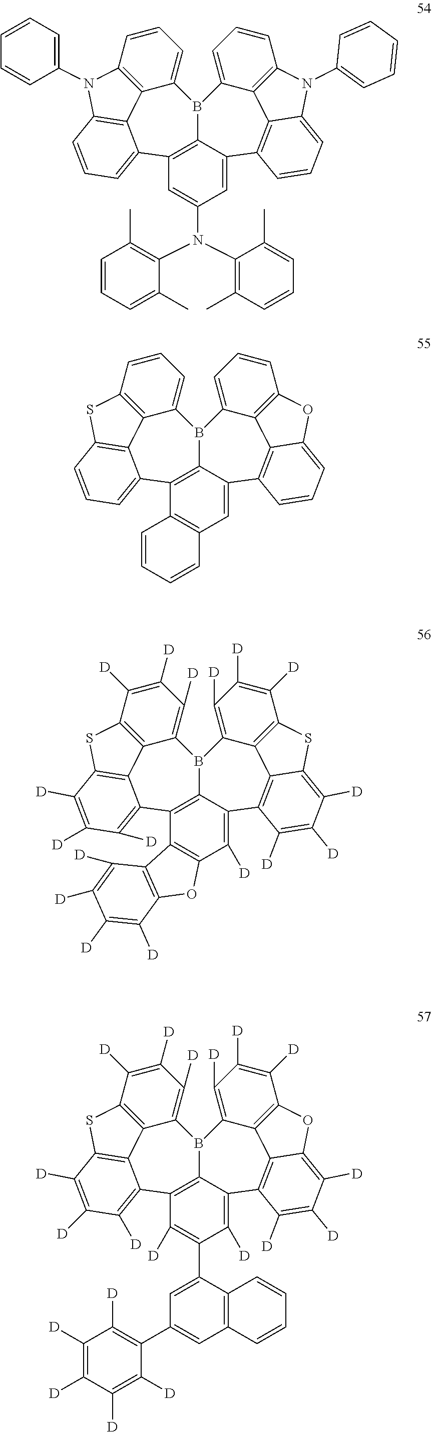

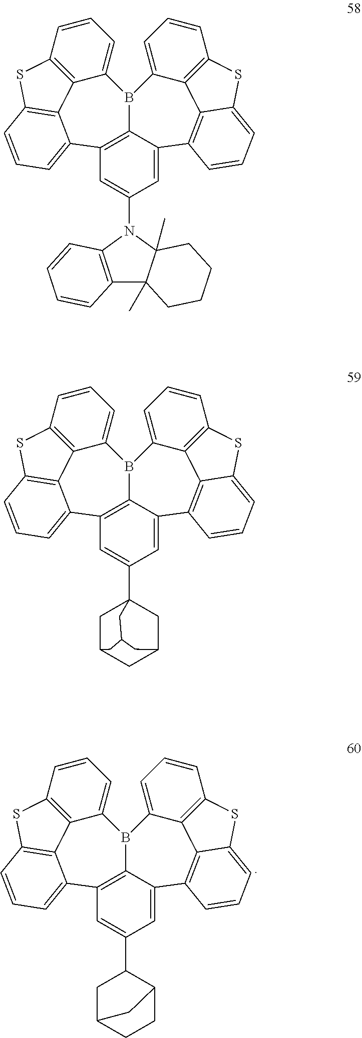 [SMILES: CC12CCCCC1(C)N(c1cc3c4c(c1)-c1cccc5sc6cccc(c6c15)B4c1cccc4sc5cccc-3c5c14)c1ccccc12 ; c1cc2c3c(c1)sc1cccc(c13)-c1cc(C34CC5CC(CC(C5)C3)C4)cc3c1B2c1cccc2sc4cccc-3c4c12 ; c1cc2c3c(c1)sc1cccc(c13)-c1cc(C3CC4CCC3C4)cc3c1B2c1cccc2sc4cccc-3c4c12]

6. An organic light emitting device comprising a first electrode, a second electrode opposite to the first electrode, and one or more organic layers interposed between the first and second electrodes wherein one of the organic layers comprises the polycyclic compound according to claim 1.

7. The organic light emitting device according to claim 6, wherein the organic layers comprise a hole injecting layer, a hole transport layer, an electron blocking layer, a functional layer having functions of both hole injection and hole transport, a light emitting layer, an electron transport layer, an electron injecting layer, a hole blocking layer, and/or a functional layer having functions of both electron injection and electron transport.

8. The organic light emitting device according to claim 7, wherein the light emitting layer is composed of a host and a dopant and the polycyclic compound represented by Formula 1 is used as the dopant.

9. The organic light emitting device according to claim 8, wherein one or more dopant compounds other than the polycyclic compound represented by Formula 1 are mixed or stacked in the light emitting layer.

10. The organic light emitting device according to claim 9, wherein at least one of the mixed or stacked dopant compounds other than the polycyclic compound represented by Formula 1 is an organometallic compound.

11. The organic light emitting device according to claim 8, wherein the host is an anthracene compound represented by Formula 2: 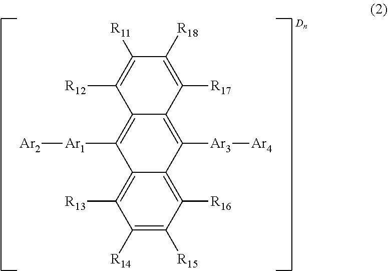
wherein R₁₁ to R₁₈ are the same as or different from each other and are each independently selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, cyclic groups in which a substituted or unsubstituted C₃-C₃₀ aliphatic ring and a C₅-C₃₀ aromatic ring are fused together, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, nitro, cyano, and halogen,
Ar₁ and Ar₃ are the same as or different from each other and are each independently a single bond or selected from substituted or unsubstituted C₆-C₃₀ arylene, substituted or unsubstituted C₅-C₃₀ heteroarylene, and divalent cyclic groups in which a substituted or unsubstituted C₃-C₃₀ aliphatic ring and a C₅-C₃₀ aromatic ring are fused together,
Ar₂ and Ar₄ are the same as or different from each other and are each independently selected from substituted or unsubstituted C₆-C₅₀ aryl, substituted or unsubstituted C₃-C₃₀ cycloalkyl, substituted or unsubstituted C₃-C₃₀ heterocycloalkyl, substituted or unsubstituted C₂-C₅₀ heteroaryl, and cyclic groups in which a substituted or unsubstituted C₃-C₃₀ aliphatic ring and a C₅-C₃₀ aromatic ring are fused together,
Dₙ represents the number of deuterium atoms replacing hydrogen atoms, and
n is an integer from 0 to 50.

12. The organic light emitting device according to claim 11, wherein the anthracene compound represented by Formula 2 is selected from the following compounds:

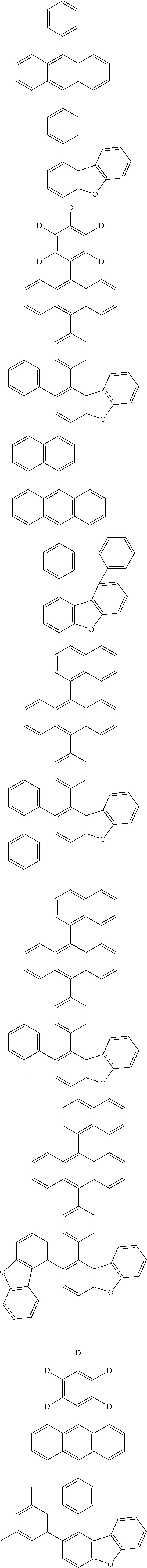

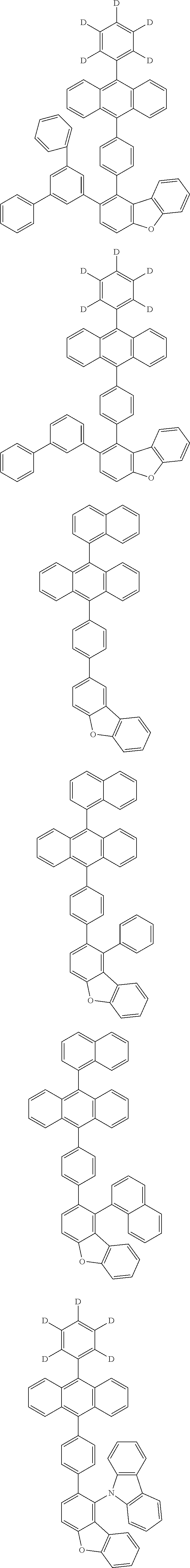

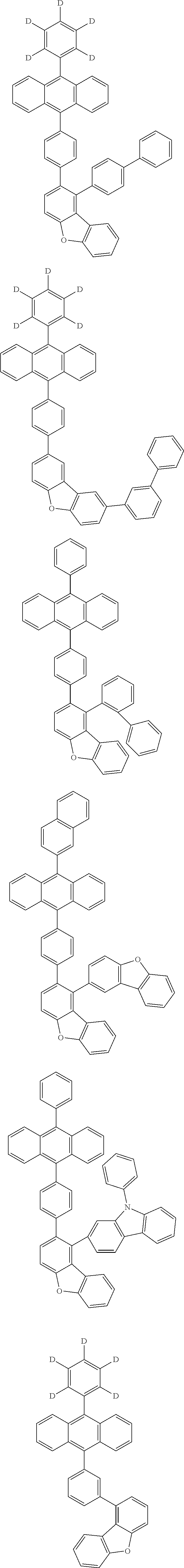

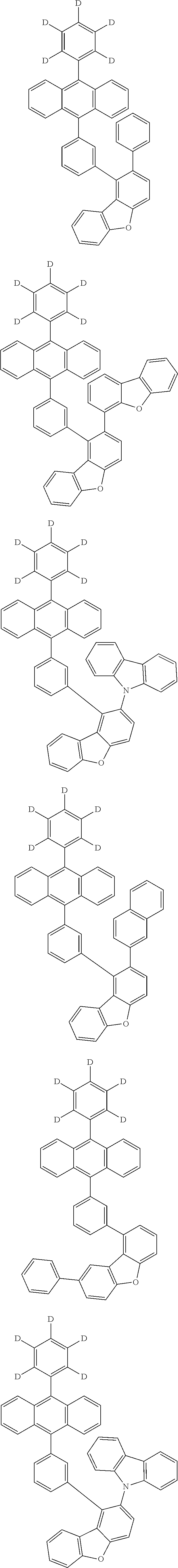

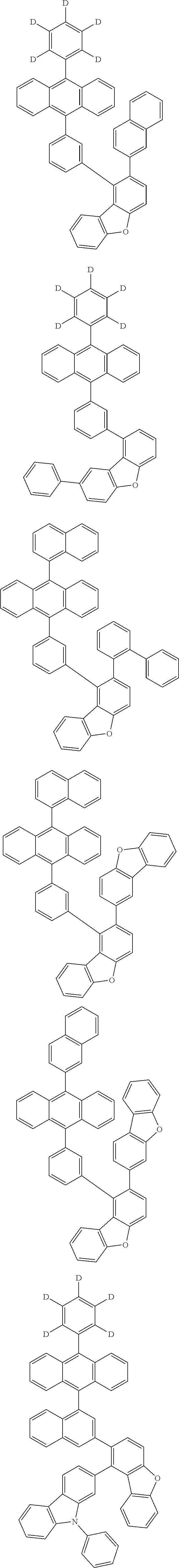

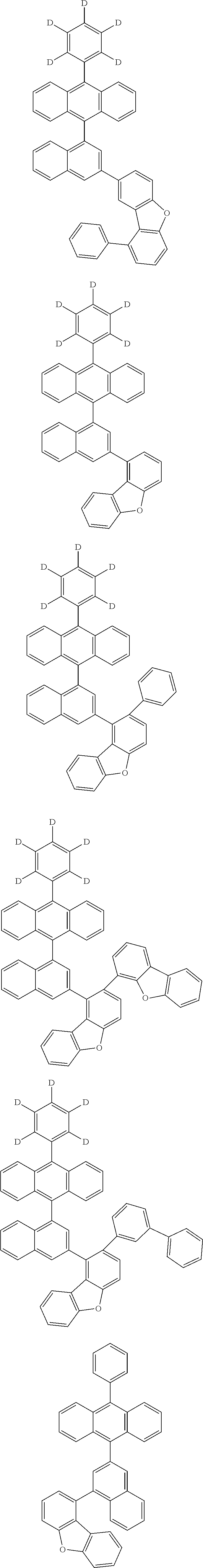

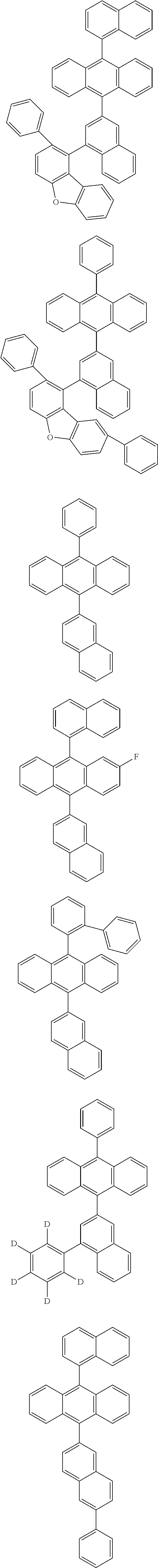

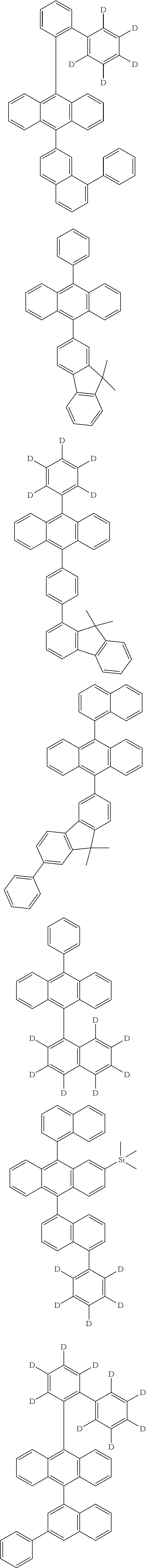

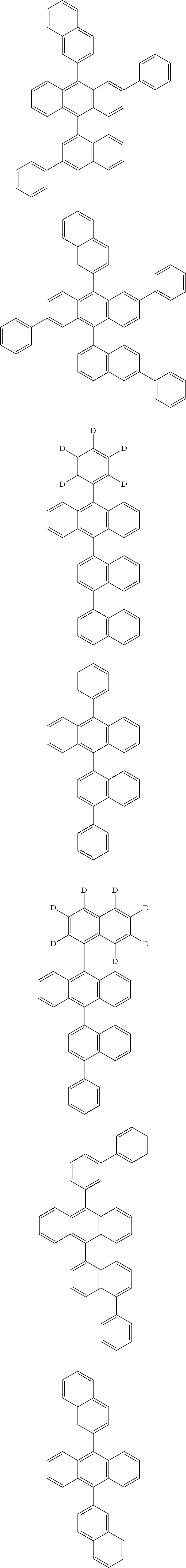

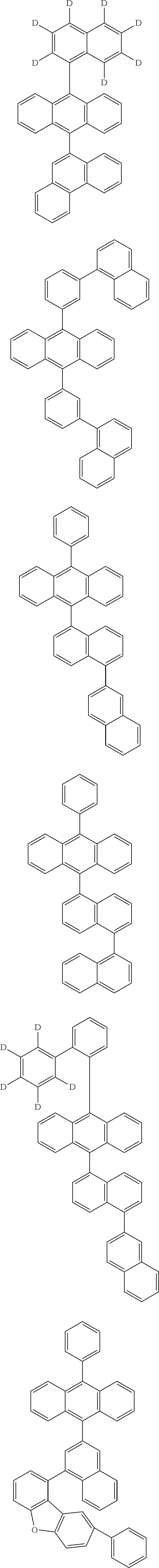

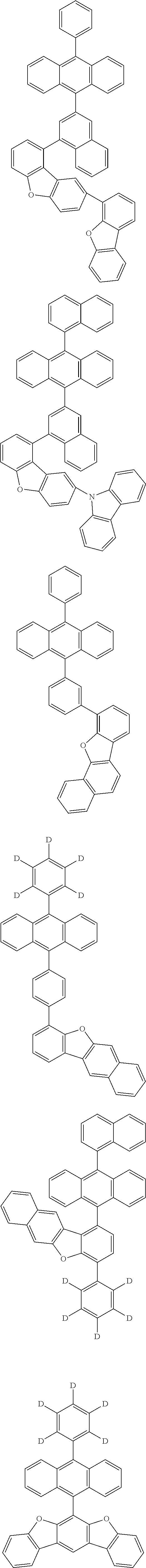

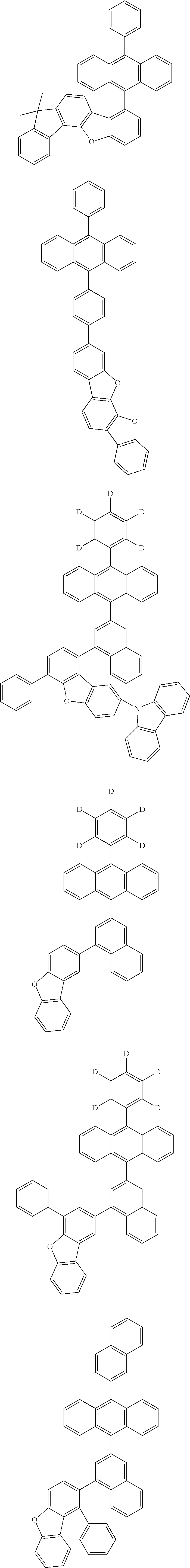

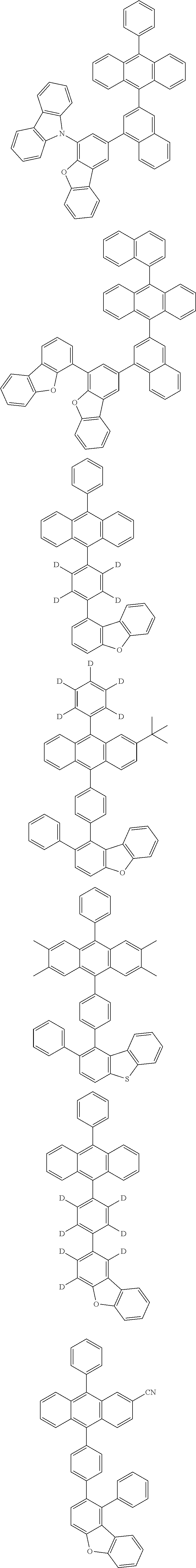

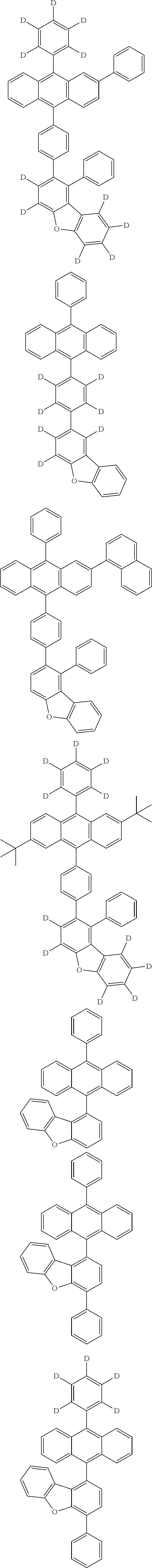

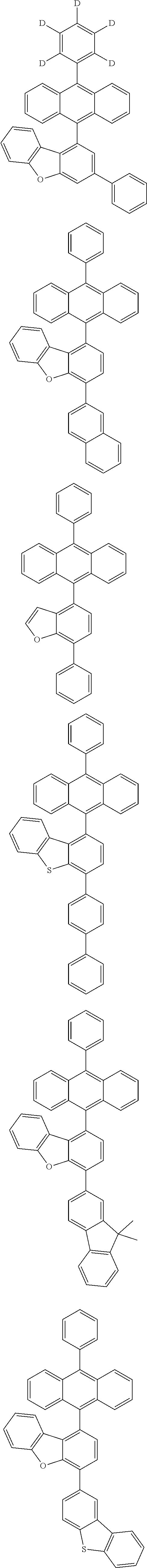

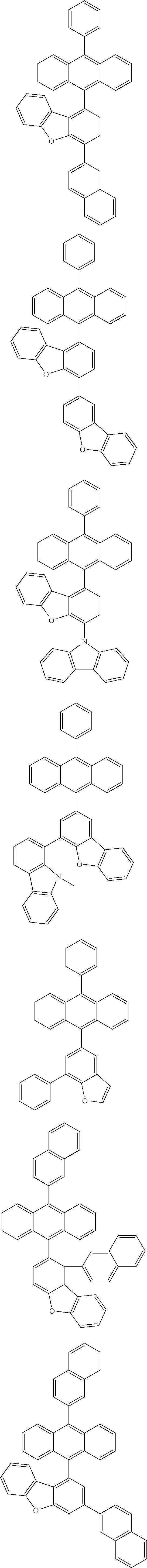

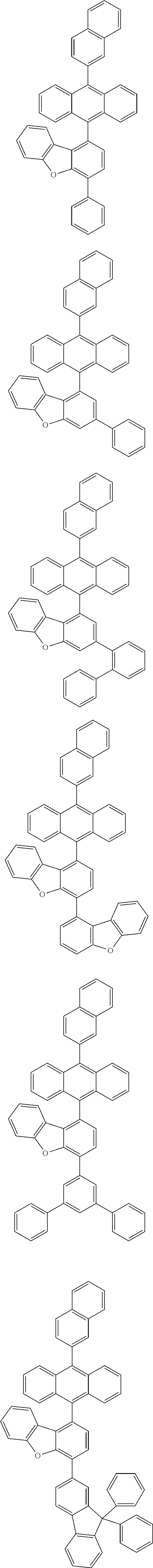

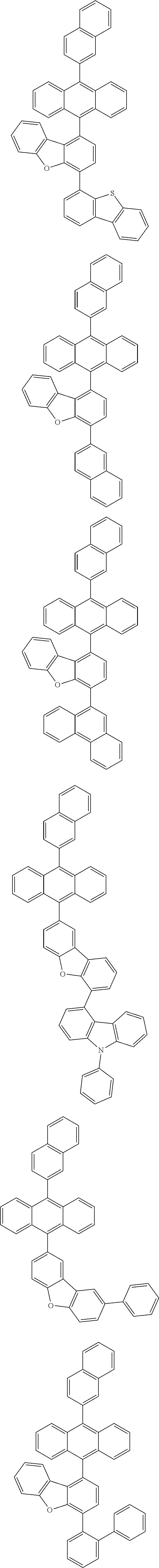

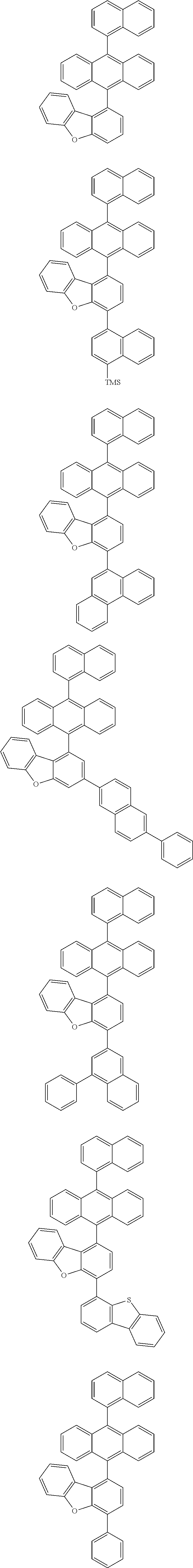

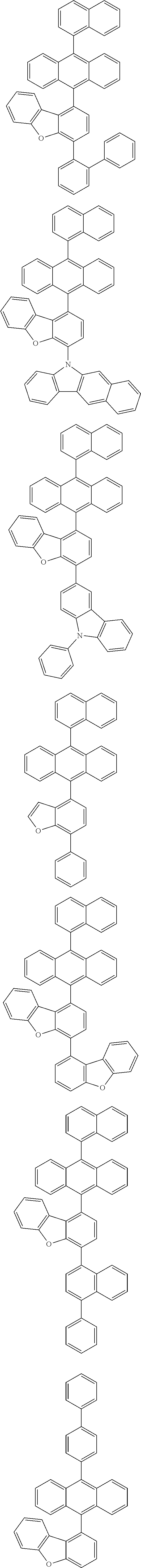

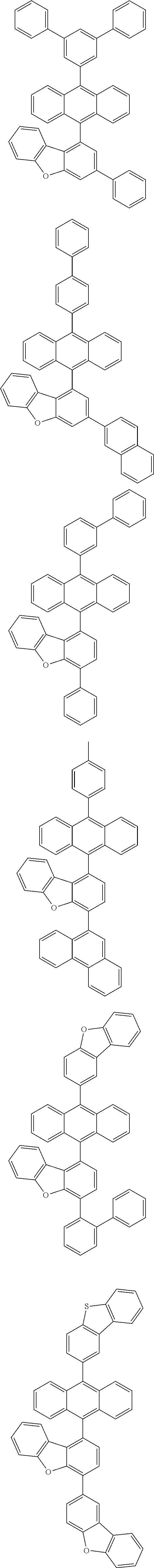

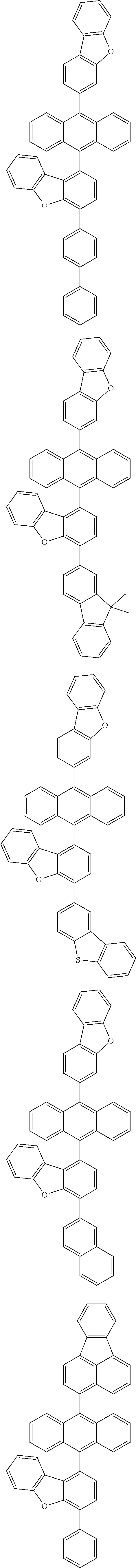

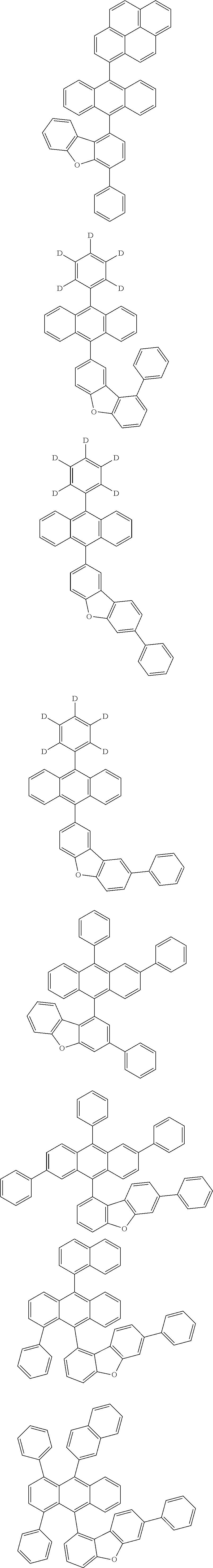

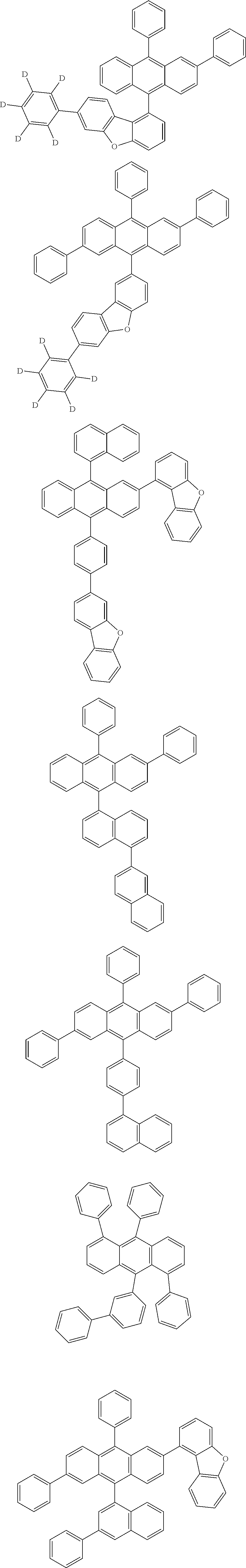

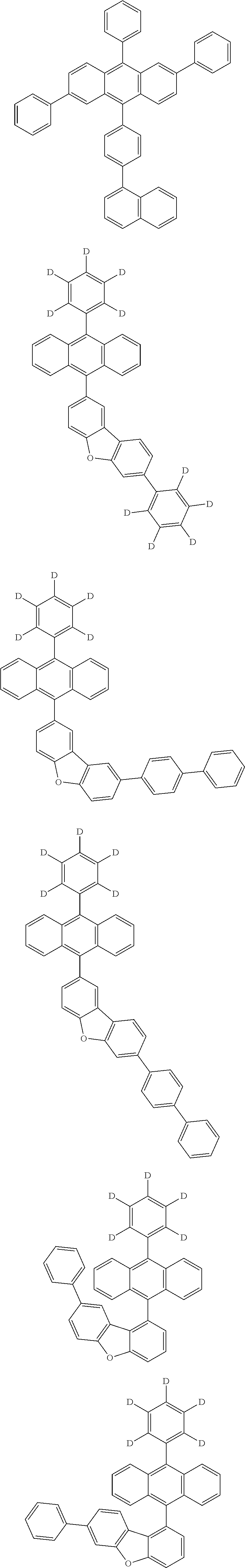

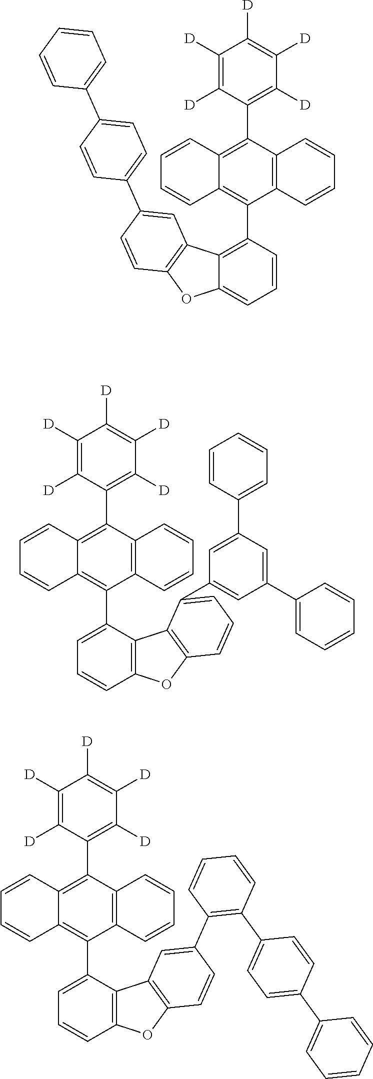 [SMILES: [2H]c1c([2H])c([2H])c(-c2c3ccccc3c(-c3cccc4oc5ccc(-c6ccc(-c7ccccc7)cc6)cc5c34)c3ccccc23)c([2H])c1[2H] ; [2H]c1c([2H])c([2H])c(-c2c3ccccc3c(-c3cccc4oc5cccc(-c6cc(-c7ccccc7)cc(-c7ccccc7)c6)c5c34)c3ccccc23)c([2H])c1[2H] ; [2H]c1c([2H])c([2H])c(-c2c3ccccc3c(-c3cccc4oc5ccc(-c6ccccc6-c6ccc(-c7ccccc7)cc6)cc5c34)c3ccccc23)c([2H])c1[2H]]

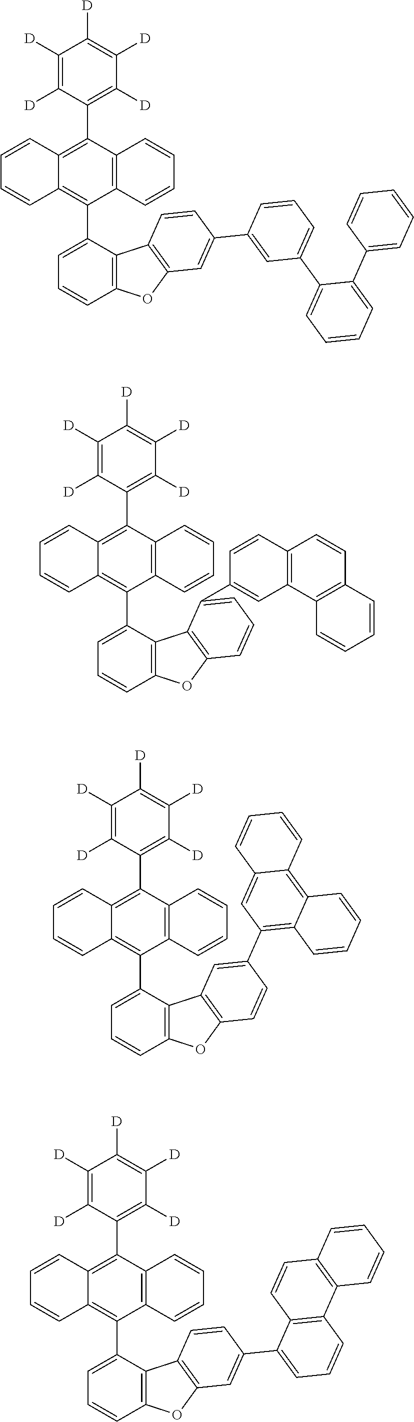 [SMILES: [2H]c1c([2H])c([2H])c(-c2c3ccccc3c(-c3cccc4oc5cc(-c6cccc(-c7ccccc7-c7ccccc7)c6)ccc5c34)c3ccccc23)c([2H])c1[2H] ; [2H]c1c([2H])c([2H])c(-c2c3ccccc3c(-c3cccc4oc5cccc(-c6ccc7ccc8ccccc8c7c6)c5c34)c3ccccc23)c([2H])c1[2H] ; [2H]c1c([2H])c([2H])c(-c2c3ccccc3c(-c3cccc4oc5ccc(-c6cc7ccccc7c7ccccc67)cc5c34)c3ccccc23)c([2H])c1[2H] ; [2H]c1c([2H])c([2H])c(-c2c3ccccc3c(-c3cccc4oc5cc(-c6cccc7c6ccc6ccccc67)ccc5c34)c3ccccc23)c([2H])c1[2H]]

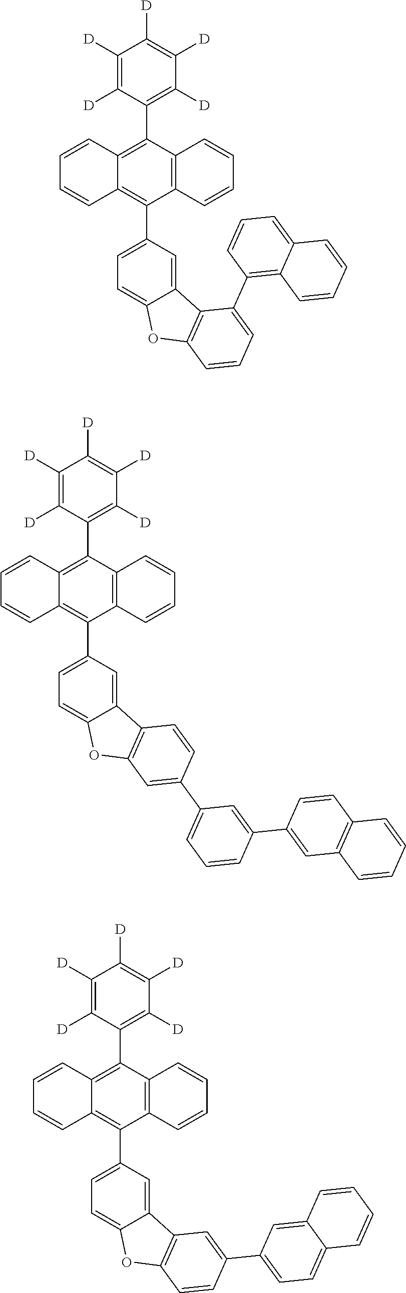 [SMILES: [2H]c1c([2H])c([2H])c(-c2c3ccccc3c(-c3ccc4oc5cccc(-c6cccc7ccccc67)c5c4c3)c3ccccc23)c([2H])c1[2H] ; [2H]c1c([2H])c([2H])c(-c2c3ccccc3c(-c3ccc4oc5cc(-c6cccc(-c7ccc8ccccc8c7)c6)ccc5c4c3)c3ccccc23)c([2H])c1[2H] ; [2H]c1c([2H])c([2H])c(-c2c3ccccc3c(-c3ccc4oc5ccc(-c6ccc7ccccc7c6)cc5c4c3)c3ccccc23)c([2H])c1[2H]]

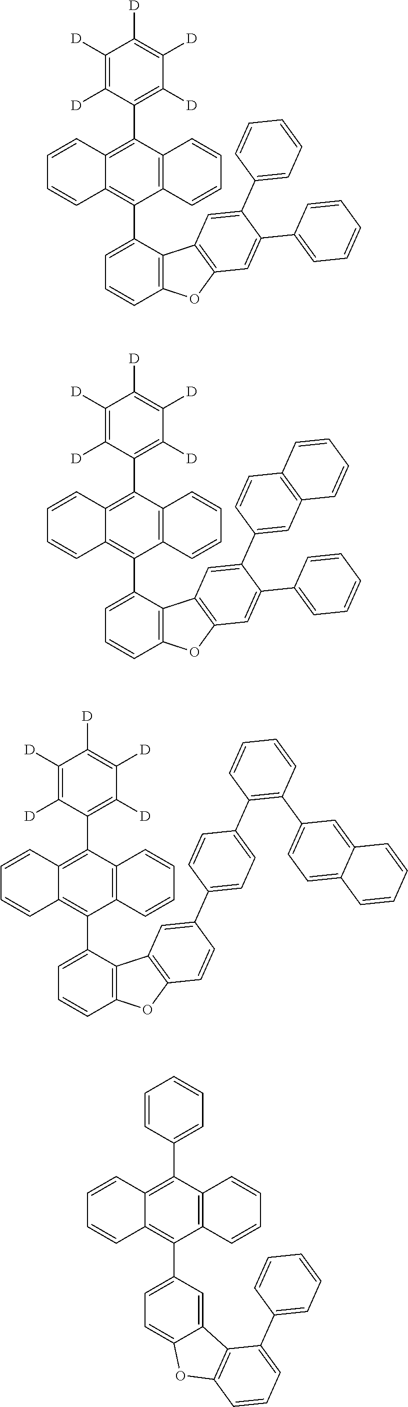 [SMILES: [2H]c1c([2H])c([2H])c(-c2c3ccccc3c(-c3cccc4oc5cc(-c6ccccc6)c(-c6ccccc6)cc5c34)c3ccccc23)c([2H])c1[2H] ; [2H]c1c([2H])c([2H])c(-c2c3ccccc3c(-c3cccc4oc5cc(-c6ccccc6)c(-c6ccc7ccccc7c6)cc5c34)c3ccccc23)c([2H])c1[2H] ; [2H]c1c([2H])c([2H])c(-c2c3ccccc3c(-c3cccc4oc5ccc(-c6ccc(-c7ccccc7-c7ccc8ccccc8c7)cc6)cc5c34)c3ccccc23)c([2H])c1[2H] ; c1ccc(-c2c3ccccc3c(-c3ccc4oc5cccc(-c6ccccc6)c5c4c3)c3ccccc23)cc1]

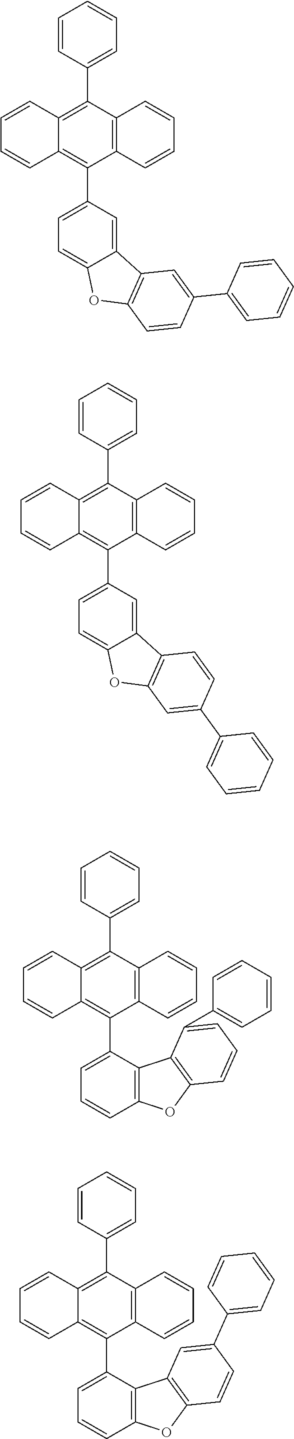 [SMILES: c1ccc(-c2ccc3oc4ccc(-c5c6ccccc6c(-c6ccccc6)c6ccccc56)cc4c3c2)cc1 ; c1ccc(-c2ccc3c(c2)oc2ccc(-c4c5ccccc5c(-c5ccccc5)c5ccccc45)cc23)cc1 ; c1ccc(-c2c3ccccc3c(-c3cccc4oc5cccc(-c6ccccc6)c5c34)c3ccccc23)cc1 ; c1ccc(-c2ccc3oc4cccc(-c5c6ccccc6c(-c6ccccc6)c6ccccc56)c4c3c2)cc1]

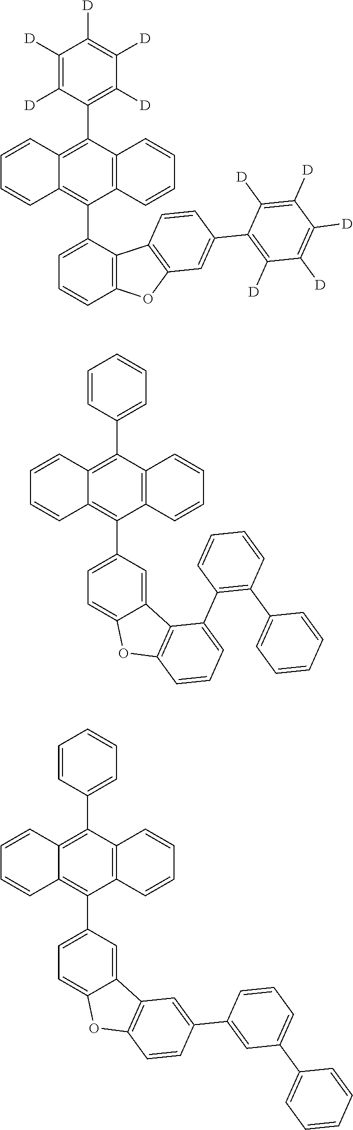 [SMILES: [2H]c1c([2H])c([2H])c(-c2ccc3c(c2)oc2cccc(-c4c5ccccc5c(-c5c([2H])c([2H])c([2H])c([2H])c5[2H])c5ccccc45)c23)c([2H])c1[2H] ; c1ccc(-c2ccccc2-c2cccc3oc4ccc(-c5c6ccccc6c(-c6ccccc6)c6ccccc56)cc4c23)cc1 ; c1ccc(-c2cccc(-c3ccc4oc5ccc(-c6c7ccccc7c(-c7ccccc7)c7ccccc67)cc5c4c3)c2)cc1]

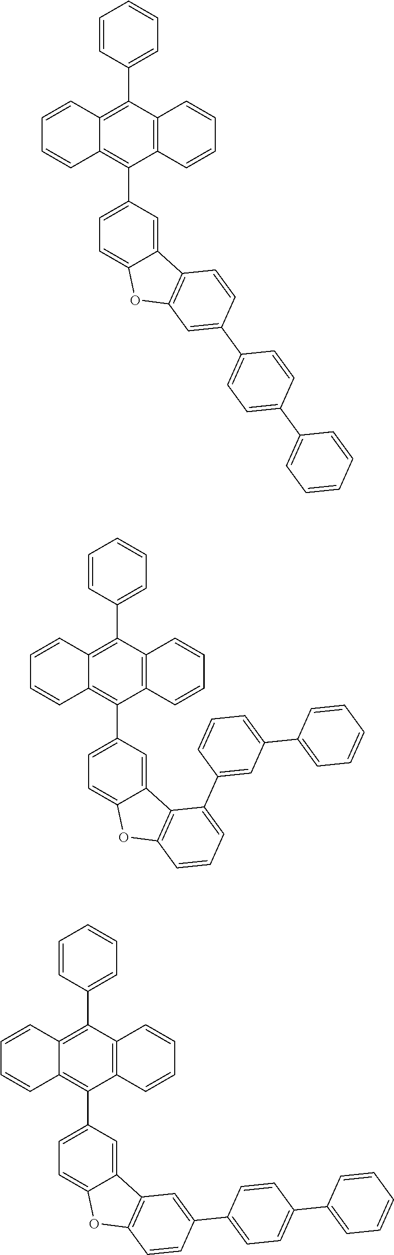 [SMILES: c1ccc(-c2ccc(-c3ccc4c(c3)oc3ccc(-c5c6ccccc6c(-c6ccccc6)c6ccccc56)cc34)cc2)cc1 ; c1ccc(-c2cccc(-c3cccc4oc5ccc(-c6c7ccccc7c(-c7ccccc7)c7ccccc67)cc5c34)c2)cc1 ; c1ccc(-c2ccc(-c3ccc4oc5ccc(-c6c7ccccc7c(-c7ccccc7)c7ccccc67)cc5c4c3)cc2)cc1]

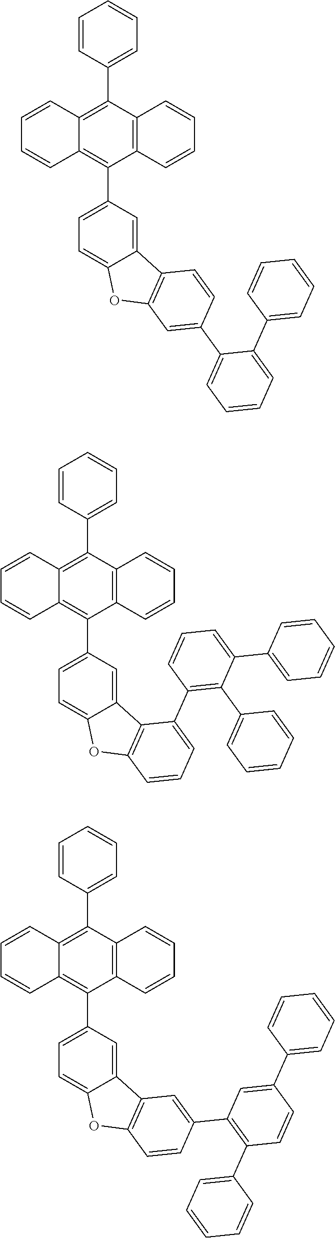 [SMILES: c1ccc(-c2ccccc2-c2ccc3c(c2)oc2ccc(-c4c5ccccc5c(-c5ccccc5)c5ccccc45)cc23)cc1 ; c1ccc(-c2cccc(-c3cccc4oc5ccc(-c6c7ccccc7c(-c7ccccc7)c7ccccc67)cc5c34)c2-c2ccccc2)cc1 ; c1ccc(-c2ccc(-c3ccccc3)c(-c3ccc4oc5ccc(-c6c7ccccc7c(-c7ccccc7)c7ccccc67)cc5c4c3)c2)cc1]

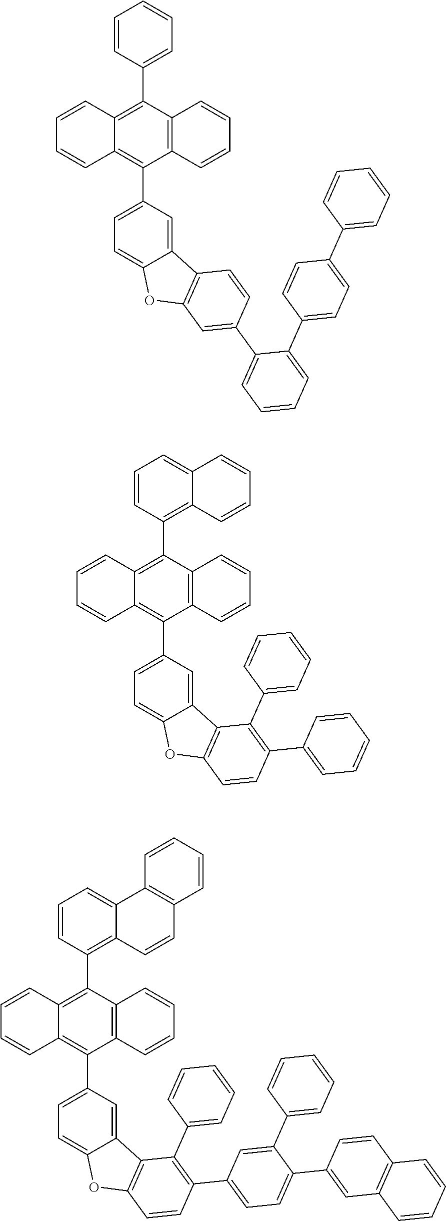 [SMILES: c1ccc(-c2ccc(-c3ccccc3-c3ccc4c(c3)oc3ccc(-c5c6ccccc6c(-c6ccccc6)c6ccccc56)cc34)cc2)cc1 ; c1ccc(-c2ccc3oc4ccc(-c5c6ccccc6c(-c6cccc7ccccc67)c6ccccc56)cc4c3c2-c2ccccc2)cc1 ; c1ccc(-c2cc(-c3ccc4oc5ccc(-c6c7ccccc7c(-c7cccc8c7ccc7ccccc78)c7ccccc67)cc5c4c3-c3ccccc3)ccc2-c2ccc3ccccc3c2)cc1]

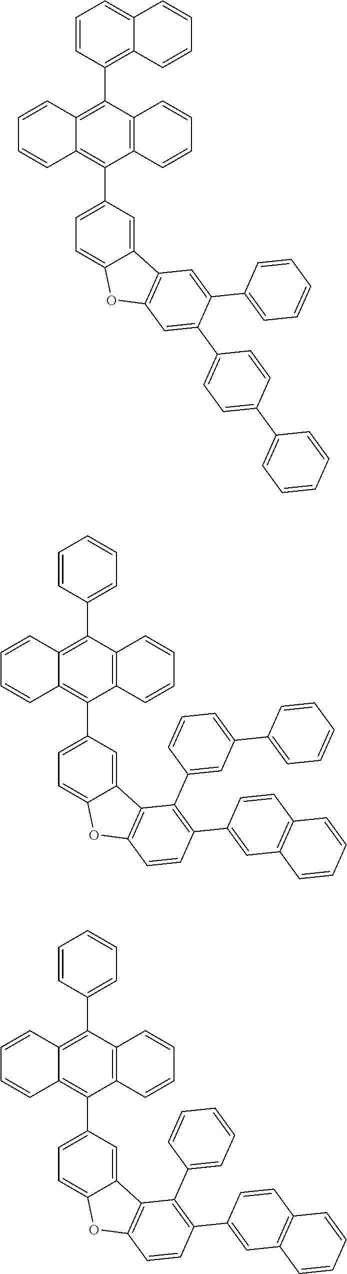 [SMILES: c1ccc(-c2ccc(-c3cc4oc5ccc(-c6c7ccccc7c(-c7cccc8ccccc78)c7ccccc67)cc5c4cc3-c3ccccc3)cc2)cc1 ; c1ccc(-c2cccc(-c3c(-c4ccc5ccccc5c4)ccc4oc5ccc(-c6c7ccccc7c(-c7ccccc7)c7ccccc67)cc5c34)c2)cc1 ; c1ccc(-c2c3ccccc3c(-c3ccc4oc5ccc(-c6ccc7ccccc7c6)c(-c6ccccc6)c5c4c3)c3ccccc23)cc1]

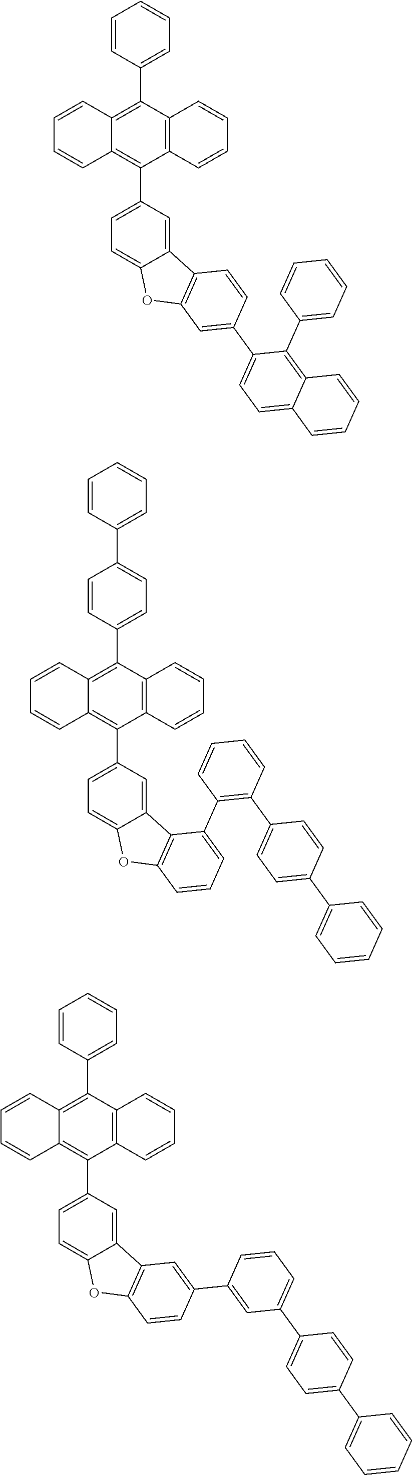 [SMILES: c1ccc(-c2c(-c3ccc4c(c3)oc3ccc(-c5c6ccccc6c(-c6ccccc6)c6ccccc56)cc34)ccc3ccccc23)cc1 ; c1ccc(-c2ccc(-c3ccccc3-c3cccc4oc5ccc(-c6c7ccccc7c(-c7ccc(-c8ccccc8)cc7)c7ccccc67)cc5c34)cc2)cc1 ; c1ccc(-c2ccc(-c3cccc(-c4ccc5oc6ccc(-c7c8ccccc8c(-c8ccccc8)c8ccccc78)cc6c5c4)c3)cc2)cc1]

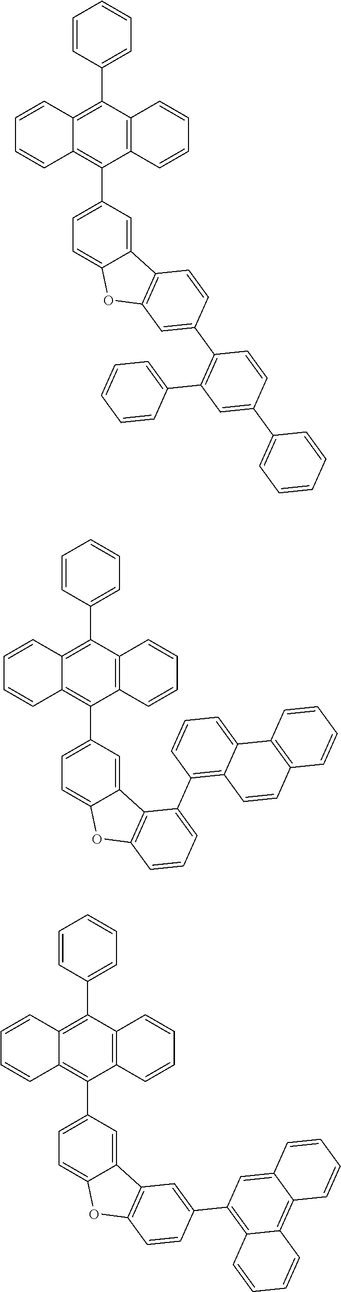 [SMILES: c1ccc(-c2ccc(-c3ccc4c(c3)oc3ccc(-c5c6ccccc6c(-c6ccccc6)c6ccccc56)cc34)c(-c3ccccc3)c2)cc1 ; c1ccc(-c2c3ccccc3c(-c3ccc4oc5cccc(-c6cccc7c6ccc6ccccc67)c5c4c3)c3ccccc23)cc1 ; c1ccc(-c2c3ccccc3c(-c3ccc4oc5ccc(-c6cc7ccccc7c7ccccc67)cc5c4c3)c3ccccc23)cc1]

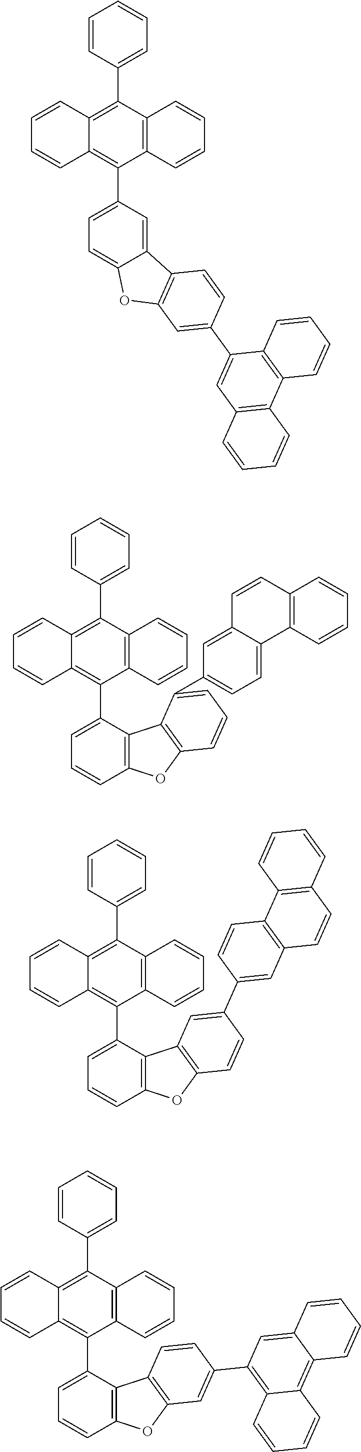 [SMILES: c1ccc(-c2c3ccccc3c(-c3ccc4oc5cc(-c6cc7ccccc7c7ccccc67)ccc5c4c3)c3ccccc23)cc1 ; c1ccc(-c2c3ccccc3c(-c3cccc4oc5cccc(-c6ccc7c(ccc8ccccc87)c6)c5c34)c3ccccc23)cc1 ; c1ccc(-c2c3ccccc3c(-c3cccc4oc5ccc(-c6ccc7c(ccc8ccccc87)c6)cc5c34)c3ccccc23)cc1 ; c1ccc(-c2c3ccccc3c(-c3cccc4oc5cc(-c6cc7ccccc7c7ccccc67)ccc5c34)c3ccccc23)cc1]

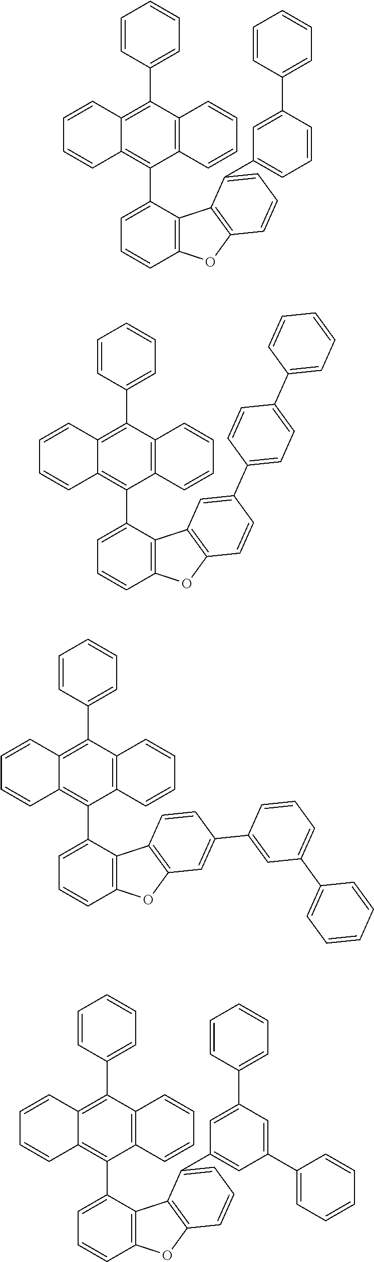 [SMILES: c1ccc(-c2cccc(-c3cccc4oc5cccc(-c6c7ccccc7c(-c7ccccc7)c7ccccc67)c5c34)c2)cc1 ; c1ccc(-c2ccc(-c3ccc4oc5cccc(-c6c7ccccc7c(-c7ccccc7)c7ccccc67)c5c4c3)cc2)cc1 ; c1ccc(-c2cccc(-c3ccc4c(c3)oc3cccc(-c5c6ccccc6c(-c6ccccc6)c6ccccc56)c34)c2)cc1 ; c1ccc(-c2cc(-c3ccccc3)cc(-c3cccc4oc5cccc(-c6c7ccccc7c(-c7ccccc7)c7ccccc67)c5c34)c2)cc1]

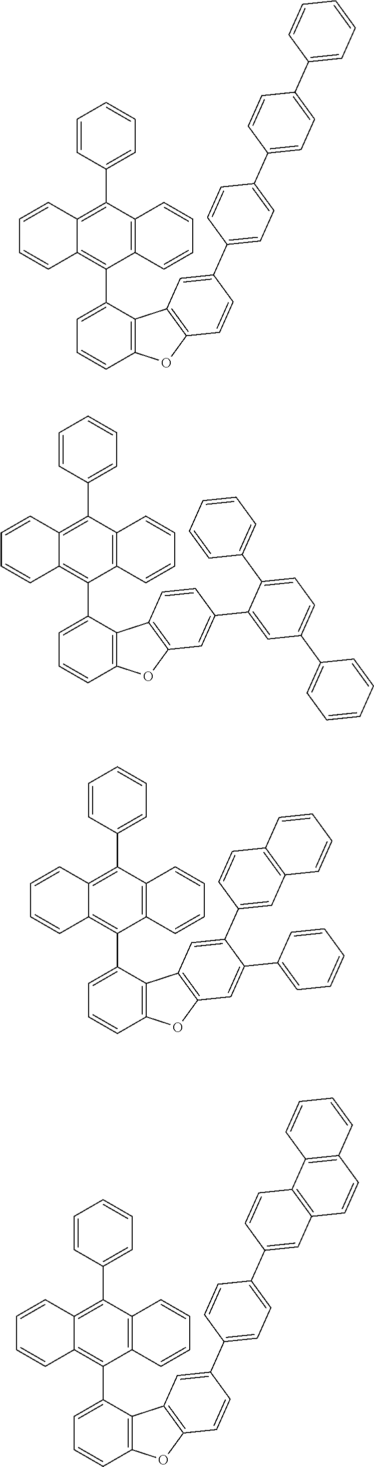 [SMILES: c1ccc(-c2ccc(-c3ccc(-c4ccc5oc6cccc(-c7c8ccccc8c(-c8ccccc8)c8ccccc78)c6c5c4)cc3)cc2)cc1 ; c1ccc(-c2ccc(-c3ccccc3)c(-c3ccc4c(c3)oc3cccc(-c5c6ccccc6c(-c6ccccc6)c6ccccc56)c34)c2)cc1 ; c1ccc(-c2cc3oc4cccc(-c5c6ccccc6c(-c6ccccc6)c6ccccc56)c4c3cc2-c2ccc3ccccc3c2)cc1 ; c1ccc(-c2c3ccccc3c(-c3cccc4oc5ccc(-c6ccc(-c7ccc8c(ccc9ccccc98)c7)cc6)cc5c34)c3ccccc23)cc1]

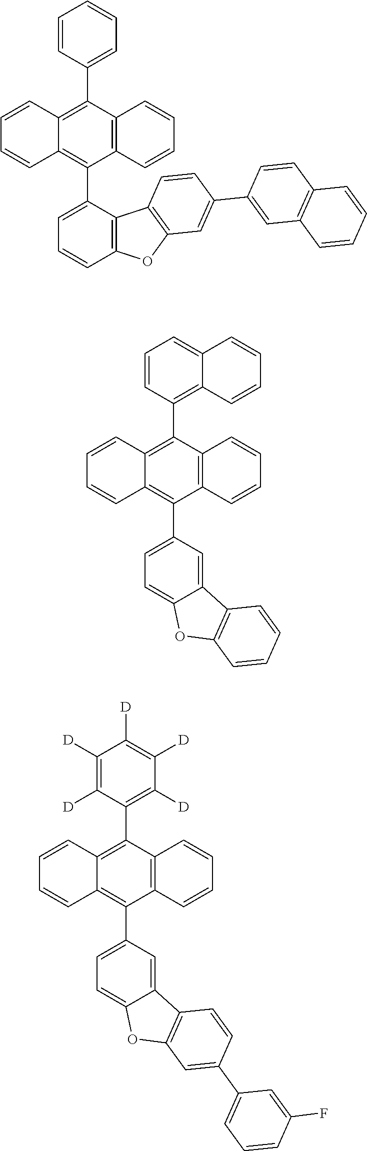 [SMILES: c1ccc(-c2c3ccccc3c(-c3cccc4oc5cc(-c6ccc7ccccc7c6)ccc5c34)c3ccccc23)cc1 ; c1ccc2c(-c3c4ccccc4c(-c4ccc5oc6ccccc6c5c4)c4ccccc34)cccc2c1 ; [2H]c1c([2H])c([2H])c(-c2c3ccccc3c(-c3ccc4oc5cc(-c6cccc(F)c6)ccc5c4c3)c3ccccc23)c([2H])c1[2H]]

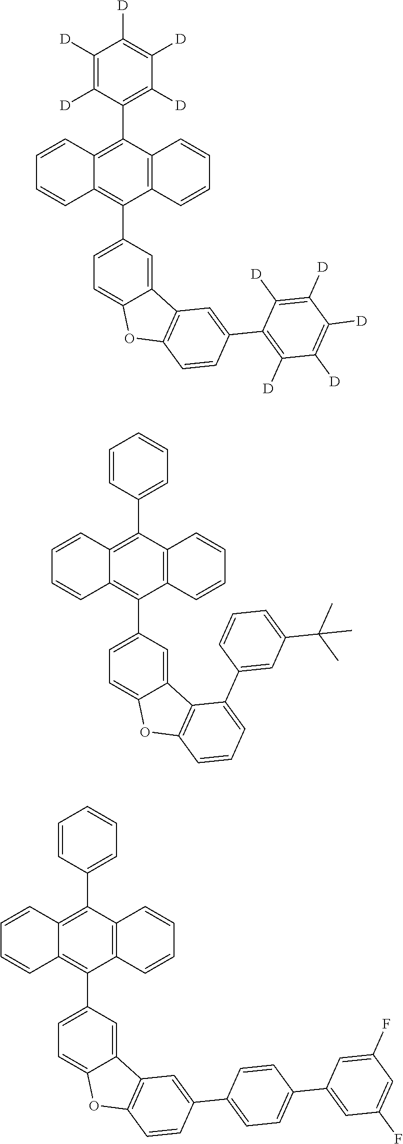 [SMILES: [2H]c1c([2H])c([2H])c(-c2ccc3oc4ccc(-c5c6ccccc6c(-c6c([2H])c([2H])c([2H])c([2H])c6[2H])c6ccccc56)cc4c3c2)c([2H])c1[2H] ; CC(C)(C)c1cccc(-c2cccc3oc4ccc(-c5c6ccccc6c(-c6ccccc6)c6ccccc56)cc4c23)c1 ; Fc1cc(F)cc(-c2ccc(-c3ccc4oc5ccc(-c6c7ccccc7c(-c7ccccc7)c7ccccc67)cc5c4c3)cc2)c1]

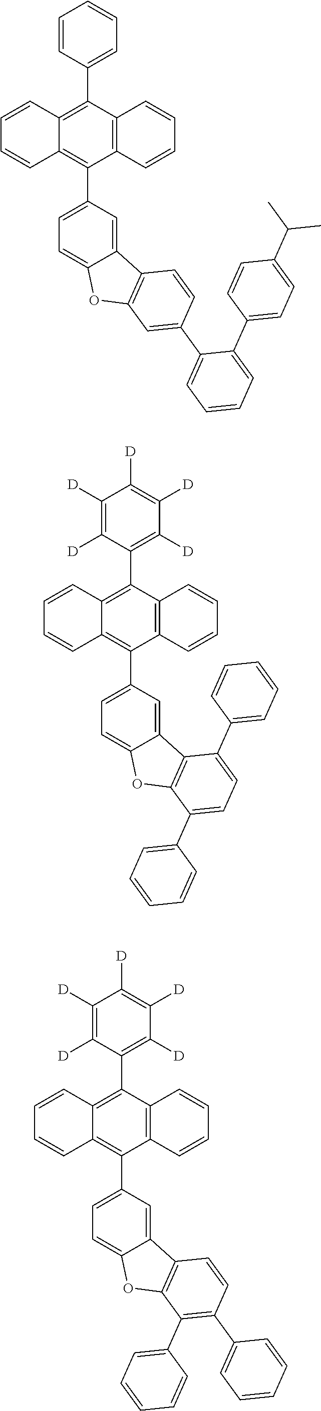 [SMILES: CC(C)c1ccc(-c2ccccc2-c2ccc3c(c2)oc2ccc(-c4c5ccccc5c(-c5ccccc5)c5ccccc45)cc23)cc1 ; [2H]c1c([2H])c([2H])c(-c2c3ccccc3c(-c3ccc4oc5c(-c6ccccc6)ccc(-c6ccccc6)c5c4c3)c3ccccc23)c([2H])c1[2H] ; [2H]c1c([2H])c([2H])c(-c2c3ccccc3c(-c3ccc4oc5c(-c6ccccc6)c(-c6ccccc6)ccc5c4c3)c3ccccc23)c([2H])c1[2H]]

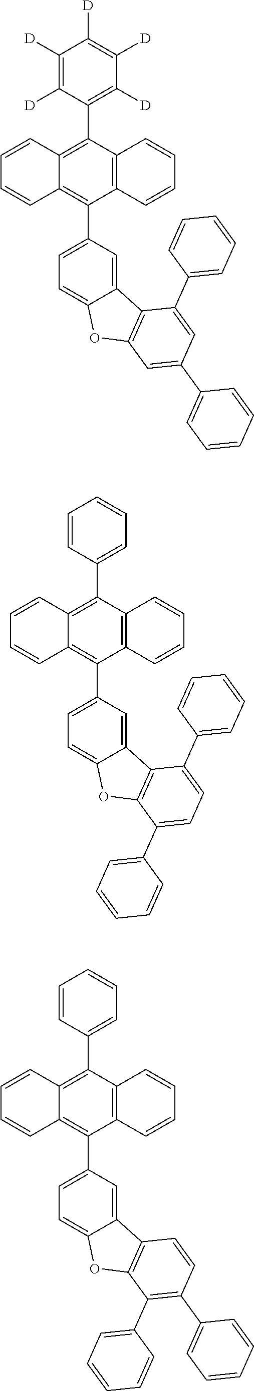 [SMILES: [2H]c1c([2H])c([2H])c(-c2c3ccccc3c(-c3ccc4oc5cc(-c6ccccc6)cc(-c6ccccc6)c5c4c3)c3ccccc23)c([2H])c1[2H] ; c1ccc(-c2c3ccccc3c(-c3ccc4oc5c(-c6ccccc6)ccc(-c6ccccc6)c5c4c3)c3ccccc23)cc1 ; c1ccc(-c2ccc3c(oc4ccc(-c5c6ccccc6c(-c6ccccc6)c6ccccc56)cc43)c2-c2ccccc2)cc1]

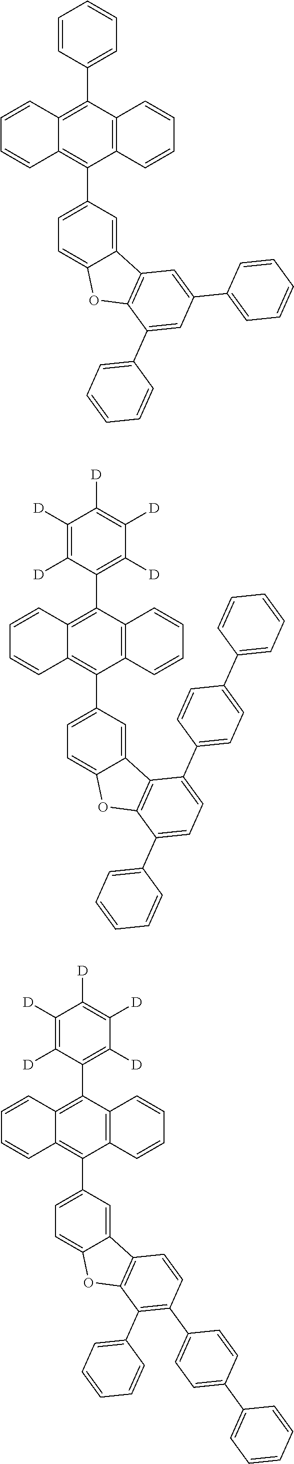 [SMILES: c1ccc(-c2cc(-c3ccccc3)c3oc4ccc(-c5c6ccccc6c(-c6ccccc6)c6ccccc56)cc4c3c2)cc1 ; [2H]c1c([2H])c([2H])c(-c2c3ccccc3c(-c3ccc4oc5c(-c6ccccc6)ccc(-c6ccc(-c7ccccc7)cc6)c5c4c3)c3ccccc23)c([2H])c1[2H] ; [2H]c1c([2H])c([2H])c(-c2c3ccccc3c(-c3ccc4oc5c(-c6ccccc6)c(-c6ccc(-c7ccccc7)cc6)ccc5c4c3)c3ccccc23)c([2H])c1[2H]]

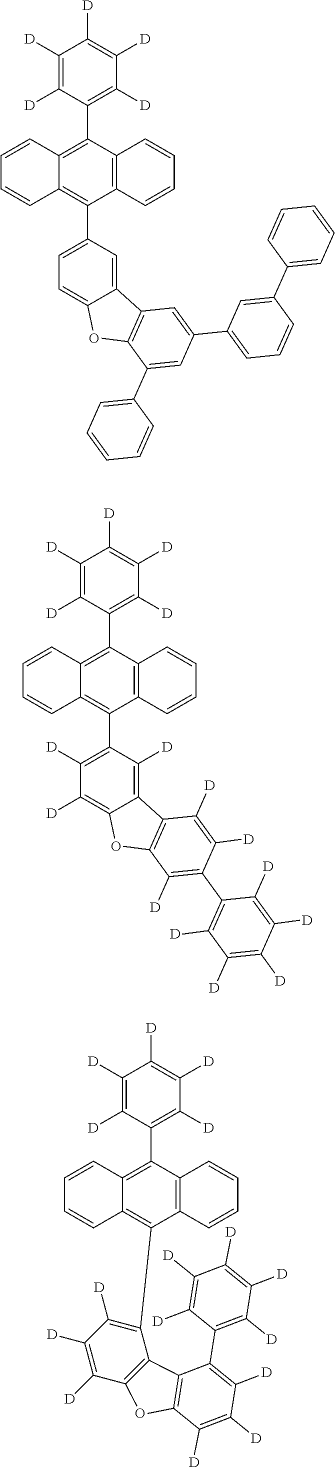 [SMILES: [2H]c1c([2H])c([2H])c(-c2c3ccccc3c(-c3ccc4oc5c(-c6ccccc6)cc(-c6cccc(-c7ccccc7)c6)cc5c4c3)c3ccccc23)c([2H])c1[2H] ; [2H]c1c([2H])c([2H])c(-c2c([2H])c([2H])c3c(oc4c([2H])c([2H])c(-c5c6ccccc6c(-c6c([2H])c([2H])c([2H])c([2H])c6[2H])c6ccccc56)c([2H])c43)c2[2H])c([2H])c1[2H] ; [2H]c1c([2H])c([2H])c(-c2c3ccccc3c(-c3c([2H])c([2H])c([2H])c4oc5c([2H])c([2H])c([2H])c(-c6c([2H])c([2H])c([2H])c([2H])c6[2H])c5c34)c3ccccc23)c([2H])c1[2H]]

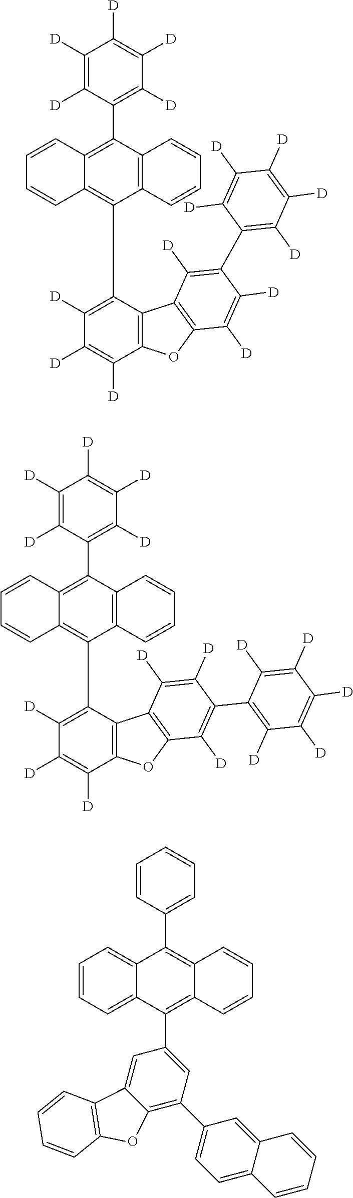 [SMILES: [2H]c1c([2H])c([2H])c(-c2c([2H])c([2H])c3oc4c([2H])c([2H])c([2H])c(-c5c6ccccc6c(-c6c([2H])c([2H])c([2H])c([2H])c6[2H])c6ccccc56)c4c3c2[2H])c([2H])c1[2H] ; [2H]c1c([2H])c([2H])c(-c2c([2H])c([2H])c3c(oc4c([2H])c([2H])c([2H])c(-c5c6ccccc6c(-c6c([2H])c([2H])c([2H])c([2H])c6[2H])c6ccccc56)c43)c2[2H])c([2H])c1[2H] ; c1ccc(-c2c3ccccc3c(-c3cc(-c4ccc5ccccc5c4)c4oc5ccccc5c4c3)c3ccccc23)cc1]

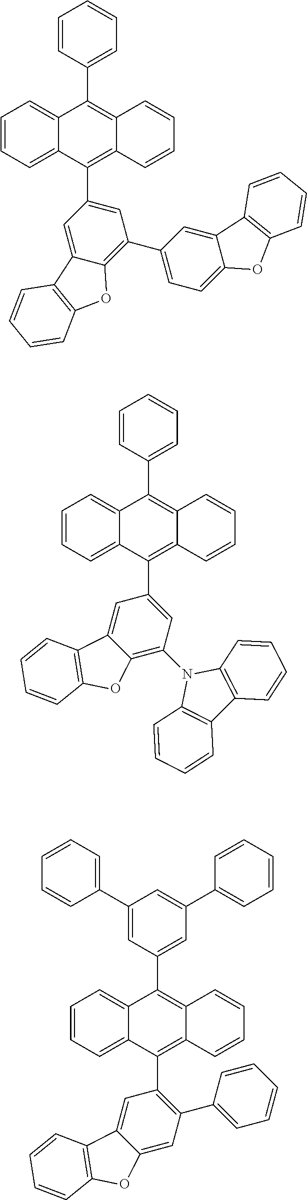 [SMILES: c1ccc(-c2c3ccccc3c(-c3cc(-c4ccc5oc6ccccc6c5c4)c4oc5ccccc5c4c3)c3ccccc23)cc1 ; c1ccc(-c2c3ccccc3c(-c3cc(-n4c5ccccc5c5ccccc54)c4oc5ccccc5c4c3)c3ccccc23)cc1 ; c1ccc(-c2cc(-c3ccccc3)cc(-c3c4ccccc4c(-c4cc5c(cc4-c4ccccc4)oc4ccccc45)c4ccccc34)c2)cc1]

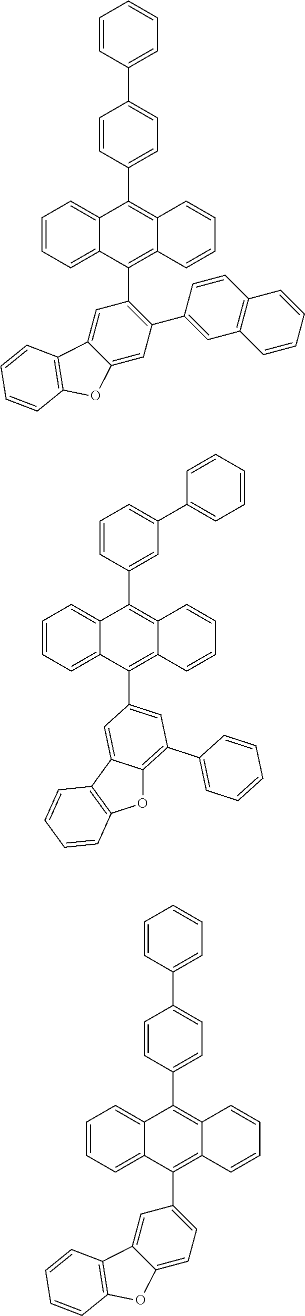 [SMILES: c1ccc(-c2ccc(-c3c4ccccc4c(-c4cc5c(cc4-c4ccc6ccccc6c4)oc4ccccc45)c4ccccc34)cc2)cc1 ; c1ccc(-c2cccc(-c3c4ccccc4c(-c4cc(-c5ccccc5)c5oc6ccccc6c5c4)c4ccccc34)c2)cc1 ; c1ccc(-c2ccc(-c3c4ccccc4c(-c4ccc5oc6ccccc6c5c4)c4ccccc34)cc2)cc1]

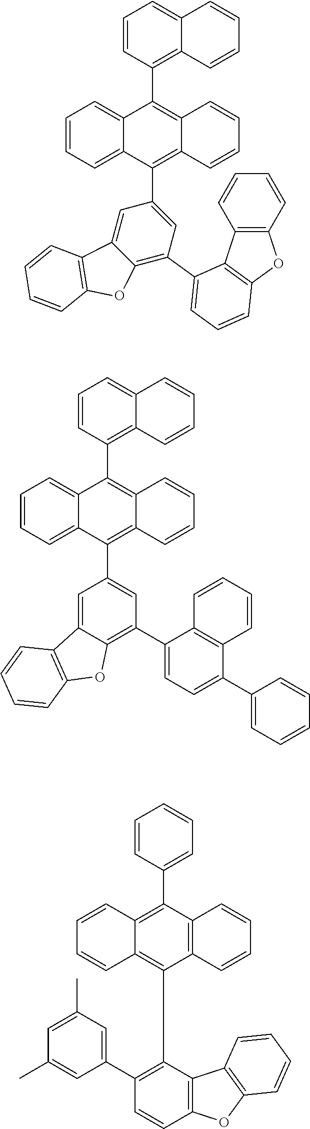 [SMILES: c1ccc2c(-c3c4ccccc4c(-c4cc(-c5cccc6oc7ccccc7c56)c5oc6ccccc6c5c4)c4ccccc34)cccc2c1 ; c1ccc(-c2ccc(-c3cc(-c4c5ccccc5c(-c5cccc6ccccc56)c5ccccc45)cc4c3oc3ccccc34)c3ccccc23)cc1 ; Cc1cc(C)cc(-c2ccc3oc4ccccc4c3c2-c2c3ccccc3c(-c3ccccc3)c3ccccc23)c1]

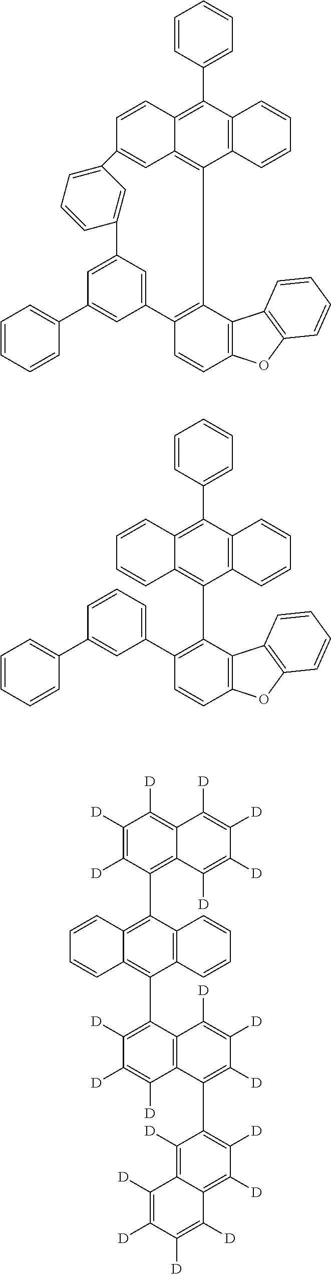 [SMILES: c1ccc(-c2cc3cc(c2)-c2ccc4oc5ccccc5c4c2-c2c4ccccc4c(-c4ccccc4)c4ccc(cc24)-c2cccc-3c2)cc1 ; c1ccc(-c2cccc(-c3ccc4oc5ccccc5c4c3-c3c4ccccc4c(-c4ccccc4)c4ccccc34)c2)cc1 ; [2H]c1c([2H])c([2H])c2c([2H])c(-c3c([2H])c([2H])c([2H])c4c(-c5c6ccccc6c(-c6c([2H])c([2H])c([2H])c7c([2H])c([2H])c([2H])c([2H])c67)c6ccccc56)c([2H])c([2H])c([2H])c34)c([2H])c([2H])c2c1[2H]]

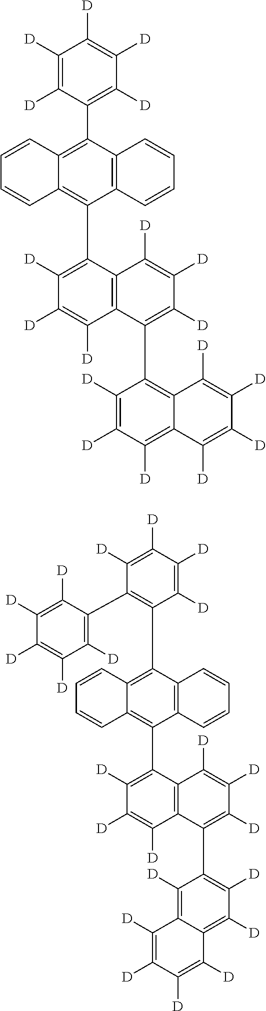 [SMILES: [2H]c1c([2H])c([2H])c(-c2c3ccccc3c(-c3c([2H])c([2H])c([2H])c4c(-c5c([2H])c([2H])c([2H])c6c([2H])c([2H])c([2H])c([2H])c56)c([2H])c([2H])c([2H])c34)c3ccccc23)c([2H])c1[2H] ; [2H]c1c([2H])c([2H])c(-c2c([2H])c([2H])c([2H])c([2H])c2-c2c3ccccc3c(-c3c([2H])c([2H])c([2H])c4c(-c5c([2H])c([2H])c6c([2H])c([2H])c([2H])c([2H])c6c5[2H])c([2H])c([2H])c([2H])c34)c3ccccc23)c([2H])c1[2H]]

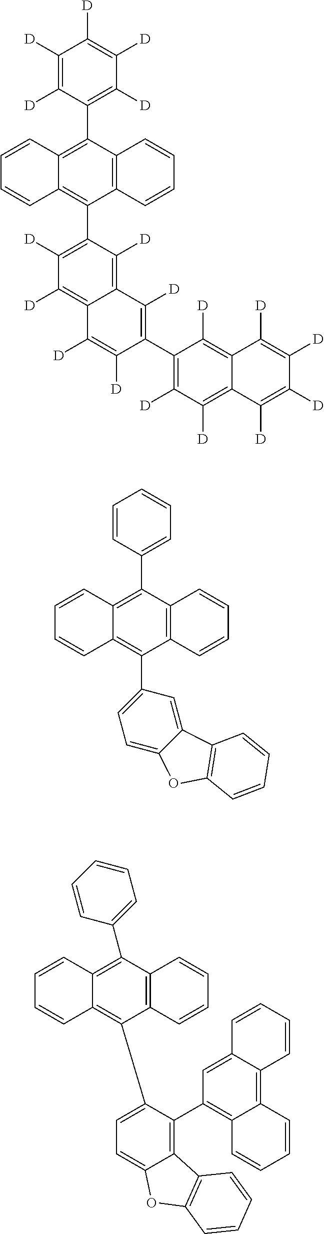 [SMILES: [2H]c1c([2H])c([2H])c(-c2c3ccccc3c(-c3c([2H])c([2H])c4c([2H])c([2H])c(-c5c([2H])c([2H])c6c([2H])c([2H])c([2H])c([2H])c6c5[2H])c([2H])c4c3[2H])c3ccccc23)c([2H])c1[2H] ; c1ccc(-c2c3ccccc3c(-c3ccc4oc5ccccc5c4c3)c3ccccc23)cc1 ; c1ccc(-c2c3ccccc3c(-c3ccc4oc5ccccc5c4c3-c3cc4ccccc4c4ccccc34)c3ccccc23)cc1]

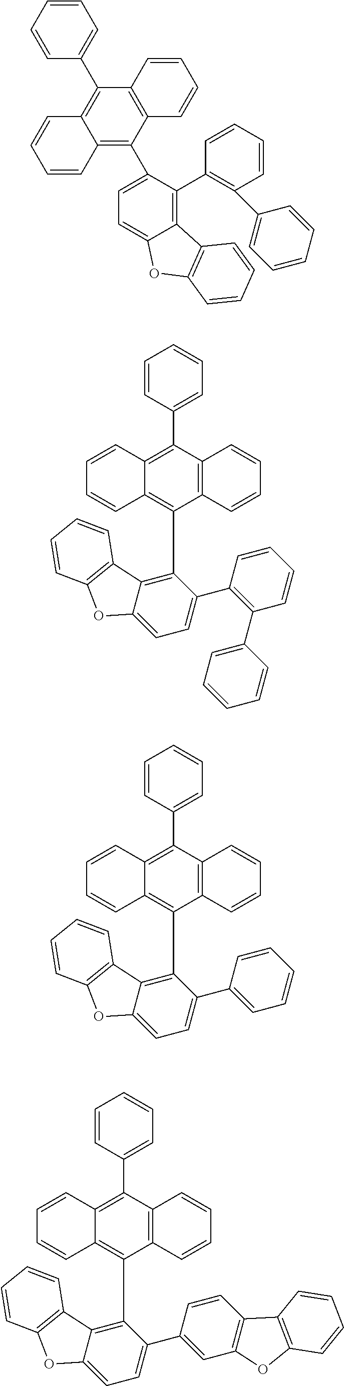 [SMILES: c1ccc(-c2ccccc2-c2c(-c3c4ccccc4c(-c4ccccc4)c4ccccc34)ccc3oc4ccccc4c23)cc1 ; c1ccc(-c2ccccc2-c2ccc3oc4ccccc4c3c2-c2c3ccccc3c(-c3ccccc3)c3ccccc23)cc1 ; c1ccc(-c2ccc3oc4ccccc4c3c2-c2c3ccccc3c(-c3ccccc3)c3ccccc23)cc1 ; c1ccc(-c2c3ccccc3c(-c3c(-c4ccc5c(c4)oc4ccccc45)ccc4oc5ccccc5c34)c3ccccc23)cc1]

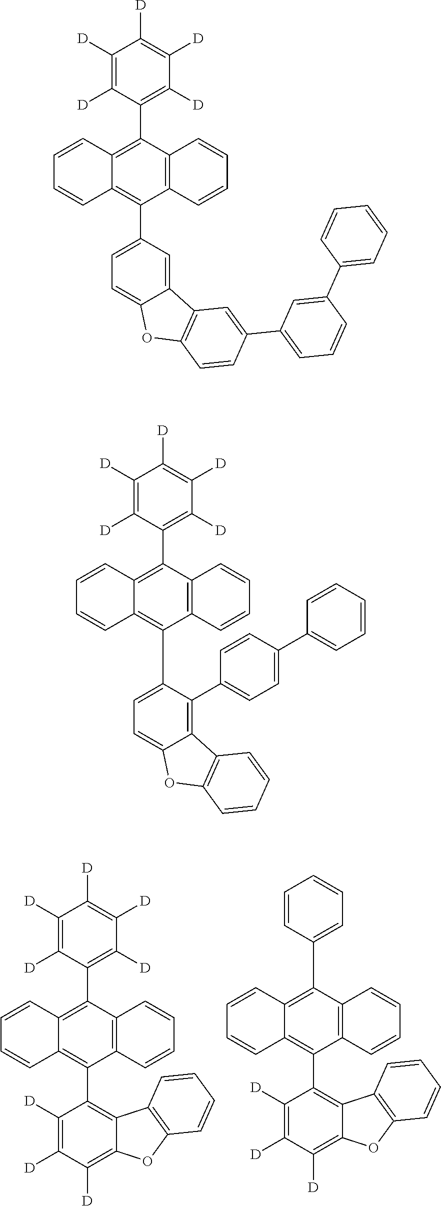

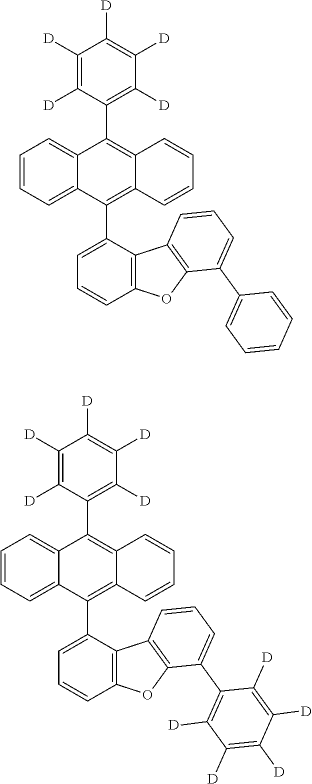 [SMILES: [2H]c1c([2H])c([2H])c(-c2c3ccccc3c(-c3cccc4oc5c(-c6ccccc6)cccc5c34)c3ccccc23)c([2H])c1[2H] ; [2H]c1c([2H])c([2H])c(-c2c3ccccc3c(-c3cccc4oc5c(-c6c([2H])c([2H])c([2H])c([2H])c6[2H])cccc5c34)c3ccccc23)c([2H])c1[2H]]

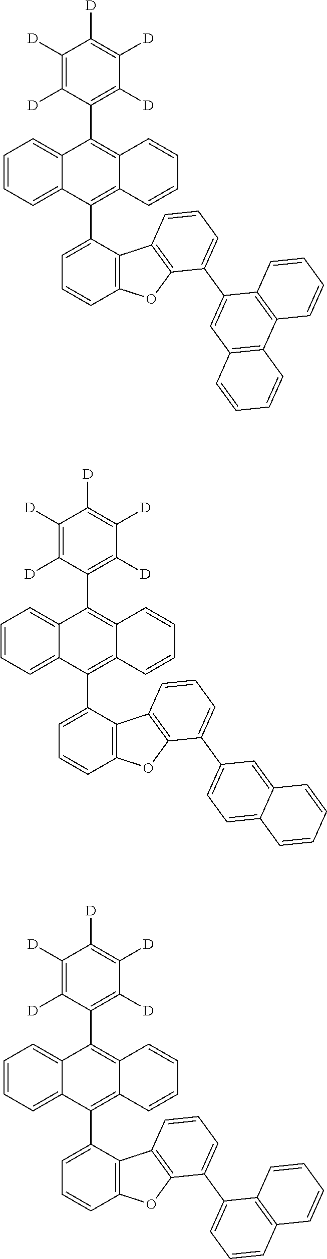 [SMILES: [2H]c1c([2H])c([2H])c(-c2c3ccccc3c(-c3cccc4oc5c(-c6cc7ccccc7c7ccccc67)cccc5c34)c3ccccc23)c([2H])c1[2H] ; [2H]c1c([2H])c([2H])c(-c2c3ccccc3c(-c3cccc4oc5c(-c6ccc7ccccc7c6)cccc5c34)c3ccccc23)c([2H])c1[2H] ; [2H]c1c([2H])c([2H])c(-c2c3ccccc3c(-c3cccc4oc5c(-c6cccc7ccccc67)cccc5c34)c3ccccc23)c([2H])c1[2H]]

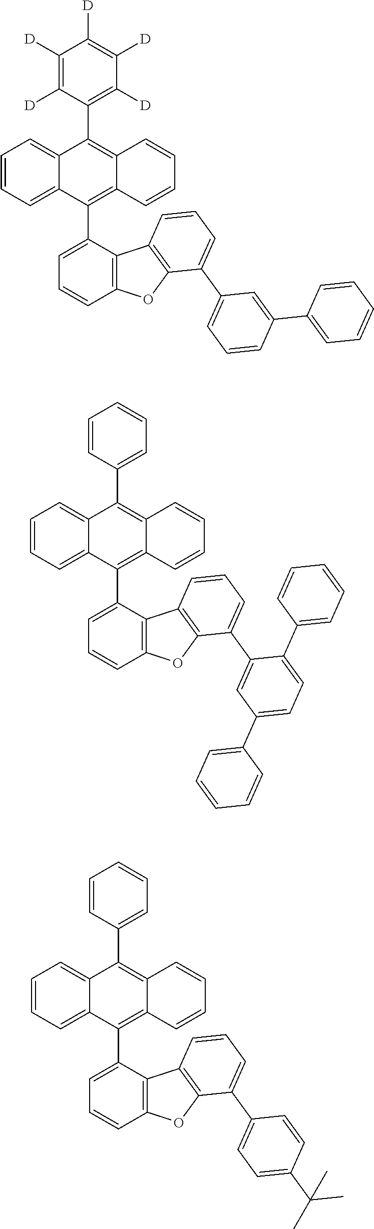 [SMILES: [2H]c1c([2H])c([2H])c(-c2c3ccccc3c(-c3cccc4oc5c(-c6cccc(-c7ccccc7)c6)cccc5c34)c3ccccc23)c([2H])c1[2H] ; c1ccc(-c2ccc(-c3ccccc3)c(-c3cccc4c3oc3cccc(-c5c6ccccc6c(-c6ccccc6)c6ccccc56)c34)c2)cc1 ; CC(C)(C)c1ccc(-c2cccc3c2oc2cccc(-c4c5ccccc5c(-c5ccccc5)c5ccccc45)c23)cc1]

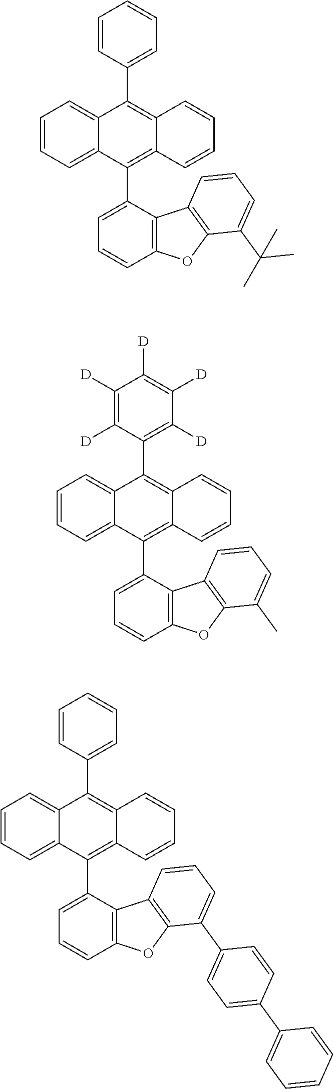 [SMILES: CC(C)(C)c1cccc2c1oc1cccc(-c3c4ccccc4c(-c4ccccc4)c4ccccc34)c12 ; [2H]c1c([2H])c([2H])c(-c2c3ccccc3c(-c3cccc4oc5c(C)cccc5c34)c3ccccc23)c([2H])c1[2H] ; c1ccc(-c2ccc(-c3cccc4c3oc3cccc(-c5c6ccccc6c(-c6ccccc6)c6ccccc56)c34)cc2)cc1]

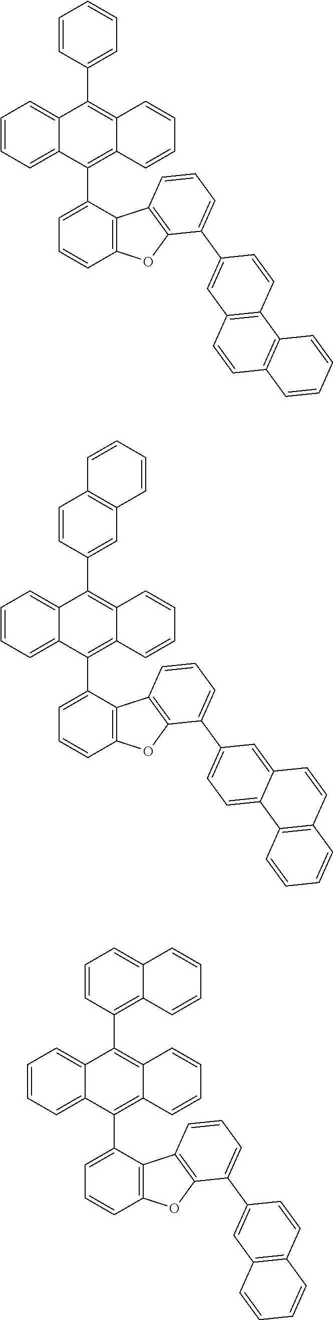 [SMILES: c1ccc(-c2c3ccccc3c(-c3cccc4oc5c(-c6ccc7c(ccc8ccccc87)c6)cccc5c34)c3ccccc23)cc1 ; c1ccc2cc(-c3c4ccccc4c(-c4cccc5oc6c(-c7ccc8c(ccc9ccccc98)c7)cccc6c45)c4ccccc34)ccc2c1 ; c1ccc2cc(-c3cccc4c3oc3cccc(-c5c6ccccc6c(-c6cccc7ccccc67)c6ccccc56)c34)ccc2c1]

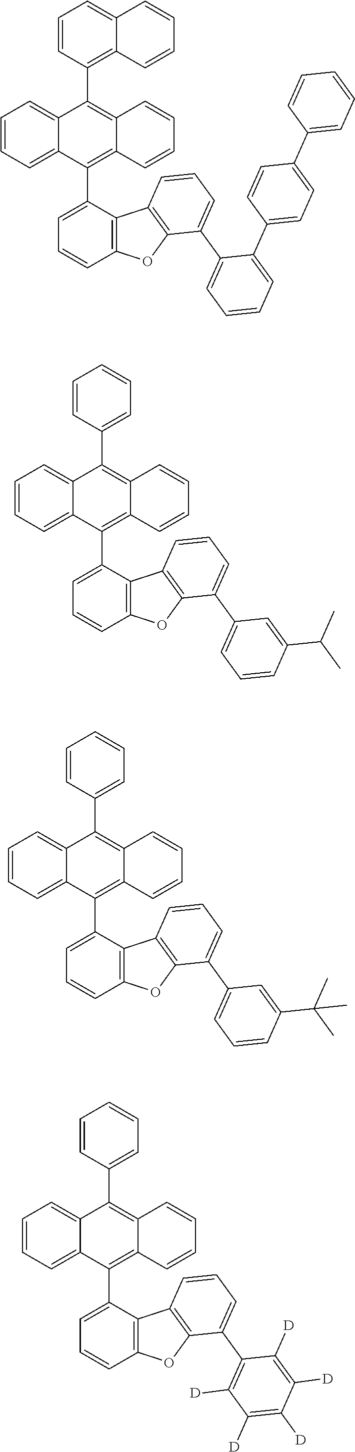 [SMILES: c1ccc(-c2ccc(-c3ccccc3-c3cccc4c3oc3cccc(-c5c6ccccc6c(-c6cccc7ccccc67)c6ccccc56)c34)cc2)cc1 ; CC(C)c1cccc(-c2cccc3c2oc2cccc(-c4c5ccccc5c(-c5ccccc5)c5ccccc45)c23)c1 ; CC(C)(C)c1cccc(-c2cccc3c2oc2cccc(-c4c5ccccc5c(-c5ccccc5)c5ccccc45)c23)c1 ; [2H]c1c([2H])c([2H])c(-c2cccc3c2oc2cccc(-c4c5ccccc5c(-c5ccccc5)c5ccccc45)c23)c([2H])c1[2H]]

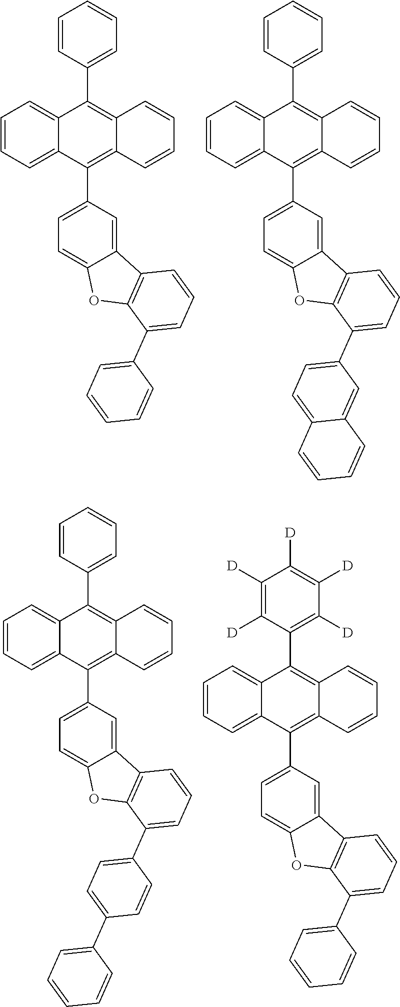

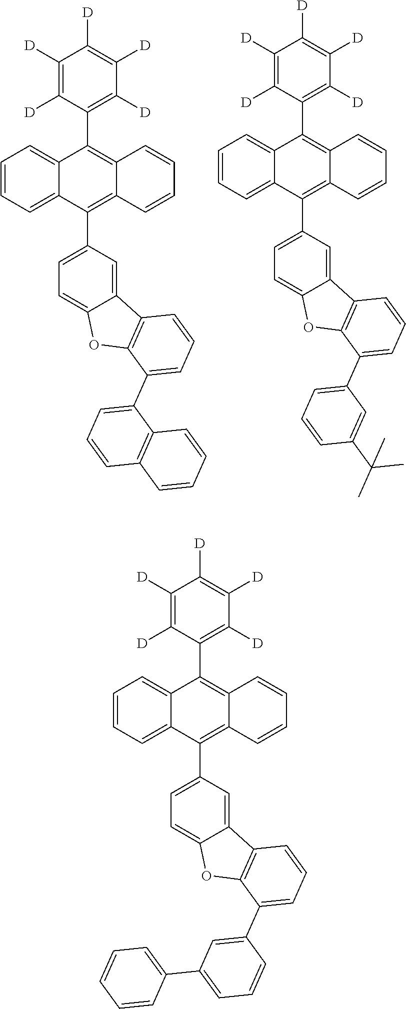

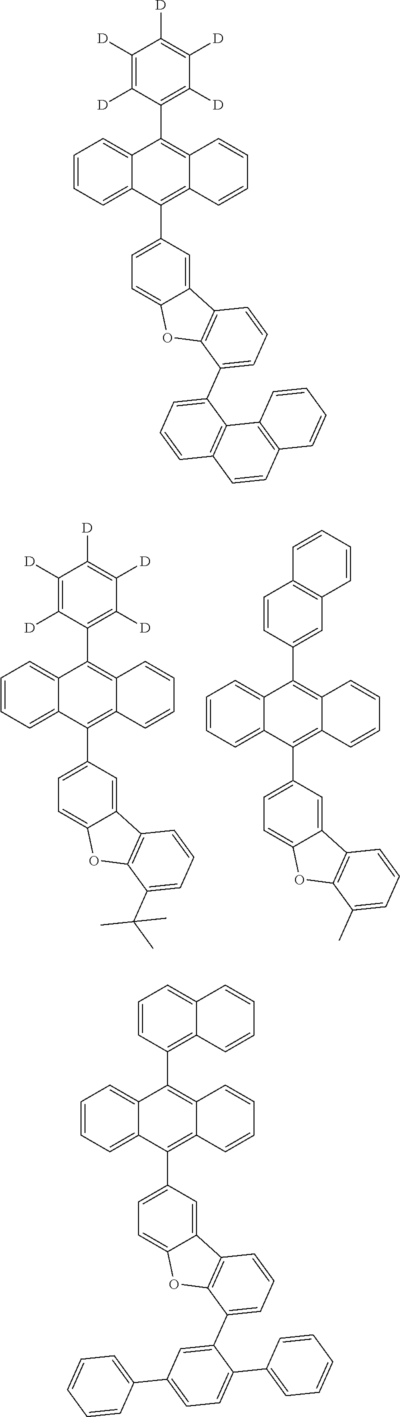

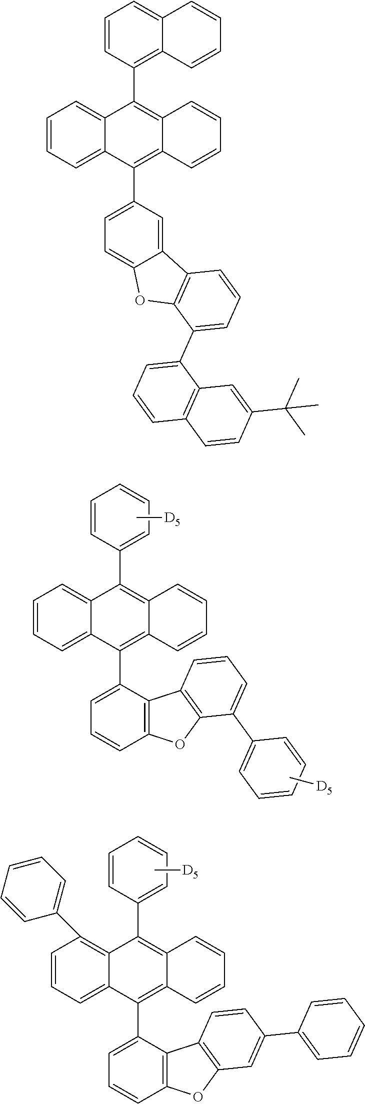

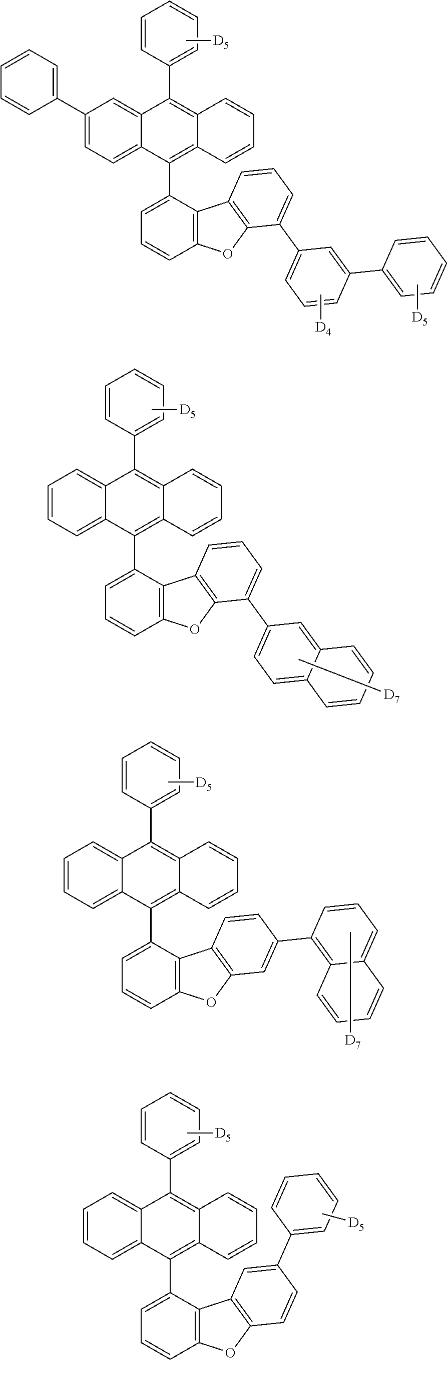

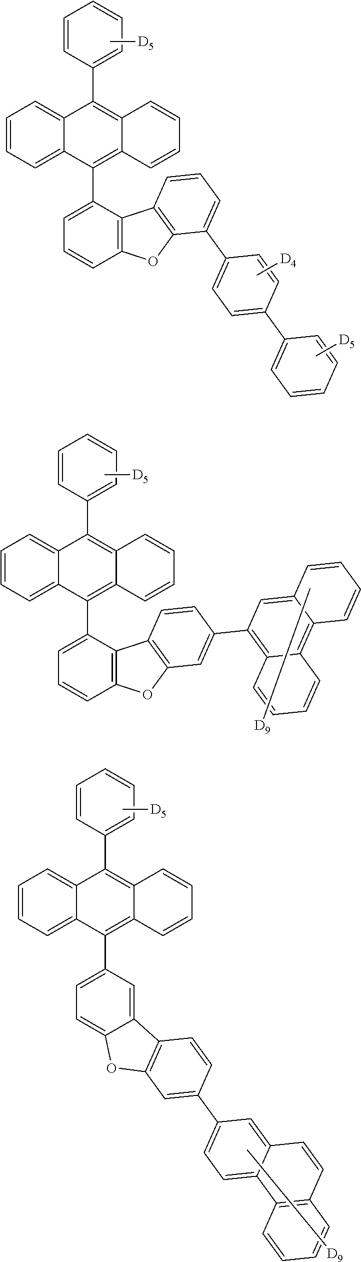

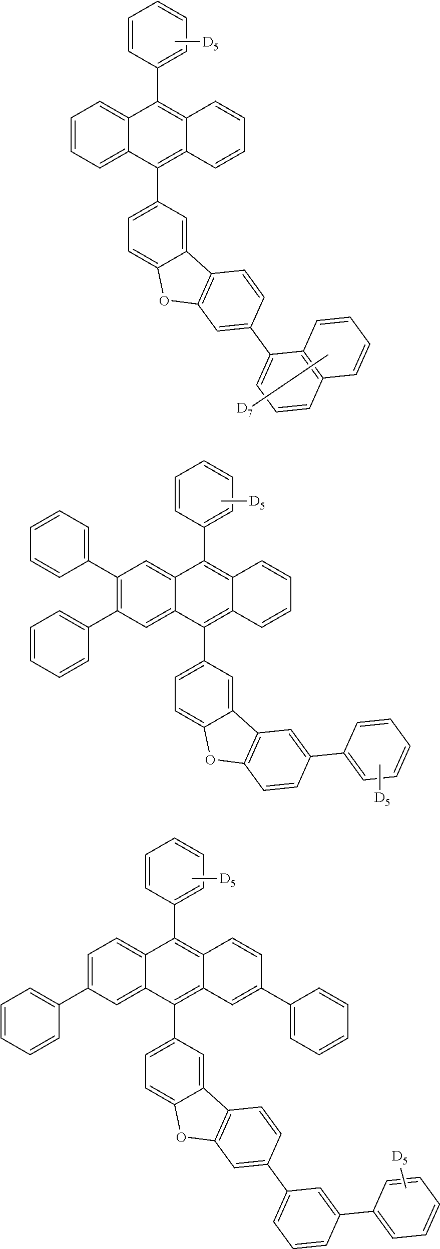

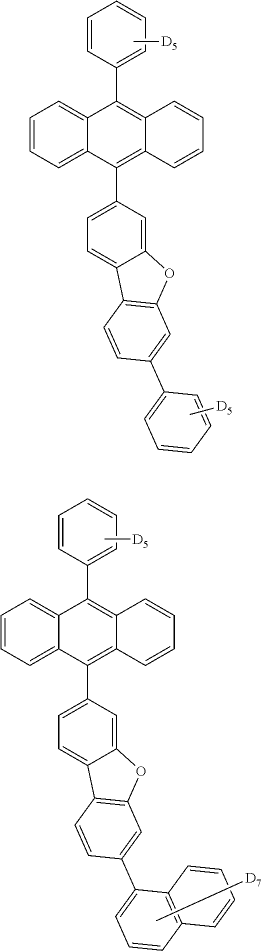

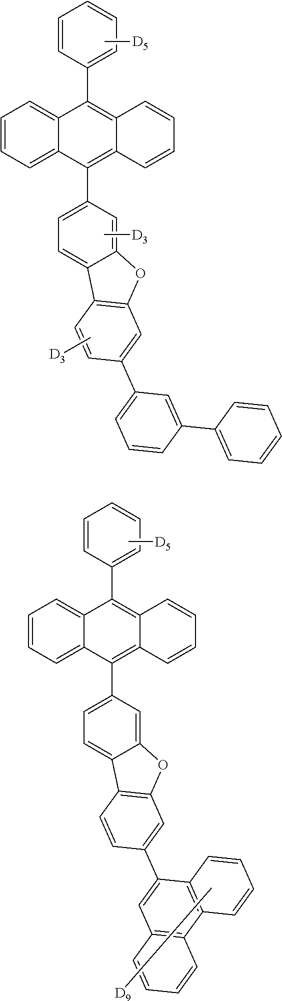

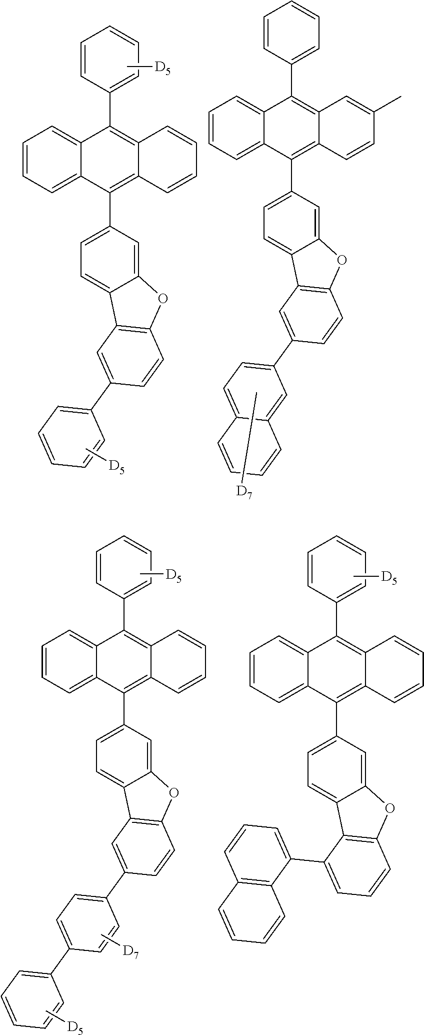

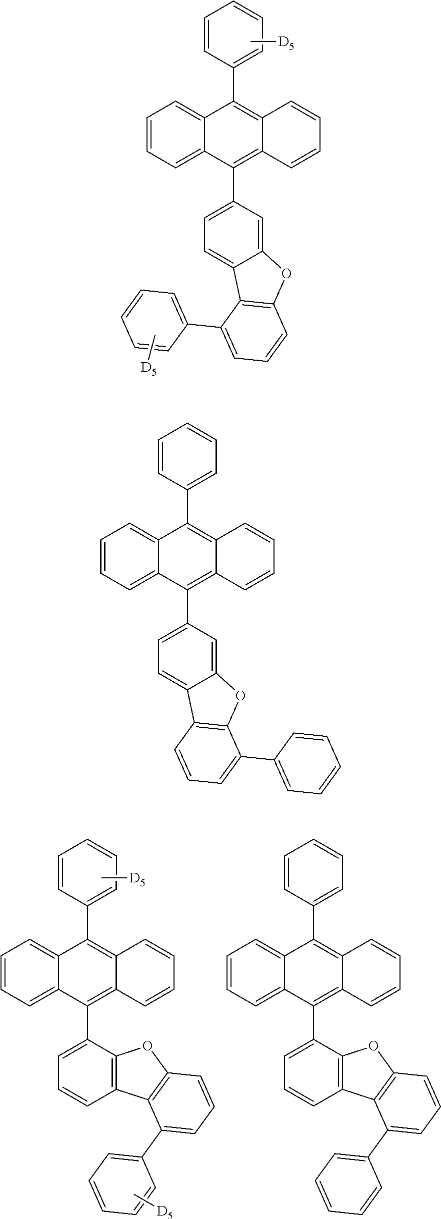

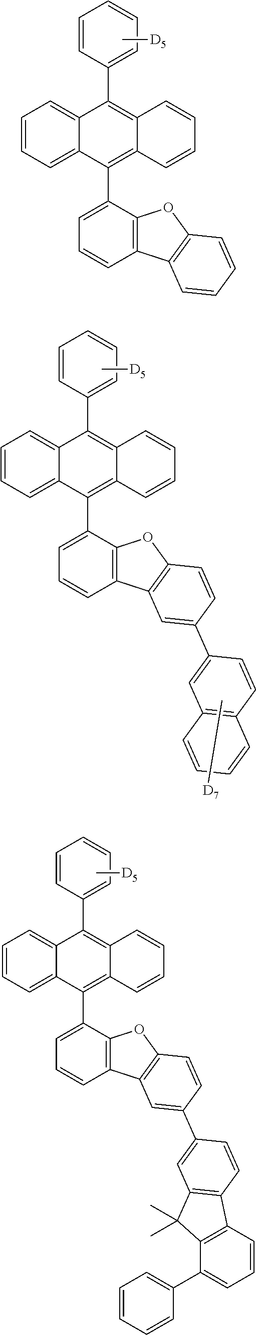

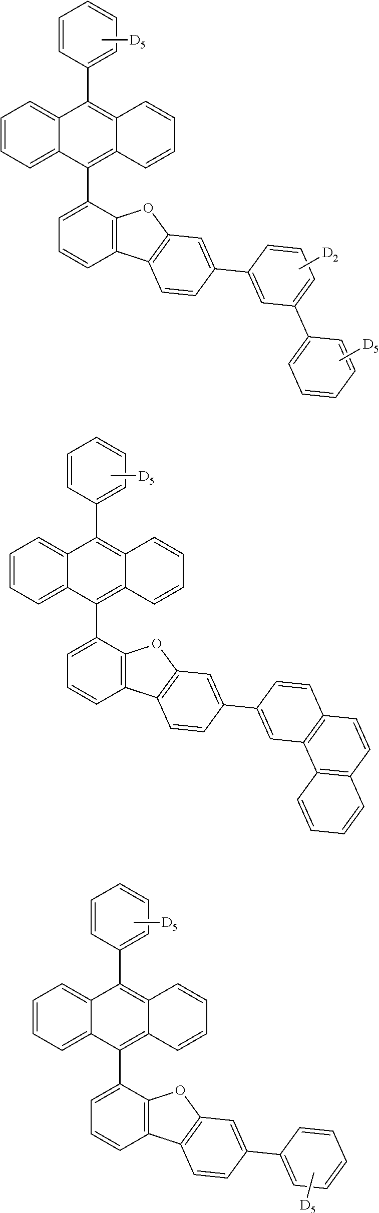

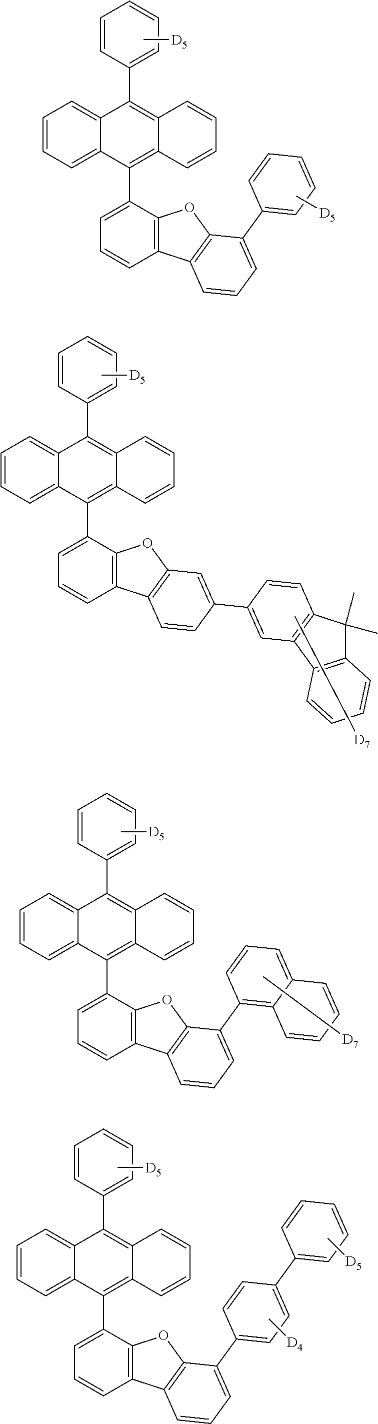

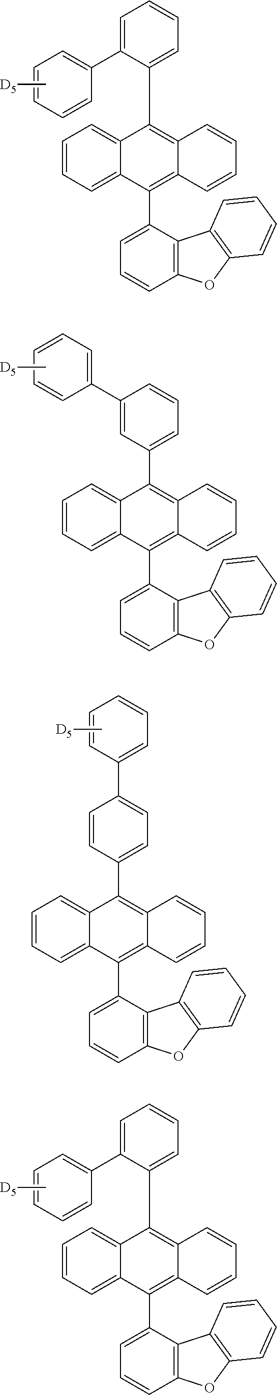

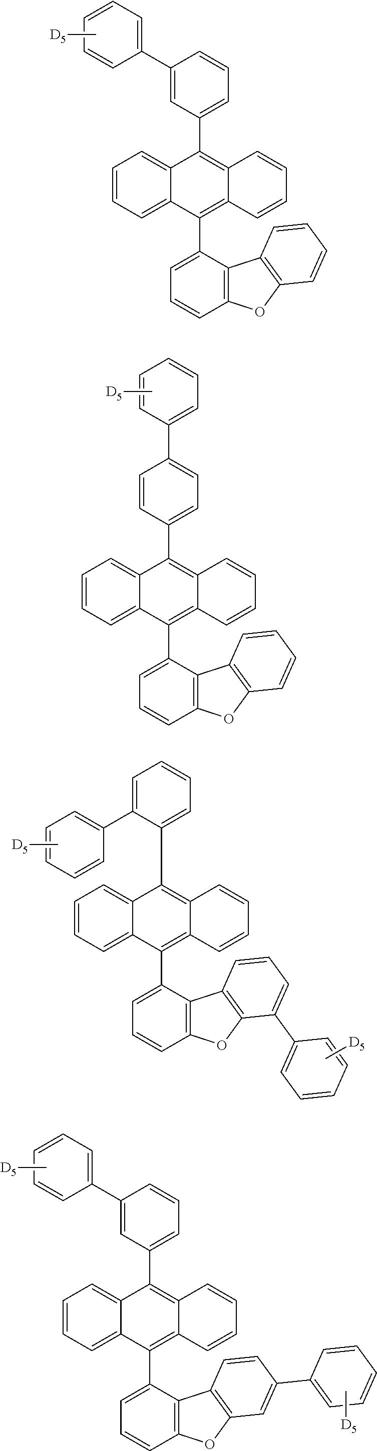

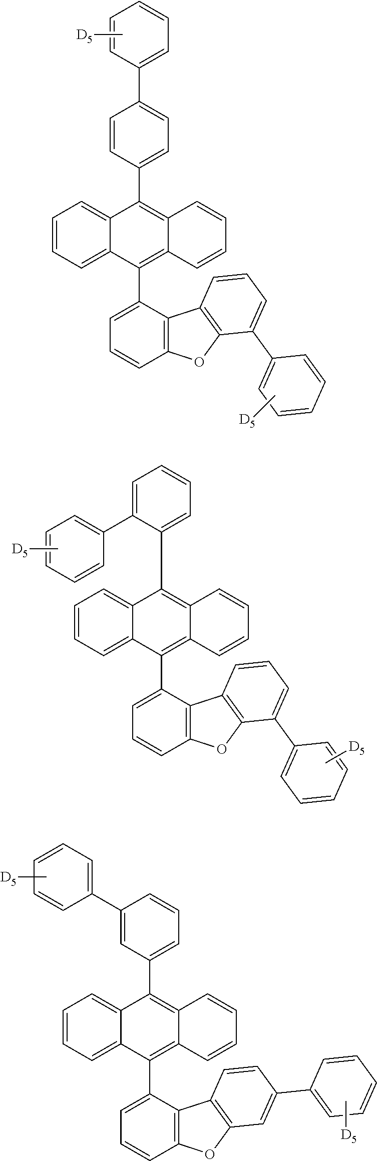

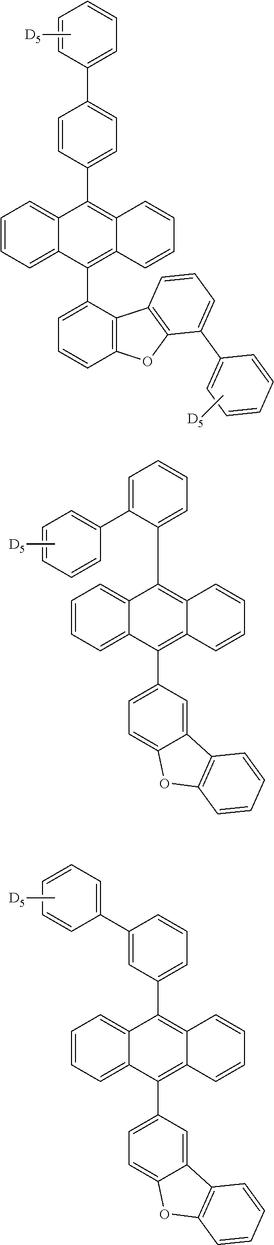

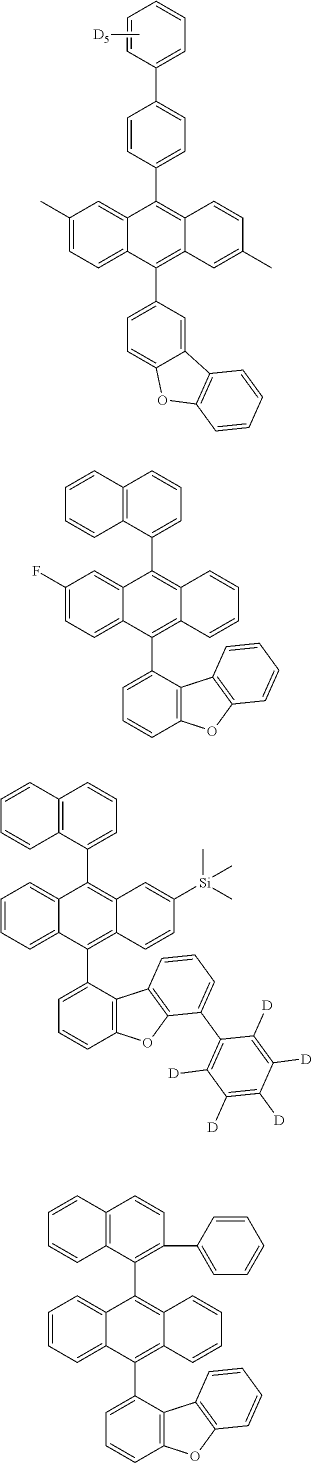

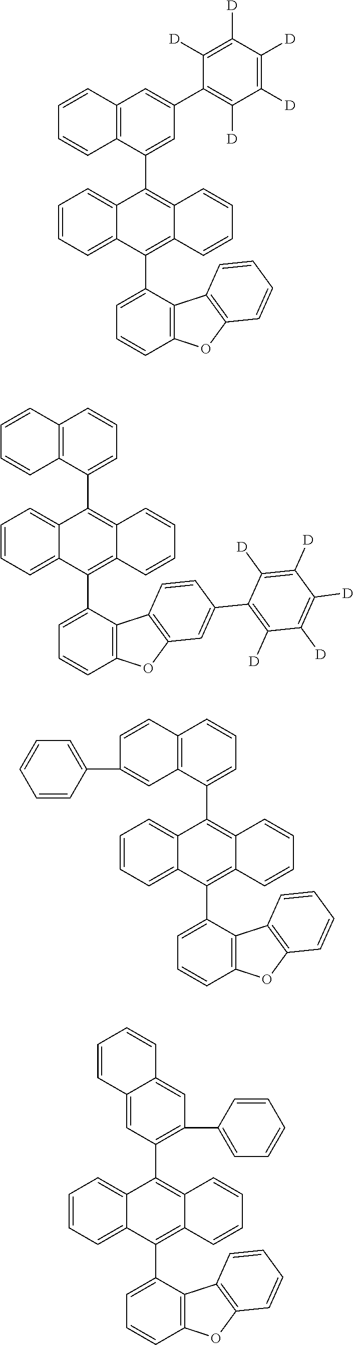 [SMILES: [2H]c1c([2H])c([2H])c(-c2cc(-c3c4ccccc4c(-c4cccc5oc6ccccc6c45)c4ccccc34)c3ccccc3c2)c([2H])c1[2H] ; [2H]c1c([2H])c([2H])c(-c2ccc3c(c2)oc2cccc(-c4c5ccccc5c(-c5cccc6ccccc56)c5ccccc45)c23)c([2H])c1[2H] ; c1ccc(-c2ccc3cccc(-c4c5ccccc5c(-c5cccc6oc7ccccc7c56)c5ccccc45)c3c2)cc1 ; c1ccc(-c2cc3ccccc3cc2-c2c3ccccc3c(-c3cccc4oc5ccccc5c34)c3ccccc23)cc1]

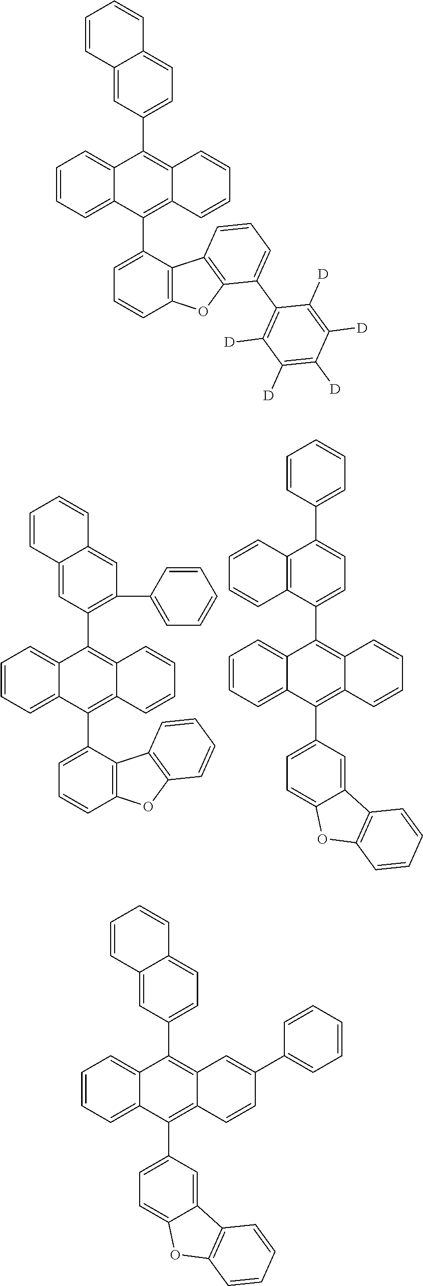

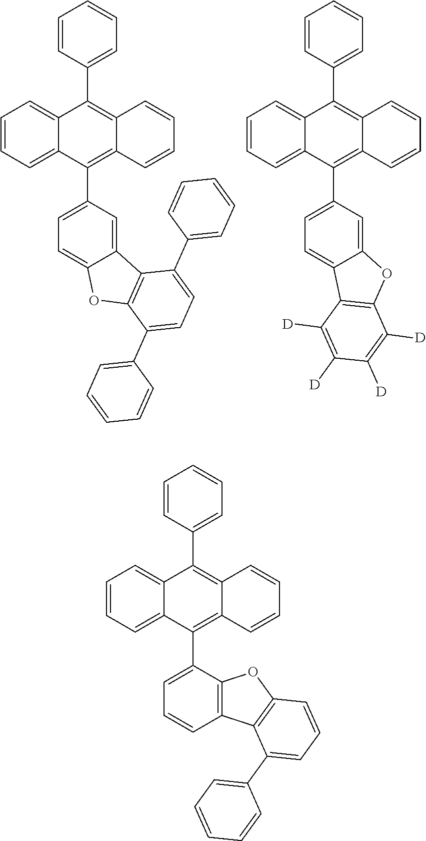

13. The organic light emitting device according to claim 11, wherein one or more host compounds other than the anthracene compound represented by Formula 2 are mixed or stacked.

14. The organic light emitting device according to claim 7, wherein each of the organic layers is formed by a deposition or solution process.

15. The organic light emitting device according to claim 6, wherein the organic light emitting device is used in a display or lighting system selected from flat panel displays, flexible displays, monochromatic flat panel lighting systems, white flat panel lighting systems, flexible monochromatic lighting systems, flexible white lighting systems, displays for automotive applications, displays for virtual reality, and displays for augmented reality.
